(19) United States
(12) Patent Application Publication
(10) Pub. No.: US 2012/0111621 A1
(43) Pub. Date: May 10, 2012

(54) RESIN COMPOSITION, RESIN SHEET, PREPREG, METAL-CLAD LAMINATE, PRINTED WIRING BOARD AND SEMICONDUCTOR DEVICE

(75) Inventors: Noriyuki Ohigashi, Tokyo (JP); Seiji Mori, Tokyo (JP); Haruo Murakami, Tokyo (JP); Akihiko Tobisawa, Tokyo (JP); Hiroshi Obata, Tokyo (JP); Takayoshi Masaki, Tokyo (JP)

(73) Assignee: SUMITOMO BAKELITE COMPANY, LTD., Tokyo (JP)

(21) Appl. No.: 13/386,135

(22) PCT Filed: Jul. 21, 2010
(86) PCT No.: PCT/JP2010/062259

§ 371 Date: Jan. 20, 2012

(30) Foreign Application Priority Data
Jul. 24, 2009 (JP) 2009-172630
Nov. 20, 2009 (JP) 2009-264857
Nov. 20, 2009 (JP) 2009-265256
Feb. 24, 2010 (JP) 2010-038652
Mar. 1, 2010 (JP) 2010-044145

(51) Int. Cl. H05K 1/00; C08L 63/00; C08K 3/36; B32B 27/38; B32B 15/092; B82Y 30/00

(52) U.S. Cl. 174/258; 428/323; 523/440; 523/443; 523/435; 977/773

(57) ABSTRACT

An object of the present invention is to provide a resin composition having excellent impregnation property into a base material and capable of producing a prepreg, metal-clad laminate and printed wiring board excellent in properties such as low warpage, flame resistance, low thermal expansion properties, drill processability and desmear resistance. A first resin composition comprises an epoxy resin, an irregular-shaped first inorganic filler and a second inorganic filler having an average particle diameter of 10 to 100 nm which is different from that of the first inorganic filler. A second resin composition comprises an epoxy resin, silicone rubber particles having an average particle diameter of 1 μm to 10 μm, boehmite particles having an average particle diameter of 0.2 μm to 5 μm, and silica nanoparticles having an average particle diameter of 10 nm to 100 nm.

### TECHNICAL FIELD

The present invention relates to a resin composition, a resin sheet, a prepreg, a metal-clad laminate, a printed wiring board and a semiconductor device.

### BACKGROUND ART

In recent years, with growing demand for highly-functional electronics, high-density integration within electronic components and high-density mounting of electronic components have been developed. Accordingly, printed wiring boards capable of high-density mounting and so on used for the electronic components have been developed in miniaturization, decrease in thickness, high density and multilayering than ever before.

Therefore, printed wiring boards and metal-clad laminates are required to meet basic needs such as flame resistance and so on, and further, to have the following properties. In particular, the printed wiring boards and metal-clad laminates are required to have: (1) excellent low thermal expansion properties and low warpage to respond to decrease in rigidity of a base material itself due to thinner design, and small dimensional change and warpage upon connecting components to the metal-clad laminates and printed wiring boards by reflow; (2) excellent desmearing properties in a plating process to respond to a multilayered printed wiring board so that electrical conduction between a upper layer metal wiring and a lower layer metal wiring can be sufficiently ensured; and (3) excellent drill processability to respond to speedy mass production so that productivity is high.

A prepreg used for producing the printed wiring board is generally produced by dissolving a resin composition mainly comprising a thermosetting resin such as an epoxy resin in a solvent to prepare a varnish, and impregnating a base material with the thus-obtained varnish followed by heat-drying. The prepreg has been produced using a resin composition comprising an inorganic filler in order to improve heat resistance, low thermal expansion properties, low warpage, desmear resistance, etc. of the prepreg, laminate and printed wiring board, or using a resin composition comprising flexible components in order to improve drill processability, etc. of the prepreg.

For example, the resin composition disclosed in Patent Literature 1 comprises an epoxy resin, a curing agent, an inorganic filler containing aluminum hydroxide or both of spherical silica and aluminum hydroxide, and flexible components comprising particles having a core-shell structure, in which the shell portion is made of a resin compatible with the epoxy resin, wherein the resin composition has a thermal expansion coefficient α_{z} of 48 or less in a thickness (Z) direction in a cured state. Patent Literature 1 discloses that the laminate produced using the resin composition has excellent dimensional stability and drill processability, and thus, the occurrence of crack in drill processing can be prevented.

Patent Literature 2 discloses a prepreg obtained by combining a thermosetting resin composition containing an aluminum hydroxide-boehmite composite as an essential component with a base material. The technique disclosed in Patent Literature 2 uses the inorganic filler having high heat resistance, such as boehmite and aluminum hydroxide-boehmite composite, to respond to increase in solder reflow temperature.

Patent Literature 3 discloses a technique relating to a filling material filled into through-holes and/or concave portions of the base material. In particular, the purpose of the technique is to prevent the occurrence of cracks and to improve drill processability in the base material filled with the filling material. Patent Literature 3 discloses a liquid filling material comprising at least a curing agent, an inorganic filler, an organic filler and a liquid resin.

### CITATION LIST

### Patent Literature

[Patent Literature 1] Japanese Patent Application Laid-Open (JP-A) No. 2009-74036

[Patent Literature 2] JP-A No. 2004-59643

[Patent Literature 3] JP-A No. 2007-250966

### SUMMARY OF INVENTION

### Technical Problem

However, in the varnish comprising the resin composition containing a large amount of particles of the inorganic filler or flexible component, dispersibility of the particles is likely to deteriorate, and thus viscosity (thixotropy) can be high. Therefore, it becomes difficult to impregnate the base material with a sufficient amount of the resin composition and to uniformly impregnate the base material with the particles. Thereby, since pressure caused by convexoconcaves of the prepreg and the particles is varied, there are problems that resins and particles are likely to be separated and streaked unevenness is caused on the metal-clad laminate to be obtained.

Also, if an irregular-shaped inorganic filler such as boehmite is used, flowability of the varnish comprising the resin composition is particularly likely to decrease. Therefore, there is a problem that it becomes difficult to fill high amount of the inorganic filler into the base material.

The present invention has been made in view of the above circumstances, and it is an object of the present invention to provide a resin composition having excellent impregnation property into a base material and capable of producing a prepreg, metal-clad laminate and printed wiring board excellent in properties (for example, low warpage, flame resistance, low thermal expansion properties, drill processability and desmear resistance), which are imparted by a filler.

Another object of the present invention is to provide a resin sheet produced using the resin composition, a prepreg produced using the resin composition, a metal-clad laminate produced using the resin composition or prepreg, a printed wiring board produced using at least one of the metal-clad laminate, prepreg and resin composition, and a semiconductor device having excellent performance produced using the printed wiring board.

### Solution to Problem

The above object can be achieved by the following (1) to (27).

(1) A resin composition for forming a laminate, comprising an epoxy resin, a first inorganic filler with an irregular shape and a second inorganic filler having an average particle diameter of 10 to 100 nm which is different from that of the first inorganic filler.

(2) The resin composition according to (1), wherein a content of the second inorganic filler is 0.5 to 5% by weight of the resin composition.

(3) The resin composition according to (1) or (2), prepared with a slurry produced by preliminarily dispersing the second inorganic filler in an organic solvent.

(4) The resin composition according to any one of (1) to (3), wherein the second inorganic filler is silica.

(5) The resin composition according to any one of (1) to (4), wherein the first inorganic filler is boehmite.

(6) The resin composition according to any one of (1) to (5), wherein the first inorganic filler has an average particle diameter of 0.5 to 5 μm.

(7) The resin composition according to any one of (1) to (6), wherein a content of the first inorganic filler is 20 to 65% by weight of the resin composition.

(8) The resin composition according to any one of (1) to (7), further comprising a third inorganic filler having an average particle diameter of 0.2 to 3 μm.

(9) The resin composition according to (8), wherein the third inorganic filler has a maximum particle diameter of 10 μm or less.

(10) The resin composition according to (8) or (9), wherein a weight ratio (w2/w3) of the content of the second inorganic filler (w2) and a content of the third inorganic filler (w3) is 0.02 to 1.5.

(11) The resin composition according to any one of (1) to (10), wherein a weight ratio (w2/w1) of the content of the first inorganic filler (w1) and the content of the second inorganic filler (w2) is 0.02 to 0.5.

(12) The resin composition according to any one of (1) to (11), further comprising a cyanate resin.

(13) The resin composition according to any one of (1) to (12), wherein the epoxy resin is at least one kind selected from the group consisting of a biphenyldimethylene type epoxy resin, a novolac type epoxy resin, a naphthalene-modified cresol novolac epoxy resin and an anthracene type epoxy resin.

(14) A resin composition comprising an epoxy resin, silicone rubber particles having an average particle diameter of 1 μm to 10 μm, boehmite particles having an average particle diameter of 0.2 μm to 5 μm, and silica nanoparticles having an average particle diameter of 10 nm to 100 nm.

(15) The resin composition according to (14), wherein each of the silicone rubber particles is a core-shell structure particle in which a core portion consisting of silicone rubber is covered with a silicone resin.

(16) The resin composition according to (14) or (15), wherein the silica nanoparticles have an average particle diameter of 40 nm or more and 100 nm or less.

(17) The resin composition according to any one of (14) to (16), further comprising a cyanate resin.

(18) The resin composition according to any one of (14) to (17), further comprising a maleimide resin.

(19) The resin composition according to any one of (14) to (18), wherein the epoxy resin is at least one kind selected from the group consisting of a biphenylaralkyl type epoxy resin, a naphthalene-skeleton modified epoxy resin and a cresol novolac type epoxy resin.

(20) A resin sheet comprising a resin layer and a base material, wherein the resin layer comprises the resin composition defined by any one of (1) to (19) and is on the base material.

(21) A prepreg comprising a base material impregnated with the resin composition defined by any one of (1) to (19).

(22) A metal-clad laminate comprising a resin-impregnated base material layer and a metal foil, wherein the metal foil is on at least one surface of the resin-impregnated base material layer, and the resin-impregnated base material layer comprises a base material impregnated with the resin composition defined by any one of (1) to (19).

(23) The metal-clad laminate according to (22), obtained by providing a metal foil on at least one surface of the prepreg defined by (21) or on at least one surface of a laminate comprising the stacked prepregs, and applying heat and pressure.

(24) A printed wiring board comprising the metal-clad laminate defined by (22) or (23) as an inner layer circuit board.

(25) A printed wiring board comprising the prepreg defined by (21) and an inner layer circuit, wherein the prepreg is used as an insulating layer on the inner layer circuit.

(26) A printed wiring board comprising the resin composition defined by any one of (1) to (19) and an inner layer circuit, wherein the resin composition is used as an insulating layer on the inner layer circuit.

(27) A semiconductor device comprising the printed wiring board defined by any one of (24) to (26), and a semiconductor element mounted on the printed wiring board.

### Advantageous Effects of Invention

By using the first resin composition of the present invention combining a first inorganic filler with an irregular shape and a second inorganic filler having an average particle diameter of 10 to 100 nm which is different from that of the first inorganic filler, a varnish containing the first inorganic filler with an irregular shape can be obtained without decreasing flowability, and thus, the warpage of a metal-clad laminate can be prevented.

By using the second resin composition containing silicone rubber particles, boehmite particles and silica nanoparticles, a varnish containing a large amount of the above three kinds of particles can be obtained in a low viscosity state, and thus the resin composition has excellent impregnation property into a base material. Also, by using the second resin composition, a metal-clad laminate having very little streaked unevenness on the surface can be obtained.

The resin sheet, prepreg and metal-clad laminate produced using the resin composition have excellent properties such as flame resistance, low thermal expansion properties, drill processability, low warpage and desmear resistance. A printed wiring board having excellent performance can be obtained using at least one of the metal-clad laminate, prepreg, resin sheet and resin composition. Furthermore, the present invention provides a semiconductor device having excellent performance using the printed wiring board.

### BRIEF DESCRIPTION OF DRAWINGS

FIG. 1 is a view schematically showing an example of an impregnating and coating apparatus used for producing a prepreg of the present invention.

FIG. 2 is a view schematically showing an example of a method for producing a metal-clad laminate of the present invention.

FIG. 3 is a view schematically showing a different example of the method for producing the metal-clad laminate of the present invention.

FIG. 4 shows: (1) a photograph of the surface of a metal foil layer of the metal-clad laminate obtained in Example B1; (2) a photograph of the surface of a metal foil layer of the metal-clad laminate obtained in Comparative example B1; and (3) a view explaining the photograph of the surface of the metal foil layer of the metal-clad laminate.

FIG. 5 shows: (1) a photograph of the surface of a metal foil layer of the metal-clad laminate obtained in Reference example C1; (2) a photograph of the surface of a metal foil layer of the metal-clad laminate obtained in Reference comparative example C1; and (3) a view explaining the photograph of the surface of the metal foil layer of the metal-clad laminate.

FIG. 6 shows: (1) a photograph of the surface of a metal foil layer of the metal-clad laminate obtained in Reference example D1; (2) a photograph of the surface of a metal foil layer of the metal-clad laminate obtained in Reference comparative example D1; and (3) a view explaining the photograph of the surface of the metal foil layer of the metal-clad laminate.

FIG. 7 shows a photograph of a cross-sectional surface of the metal-clad laminate obtained in Reference example E1.

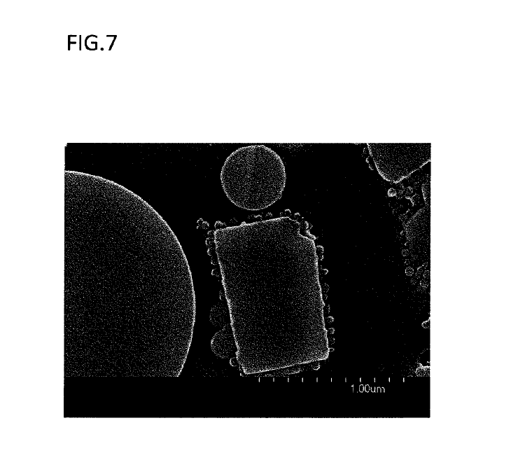

FIG. 8 shows a photograph of a cross-sectional surface of the metal-clad laminate obtained in Reference example E9.

### DESCRIPTION OF EMBODIMENTS

Hereinafter, a resin composition of the present invention, and a resin sheet, a prepreg, a metal-clad laminate, a printed wiring board and a semiconductor device, all of which comprising the resin composition, of the present invention will be described.

First, the resin compositions of the present invention will be described.

Each of the first to fifth resin compositions of the present invention contains a filler at a high rate; however, a decrease in flowability of a varnish obtained by mixing the resin composition with a solvent can be prevented. Thus, the resin compositions of the present invention have excellent impregnation property into a base material. Accordingly, the resin compositions of the present invention are highly effective in using the filler, for example, in improving characteristics such as low warpage, flame resistance, low thermal expansion properties, drill processability and desmear resistance in the prepreg, laminate or printed wiring board.

The reason why the varnish of each of the resin compositions of the present invention can contain the filler at a high rate while keeping flowability, that is, in a low viscosity state, can be considered as follows. First, each of the resin compositions of the present invention contains several kinds of filler particles. These different filler particles contained in each of the resin compositions of the present invention are selected as ones which create an attractive force between these particles. Accordingly, each of these filler particles is contained in the resin composition in a high dispersed state, so that a decrease in flowability of the varnish is prevented.

Each of the first to fifth resin compositions of the present invention has a common concept as described above.

In the present invention, the filler particles on which the attractive force acts may be present in a state of having spaces between the particles, or in a state that the particles are attached (contacted) to each other. If the combination of the different kinds of filler particles creates a strong attractive force, the filler particles are present in a state of being attached to each other, in particular, for example, in a state that each of the filler particles having a small particle diameter is attached onto the surface of each of the filler particles having a large particle diameter.

Examples of the attractive force include an attractive force created by a surface potential (zeta potential) of filler particles, an attractive force created by van der Waals' force, and an attractive force created by chemical bonding caused by a coupling agent treatment, etc. Among them, an attractive force created by the surface potential is preferred.

### [First Resin Composition]

The first resin composition of the present invention is a resin composition for forming a laminate, comprising an epoxy resin, a first inorganic filler with an irregular shape and a second inorganic filler having an average particle diameter of 10 to 100 nm which is different from that of the first inorganic filler.

In the first resin composition containing the epoxy resin, the irregular-shaped first inorganic filler and the second inorganic filler, the irregular-shaped first inorganic filler and the second inorganic filler (for example, nanosilica) are attracted to each other by an interaction due to the difference in surface potential therebetween. Therefore, the second inorganic filler is present around the irregular-shaped first inorganic filler, and the second inorganic filler exerts the effect as a spacer of the irregular-shaped first inorganic fillers, which results in decrease in the attraction created by van der Waals' force which acts the space between the irregular-shaped first inorganic fillers, and the aggregation thereof is prevented. Thereby, the irregular-shaped first inorganic fillers are contained in the first resin composition in a high dispersed state, and thus a decrease in flowability of the varnish is prevented.

As described above, even if the irregular-shaped inorganic filler is used, the present invention can provide a resin composition capable of preventing the warpage of the prepreg and laminate without decreasing flowability of the varnish.

The first resin composition of the present invention contains an epoxy resin. Thereby, a metal-clad laminate and printed wiring board excellent in electrical properties can be obtained.

The epoxy resin is not particularly limited. It is preferable that the epoxy resin substantially contains no halogen atom. Herein, “substantially contains no halogen atom” means that it is allowable for halogen derived from a halogenated component used in the process of synthesizing the epoxy resin to be left in the epoxy resin even after the process of removing the halogen. Generally, it is preferable that the amount of halogen atom contained in the epoxy resin does not exceed 30 ppm.

Examples of the epoxy resin substantially containing no halogen atom include: bisphenol type epoxy resins such as bisphenol A type epoxy resins, bisphenol F type epoxy resins, bisphenol E type epoxy resins, bisphenol S type epoxy resins, bisphenol Z type epoxy resins (4,4′-cyclohexylidenebisphenol type epoxy resins), bisphenol P type epoxy resins (4,4′-(1,4)-phenylenediisopropylidene)bisphenol type epoxy resins) and bisphenol M type epoxy resins (4,4′-(1,3-phenylenediisopropylidene)bisphenol type epoxy resins); novolac type epoxy resins such as phenol novolac type epoxy resins and cresol novolac type epoxy resins; arylalkylene type epoxy resins such as biphenyl type epoxy resins, xylylene type epoxy resins, phenol aralkyl type epoxy resins, biphenyl aralkyl type epoxy resins, biphenyl dimethylene type epoxy resins, trisphenolmethane novolac type epoxy resins, glycidylethers of 1,1,2,2-(tetraphenol)ethane, trifunctional or tetrafunctional glycidylamines and tetramethyl biphenyl type epoxy resins; naphthalene type epoxy resins such as naphthalene-skeleton modified epoxy resins, methoxynaphthalene-modified cresol novolac type epoxy resins and methoxynaphthalene dimethylene type epoxy resins; anthracene type epoxy resins; phenoxy type epoxy resins; dicyclopentadiene type epoxy resins; norbornene type epoxy resins; adamantane type epoxy resins; fluorene type epoxy resins; and flame-retardant epoxy resins in which the above resins are halogenated.

They can be used alone, or in combination with two or more kinds of epoxy resins having different weight-average molecular weights, or one or more kinds of epoxy resins can be used in combination with a prepolymer of the epoxy resin.

Among the above epoxy resins, at least one kind selected from the group consisting of biphenyldimethylene type epoxy resins, novolac type epoxy resins, naphthalene-modified cresol novolac epoxy resins and anthracene type epoxy resins is particularly preferable. By using the above epoxy resins, hygroscopic solder heat resistance and flame resistance of the laminate and printed wiring board to be obtained can be improved.

The content of the epoxy resin is not particularly limited, and is preferably 5% by weight or more and 60% by weight or less of the resin composition. If the content is less than the above lower limit, curability of the resin composition may decrease and humidity resistance of the prepreg or printed wiring board, which is obtained using the resin composition, may decrease. If the content exceeds the above upper limit, linear thermal expansion of the prepreg or printed wiring board may increase and heat resistance thereof may decrease. The content of the epoxy resin is particularly preferably 10% by weight or more and 50% by weight or less of the resin composition.

The weight-average molecular weight of the epoxy resin is not particularly limited, and is preferably 1.0×10² or more and 2.0×10⁴ or less. If the weight-average molecular weight is less than the above lower limit, tackiness may be exhibited on the surface of the insulating resin layer formed with the resin composition. If the weight-average molecular weight exceeds the above upper limit, solder heat resistance of the insulating resin layer may decrease. By having the weight-average molecular weight within the above range, it is possible to take an excellent balance of the above properties.

In the present invention, the weight-average molecular weight of the epoxy resin can be measured by, for example, gel permeation chromatography (GPC) to specify as a polystyrene calibrated-weight molecular weight.

The first resin composition of the present invention contains the irregular-shaped first inorganic filler. Thereby, it is possible to improve low thermal expansion properties, heat resistance and drill processability of the laminate and printed wiring board obtained using the resin composition.

Examples of the irregular-shaped first inorganic filler include crushed silica, zinc borate, talc, aluminum hydroxide and boehmite (alumina monohydrate obtained by modifying gibbsite).

Among them, preferred are aluminum hydroxide and boehmite. This is because it is possible to improve heat resistance and drill processability of the laminate and printed wiring board obtained using the resin composition.

The average particle diameter of the first inorganic filler is not particularly limited, and is preferably 0.3 to 5 μm, more preferably 0.5 to 5 μm, still more preferably 0.5 to 3 μm. If the average particle diameter is within the above range, the resin composition having particularly excellent high filling properties of the first inorganic filler and flowability can be obtained.

The average particle diameter of the first inorganic filler can be measured by a laser diffraction and scattering method. It can be measured by dispersing the inorganic filler in water by ultrasonic sound, preparing a particle size distribution of the inorganic filler based on volume by means of a laser diffraction particle size analyzer (product name: LA-500; manufactured by: HORIBA), and defining the thus-obtained median diameter as the average particle diameter. In particular, the average particle diameter of the inorganic filler can be defined by D50.

The content of the first inorganic filler is not particularly limited, and is preferably 20 to 65% by weight, more preferably 25 to 55% by weight of the resin composition. If the content is within the above range, the resin composition having particularly excellent balance of heat resistance and flowability can be obtained.

The 1% weight-loss thermal decomposition temperature of the first inorganic filler is preferably 260° C. or more, more preferably 300° C. or more. The 1% weight-loss thermal decomposition temperature is defined as a temperature at which a weight of the inorganic filler is reduced by 1% of an initial weight at a heating rate of 10° C./min by means of a differential thermal balance (TG/DTA). Examples of the first inorganic filler having a 1% weight-loss thermal decomposition temperature of 300° C. or more include boehmite or the like.

The first resin composition of the present invention contains the second inorganic filler having an average particle diameter of 10 to 100 nm which is different from that of the first inorganic filler. Thereby, it is possible to prevent a decrease in flowability of the varnish caused upon using the irregular-shaped first inorganic filler.

Examples of the second inorganic filler include fused silica obtained by the dry methods such as a combustion method, and sol-gel silica obtained by the wet methods such as a precipitation method and a gel method.

Since dispersibility of the second inorganic filler can be improved and a decrease in flowability of the varnish can be further prevented, the first resin composition is preferably prepared with a slurry produced by preliminarily dispersing the second inorganic filler in an organic solvent. It is particularly preferable to use a slurry produced by preliminarily dispersing nanosized silica in the organic solvent.

By using such a slurry produced by preliminarily dispersing the second inorganic filler (particularly, silica) in the organic solvent, it is possible to prevent a decrease in flowability of the varnish upon using the irregular-shaped first inorganic filler. The reasons thereof are considered as below. First, this is because nanosized particles such as nanosized silica easily aggregate and often form secondary aggregates, etc. upon being charged in a resin composition; however, such secondary aggregates can be prevented by using particles in a form of slurry, so that it is possible to prevent a decrease in flowability. Secondly, this is because there is an increase in effect of preventing the irregular-shaped first inorganic filler from aggregation due to the difference in surface potential between the second inorganic filler (nanosized silica) and the irregular-shaped first inorganic filler.

The average particle diameter of the second inorganic filler is preferably 15 to 90 nm, more preferably 25 to 75 nm. If the average particle diameter is within the above range, high filling properties of the second inorganic filler and high flowability of the varnish in the resin composition can be improved.

The average particle diameter can be measured by, for example, an ultrasonic vibration current method (zeta potential), an ultrasonic attenuation spectroscopy (particle size distribution), a laser diffraction and scattering method or dynamic light scattering method.

For example, it can be measured by dispersing the inorganic filler in water by ultrasonic sound, preparing a particle size distribution of the inorganic filler based on volume by means of a dynamic light scattering particle size distribution analyzer (product name: LB-550; manufactured by HORIBA), and defining the thus-obtained median diameter as the average particle diameter. In particular, the average particle diameter of the inorganic filler can be defined by D50.

The content of the second inorganic filler is not particularly limited, and is preferably 0.5 to 20% by weight, more preferably 1 to 10% by weight, still more preferably 0.5 to 5% by weight of the resin composition. If the content is within the above range, the resin composition having particularly excellent impregnation property in the prepreg and formability can be obtained.

The weight ratio (w2/w1) of the content of the first inorganic filler (w1) and the content of the second inorganic filler (w2) is not particularly limited, and is preferably 0.02 to 0.5, more preferably 0.06 to 0.4. If the weight ratio is within the above range, formability can be particularly improved.

The first resin composition is not particularly limited, and preferably contains the third inorganic filler having an average particle diameter of 0.2 to 3 μm. By using the third inorganic filler having the above-mentioned average particle diameter in combination with the first inorganic filler and the second inorganic filler, heat resistance and dimensional stability of the laminate and printed wiring board obtained using the resin composition can be particularly improved. In addition, by using the first inorganic filler, the second inorganic filler and the third inorganic filler in combination, impregnation property of a resin varnish can be improved in comparison with the conventional resin composition containing a submicron order inorganic filler like as the third inorganic filler and an irregular-shaped inorganic filler like the first organic filler.

The average particle diameter of the third inorganic filler is preferably 0.3 to 2.5 μm, more preferably 0.4 to 1.5 μm. If the average particle diameter is within the above range, it is possible to increase the balance between high filling properties of the third inorganic filler in the resin composition and workability such as press molding of the prepreg obtained using the resin composition and drill processing of the laminate.

The average particle diameter of the third inorganic filler can be measured by a laser diffraction and scattering method. In particular, the average particle diameter of the third inorganic filler can be measured by the method similarly as in the first inorganic filler.

The maximum particle diameter of the third inorganic filler is not particularly limited, and is preferably 10 μm or less, more preferably 5 μm or less. Thereby, drill bit breakage rate upon drill processing in the production of the printed wiring board can be decreased.

Examples of the third inorganic filler include silica, titanium oxide, silicon nitride, aluminum nitride, boron nitride and alumina. Among them, preferred is silica, more preferred is spherical fused silica. This is because the above-mentioned fused silica has excellent low thermal expansion properties compared with other inorganic fillers. The method for producing the spherical silica is not particularly limited. The spherical silica can be obtained by the known method. Examples of the method for producing the spherical silica include the dry silica method, the wet silica method and the sol-gel method.

The weight ratio (w2/w3) of the content of the second inorganic filler (w2) and the content of the third inorganic filler (w3) is not particularly limited, and is preferably 0.02 to 1.5, more preferably 0.05 to 1.2. If the weight ratio is within the above range, formability of the laminate and printed wiring board upon stacking prepregs comprising the resin composition can be particularly excellent.

The specific surface area of the third inorganic filler (particularly, silica) is not particularly limited, and is preferably 1 m²/g or more and 250 m²/g or less. If the specific surface area exceeds the above upper limit, the third inorganic fillers easily aggregate and the structure of the resin composition may be unstable. If the specific surface area is less than the above lower limit, the third inorganic filler may be less suitable to be filled in the resin composition. The specific surface area can be measured by a BET method.

The third inorganic filler (particularly, silica) may be preliminarily subjected to surface treatment using any of silanes containing functional groups and/or alkyl silazanes. By the preliminary surface treatment, aggregation of the third inorganic filler can be prevented and the silica can be suitably dispersed in the resin composition of the present invention. In addition, since the adhesion between the epoxy resin and the surface of the third inorganic filler improves, an insulating layer having excellent mechanical strength can be obtained.

As the silanes containing functional groups of the above silanes containing functional groups and/or alkyl silazanes, known silanes containing functional groups can be used. The examples include epoxysilane, styrylsilane, methacryloxysilane, acryloxysilane, mercaptosilane, N-butylaminopropyltrimethoxysilane, N-ethylaminoisobutyltrimethoxysilane, N-methylaminopropyltrimethoxysilane, N-phenyl-3-aminopropyltrimethoxysilane, 3-(N-allylamino) propyltrimethoxysilane, (cyclohexylaminomethyl)triethoxysilane, N-cyclohexylaminopropyltrimethoxysilane, N-ethylamino isobutylmethoxyldiethoxysilane, (phenylaminomethyl)methyldimethoxysilane, N-phenylaminomethyltriethoxysilane, N-methylaminopropylmethyldimethoxysilane, vinylsilane, isocyanate silane, sulfidesilane, chloropropylsilane and ureidosilane compounds.

Examples of the alkyl silazanes include hexamethyldisilazane (HMDS), 1,3-divinyl-1,1,3,3-tetramethyldisilazane, octamethyltrisilazane and hexamethylcyclotrisilazane. Among them, hexamethyldisilazane (HMDS) is preferable as the alkyl silazanes.

The amount of the silanes containing functional groups and/or alkyl silazanes used for preliminary surface treatment of the third inorganic filler (particularly, silica) is not particularly limited, and is preferably 0.01 part by weight or more and 5 parts by weight or less, more preferably 0.1 part by weight or more and 3 parts by weight or less, with respect to 100 parts by weight of the third inorganic filler. If the content of the silanes containing functional groups and/or alkyl silazanes exceeds the above upper limit, cracks may be caused in the insulating layer when the printed wiring board is produced. If the content is less than the above lower limit, bonding force of resin components and the third inorganic filler may decrease.

The method of preliminary surface treatment of the third inorganic filler (particularly, silica) using silanes containing functional groups and/or alkyl silazanes is not particularly limited, and a wet method or a dry method is preferable. The wet method is particularly preferable since uniform surface treatment of the third inorganic filler can be performed in comparison with the dry method.

The content of the third inorganic filler (particularly, silica) is not particularly limited, and is preferably 20% by weight or more and 85% by weight or less, more preferably 25% by weight or more and 75% by weight or less of the resin composition. If the content of the third inorganic filler is less than the above lower limit, linear thermal expansion of a cured product of the resin composition may increase and water absorption properties thereof may increase. If the content exceeds the above upper limit, formability of the insulating resin layer and prepreg may decrease due to decrease in flowability of the resin composition. By having the content of the third inorganic filler within the above range, the linear thermal expansion of the cured product of the resin composition can be 35 ppm or less.

In the present invention, the content of components with respect to the resin composition is defined based on the premise that the total amount of the components excluding a solvent contained for the purpose of dissolving and/or dispersing the components is 100% by weight.

The first resin composition is not particularly limited, and preferably contains a cyanate resin. Thereby, flame resistance can be improved.

The cyanate resin is not particularly limited, and can be obtained by, for example, reacting a cyanogen halide compound with phenols or naphthols and, as needed, prepolymerizing the reactant by a method such as heating. In addition, commercial products prepared as described above can be used.

The cyanate resin is not particularly limited, and the examples include bisphenol type cyanate resins such as novolac type cyanate resins, bisphenol A type cyanate resins, bisphenol E type cyanate resins and tetramethyl bisphenol F type cyanate resins.

The cyanate resin preferably has two or more cyanate groups (—O—CN) in the molecule. Examples of the cyanate resin include cyanate resins obtained by the reaction between 2,2′-bis(4-cyanatophenyl)isopropylidene, 1,1′-bis(4-cyanatophenyl)ethane, bis(4-cyanato-3,5-dimethylphenyl)methane, 1,3-bis(4-cyanatophenyl-1-(1-methylethylidene))benzene, dicyclopentadiene type cyanate ester, phenol novolac type cyanate ester, bis(4-cyanatophenyl)thioether, bis(4-cyanatophenyl)ether, 1,1,1-tris(4-cyanatophenyl)ethane, tris(4-cyanatophenyl)phosphite, bis(4-cyanatophenyl)sulfone, 2,2-bis(4-cyanatophenyl)propane, 1,3-,1,4-,1,6-,1,8-,2,6- or 2,7-dicyanatonaphthalene, 1,3,6-tricyanatonaphthalene, 4,4-dicyanatobiphenyl, and phenol novolac type or cresol novolac type polyphenol and cyanogen halide, and cyanate resins obtained by the reaction between naphtholaralkyl type polynaphthol and cyanogen halide.

Among them, phenol novolac type cyanate resins are excellent in flame resistance and low thermal expansion properties, and 2,2′-bis(4-cyanatophenyl)isopropylidene and dicyclopentadiene type cyanate ester are excellent in control of cross-linking density and in humidity resistant reliability. Particularly, phenol novolac type cyanate resins are preferable from the viewpoint of low thermal expansion properties. In addition, one or more kinds of other cyanate resins can be further used together, but not particularly limited thereto.

The cyanate resins can be used alone, or in combination with two or more kinds having different weight-average molecular weights, or the cyanate resin can be used in combination with a prepolymer of the cyanate resin.

The prepolymer is generally obtained by, for example, trimerizing the cyanate resin by heating reaction or the like, and it is favorably used to control formability and flowability of the resin composition.

The prepolymer is not particularly limited. For example, in the case of using a prepolymer having a trimerization rate of 20 to 50% by weight, excellent formability and flowability can be exhibited.

The content of the cyanate resin is not particularly limited, and is preferably 5 to 60% by weight, more preferably 10 to 50% by weight, still more preferably 10 to 40% by weight on the solid content basis of the resin composition. If the content is within the above range, the cyanate resin can effectively exhibit heat resistance and flame resistance. If the content of the cyanate resin is less than the above lower limit, thermal expansion properties may increase and heat resistance may decrease. If the content exceeds the above upper limit, there may be a decrease in strength of the prepreg produced using the resin composition.

The first resin composition is not particularly limited, and preferably contains a coupling agent. Thereby, mechanical strength of the laminate and printed wiring board obtained using the resin composition can be improved.

Particularly in the case of using boehmite as the first inorganic filler, aromatic amino silane is preferably used as the coupling agent. Thereby, water absorption properties of a cured product of the resin composition can be further decreased as a result of synergistic effect of boehmite and aromatic amino silane, and the multilayer printed wiring board obtained using the resin composition has excellent adhesion between a metal foil and a prepreg and between prepregs in the test after moisture absorption treatment.

Examples of the aromatic amino silane include secondary aromatic amino silanes such as N-phenyl-3-aminopropyltrimethoxysilane, (phenylaminomethyl)methyldimethoxysilane and N-phenylaminomethyltriethoxysilane; and primary aromatic amines such as 3-(m-aminophenoxy)propyltrimethoxysilane, p-aminophenyltrimethoxysilane and m-aminophenyltrimethoxysilane. Among them, preferred are secondary aromatic amino silanes such as N-phenyl-3-aminopropyltrimethoxysilane, etc. By using these aromatic amino silanes, the resin composition having excellent desmearing properties in the process of removing resin residues after laser radiation during the process of producing the multilayer printed wiring board can be obtained, while water absorption property can be decreased by using with boehmite.

The content of the coupling agent (particularly, aromatic amino silane) is not particularly limited, and is preferably 0.05 part by weight or more and 5 parts by weight or less, more preferably 0.2 part by weight or more and 2.5 parts by weight or less, with respect to 100 parts by weight of the first inorganic filler. If the content of the coupling agent exceeds the above upper limit, formability of the prepreg comprising the base material impregnated with the first resin composition of the present invention may decrease in the production of the laminate. If the content is less than the above lower limit, the adhesion between a circuit and the insulating layer formed with the first resin composition of the present invention may decrease.

The first resin composition can further use a phenolic curing agent. Well-known, commonly-used products may be used alone or in combination of two or more kinds as the phenolic curing agent. The example include phenol novolac resins, alkylphenol novolac resins, bisphenol A novolac resins, dicyclopentadiene-type phenol resins, xylok-type phenol resins, terpene-modified phenol resins and polyvinyl phenols.

The compounding amount of the phenolic curing agent is not particularly limited. The equivalent ratio with the epoxy resin (phenolic hydroxyl group equivalent/epoxy group equivalent) is preferably less than 1.0 and 0.1 or more. Thereby, an unreacted phenolic curing agent is not left, so that heat resistance after moisture absorption of the laminate and printed wiring board obtained using the resin composition can be improved. Furthermore, if high heat resistance after moisture absorption is required, the equivalent ratio is particularly preferably in the range of 0.2 to 0.5. The phenol resin can accelerate curing the cyanate group and epoxy group in addition to acting as a curing agent.

As needed, the first resin composition can contain additives other than the above components to the extent that the properties are not deteriorated. Examples of the additives other than the above components include: accelerators such as imidazole, triphenylphosphine and quaternary phosphonium salt; surfactants such as acrylate; and colorants such as a dye and a pigment.

The resin composition of the present invention is used as a varnish obtained by dissolving the resin composition in a solvent upon producing the resin sheet or prepreg. The method for preparing the varnish is not particularly limited, and the example include a method comprising the steps of: preparing a slurry produced by dissolving an epoxy resin, first inorganic filler and second inorganic filler in a solvent; adding other components of the resin composition to the slurry; and further adding the solvent thereto to dissolve and mix the same.

The solvent is not particularly limited, and the solvent which exhibits excellent solubility to the resin composition is preferable. The examples include acetone, methyl ethyl ketone (MEK), cyclohexanone (ANON), methyl isobutyl ketone (MIBK), cyclopentanone, dimethylformamide, dimethylacetamide, N-methylpyrolidone. A poor solvent can be used to the extent that it exerts no negative effect.

The solid content of the resin composition contained in the varnish is not particularly limited, and is preferably 30 to 80% by weight, more preferably 40 to 70% by weight. Thereby, impregnation property of the resin composition into the base material can be improved.

### [Second Resin Composition]

Next, the second resin composition of the present invention will be described.

The second resin composition of the present invention contains an epoxy resin, silicone rubber particles having an average particle diameter of 1 μm to 10 μm, boehmite particles having an average particle diameter of 0.2 μm to 5 μm, and silica nanoparticles having an average particle diameter of 10 nm to 100 nm.

In the second resin composition, the silicone rubber particles, boehmite particles and silica nanoparticles are combined; thereby, the resin varnish of the present invention can contain a large amount of the above three kinds of particles in a low viscosity state. This is because the silica nanoparticles having a negative surface zeta potential are selectively attached around the boehmite particles having a positive surface zeta potential, so that the repulsion force between the silicone rubber particles and boehmite particles, both of which have a positive surface zeta potential, is reduced. Therefore, the varnish can be in a low viscosity state even if the varnish contains a large amount of particles.

In addition, by using the second resin composition having low viscosity despite containing a large amount of the above-mentioned filler particles, it is possible to obtain a prepreg comprising a base material impregnated with a sufficient amount of the resin composition. The obtained prepreg is excellent in flame resistance, low thermal expansion properties, drill processability and desmear resistance.

The metal-clad laminate using the prepreg comprising the above-mentioned second resin composition and/or resin composition has large flow, since the varnish of the resin composition is in a low viscosity state. However, the resin composition contains the silicone rubber particles, boehmite particles and silica nanoparticles; thereby, the balance of the flowability of the above particles and the resin flowability can be excellent, and the pressure by the particles is less varied due to the cushion effect of the silicone rubber particles, so that the surface of the metal-clad laminate has very little streaked unevenness.

The silicone rubber particles are not particularly limited as long as they are elastic rubber particles formed with organopolysiloxane. The examples include particles made of silicone rubber (organopolysiloxane cross-linked elastomer) itself and core-shell structure particles in which a core portion made of silicone rubber is covered with a silicone resin. Examples of the silicone rubber particles include commercial products such as KMP-605, KMP-600, KMP-597 and KMP-594 (they are manufactured by: Shin-Etsu Chemical Co., Ltd.), and TREFIL E-500 and TREFIL E-600 (they are manufactured by: Dow Corning Toray Silicone Co., Ltd.).

The average particle diameter of the silicone rubber particles is 1 to 10 μm, preferably 1 to 5 μm, from the viewpoint of excellent impregnation property.

The content of the silicone rubber particles is not particularly limited, and is preferably 5 to 50% by weight on the solid content basis of the resin composition, more preferably 10 to 40% by weight from the viewpoint of excellent impregnation property.

The boehmite particles are aluminum oxide monohydrate. The examples include commercial products such as AOH-30, AOH-60 (they are manufactured by: TESCO Co., Ltd.), BMB series in the form of a particle, BMT series in the form of a plate and BMF series in the form of a scale (they are manufactured by: Kawai Lime Industry Co., Ltd.).

The average particle diameter of the boehmite particles is 0.2 to 5 μm, preferably 0.5 to 4 μm, from the viewpoint of excellent impregnation property.

The content of the boehmite particles is not particularly limited, and is preferably 5 to 50% by weight on the solid content basis of the resin composition, more preferably 10 to 40% by weight, from the viewpoint of excellent impregnation property.

The average particle diameter of the silica nanoparticles is 10 to 100 nm, preferably 40 to 100 nm, from the viewpoint of impregnation property. This is because if the average particle diameter is less than 10 nm, the distance between filaments of the base material cannot be increased. If the average particle diameter exceeds 100 nm, the silica nanoparticles may not impregnate into the spaces between filaments.

The silica nanoparticles are not particularly limited, and ones produced by the following method can be used. Examples of the method include: combustion method such as the VMC (Vaperized Metal Combustion) method and the PVS (Physical Vapor Synthesis) method; fusion methods in which crushed silica is subjected to flame fusion; precipitation methods; and gel methods. Among them, the VMC method is particularly preferable. The VMC method is a method for forming silica particles by charging silicon powders in chemical flame formed in oxygen-containing gas to burn followed by cooling. In the VMC method, the particle diameter of the silica particles to be obtained can be adjusted by adjusting the particle diameter of silicon powders to be charged, the charging amount of silicon powders and flame temperature, etc.

Also, commercial products such as NSS-5N (manufactured by Tokuyama Corporation) and Sicastar 43-00-501 (manufactured by Micromod) can be used.

The content of the silica nanoparticles is not particularly limited, and is preferably 1 to 10% by weight, more preferably 2 to 5% by weight on a solid content basis of the resin composition. If the content is within the above range, the resin composition has particularly excellent impregnation property.

The weight ratio (weight of silicone rubber particles/weight of silica nanoparticles) of the content of the silicone rubber particles to the content of the silica nanoparticles is not particularly limited, and is preferably 1 to 15, more preferably 1 to 10, still more preferably 2 to 5.

The weight ratio (weight of boehmite particles/weight of silica nanoparticles) of the content of the boehmite particles to the content of the silica nanoparticles is not particularly limited, and is preferably 1 to 50, more preferably 2 to 20.

If the weight ratio of the content of the silicone rubber particles to the content of the silica nanoparticles, and the weight ratio of the content of the boehmite particles to the content of the silica nanoparticles is within the above range, formability can be particularly improved. If they are less than or exceeds the above range, impregnation property decreases, thus, solder heat resistance and insulation reliability are likely to decrease due to void occurrence.

The average particle diameter of the silicone rubber particles, boehmite particles and silica nanoparticles can be measured by, for example, a laser diffraction and scattering method and dynamic light scattering method. For example, it can be measured by dispersing particles in water by ultrasonic sound, preparing a particle size distribution of the particles based on volume by means of a laser diffraction particle size analyzer (product name: LA-500; manufactured by: HORIBA) or dynamic light scattering particle size distribution analyzer (product name: LB-550; manufactured by: HORIBA), and defining the thus-obtained median diameter as the average particle diameter. In particular, the average particle diameter of the silicone rubber particles, boehmite particles and silica nanoparticles can be defined by D50 (median diameter).

The resin composition of the present invention can further contain inorganic fillers such as silica, aluminum hydroxide and talc to the extent that the properties are not deteriorated.

The epoxy resin is not particularly limited, and explanation for the epoxy resin is omitted here since it is the same as one in the first resin composition.

Among the epoxy resins as described above, at least one kind selected from the group consisting of biphenylaralkyl type epoxy resins, naphthalene-skeleton modified epoxy resins and cresol novolac type epoxy resins is particularly preferable. By using these epoxy resins, heat resistance and flame resistance of the prepreg, laminate and printed wiring board to be obtained can be improved.

The content of the epoxy resin is not particularly limited, and is preferably 5 to 30% by weight on a solid content basis of the resin composition. If the content is less than the above lower limit, curability of the resin composition may decrease, and humidity resistance of the prepreg or printed wiring board obtained using the resin composition may decrease. If the content exceeds the above upper limit, linear thermal expansion of the prepreg or printed wiring board may increase and heat resistance may decrease.

The weight-average molecular weight of the epoxy resin is not particularly limited, and is preferably 40 to 18,000. If the weight-average molecular weight is less than the above lower limit, the glass-transition point decreases. If the weight-average molecular weight exceeds the above upper limit, flowability decreases, so that the base material may not be impregnated with the resin composition. By having the weight-average molecular weight within the above range, the resin composition having excellent impregnation property can be obtained.

The second resin composition is not particularly limited, and preferably contains a cyanate resin. Thereby, flame resistance can be further improved.

The cyanate resin is not particularly limited, and explanation of specific examples and contents of the cyanate resin is omitted here since they are the same as ones in the first resin composition.

The second resin composition is not particularly limited, and preferably contains a maleimide resin. Thereby, heat resistance can be improved.

The maleimide resin is not particularly limited. The examples include bismaleimide resins such as N,N′-(4,4′-diphenylmethane)bismaleimide, bis(3-ethyl-5-methyl-4-maleimidephenyl)methane and 2,2-bis[4-(4-maleimidephenoxy)phenyl]propane. In addition, one or more kinds of other maleimide resins can be further used together, but not particularly limited thereto.

The maleimide resins can be used alone or in combination with a maleimide resin having a different weight-average molecular weight, or each of the maleimide resins can be used in combination with a prepolymer of the maleimide resin.

The content of the maleimide resin is not particularly limited, and is preferably 1 to 30% by weight, and more preferably 5 to 20% by weight on a solid content basis of the resin composition.

Furthermore, the second resin composition can contain at least one kind selected from the group consisting of polyimide resins, triazine resins, phenol resins and melamine resins.

The second resin composition can use a phenolic curing agent. The phenolic curing agent is not particularly limited, and explanation of specific examples and contents of the phenolic curing agent is omitted here since they are the same as ones in the first resin composition.

As needed, the second resin composition can contain additives other than the above components to the extent that the properties are not deteriorated. Examples of the additives other than the above components include: coupling agents such as an epoxy silane coupling agent, a cationic silane coupling agent, an amino silane coupling agent, a titanate coupling agent and a silicone oil coupling agent; accelerators such as imidazole, triphenylphosphine and quaternary phosphonium salt; surface conditioners such as acrylic polymer; and colorants such as a dye and a pigment.

### [Third Resin Composition]

Next, the third resin composition of the present invention will be described.

The third resin composition of the present invention contains an epoxy resin, silicone rubber particles having an average particle diameter of 1 μm to 10 μm, and silica nanoparticles having an average particle diameter of 10 nm to 150 nm.

In the third resin composition, the silicone rubber particles and silica nanoparticles are combined; thereby, the resin varnish of the present invention can contain a large amount of the above two kinds of particles in a low viscosity state. This is because, since the silicone rubber particles having a positive surface zeta potential and the silica nanoparticles having a negative surface zeta potential are attracted to each other, the varnish has low viscosity even if the resin varnish contains a large amount of particles.

By using the third resin composition having low viscosity despite containing a large amount of the above-mentioned filler particles, it is possible to obtain a prepreg comprising the base material impregnated with a sufficient amount of the resin composition. The obtained prepreg is excellent in flame resistance, low thermal expansion properties, drill processability and desmear resistance.

The metal-clad laminate using the prepreg comprising the above-mentioned third resin composition and/or resin composition has large flow, since the varnish of the resin composition is in a low viscosity state. However, the resin composition contains the silicone rubber particles and silica nanoparticles; thereby, the balance of the flowability of the above particles and the resin flowability can be excellent, and the pressure by the particles is less varied due to the cushion effect of the silicone rubber particles, so that the surface of the metal-clad laminate has very little streaked unevenness.

The silicone rubber particles are not particularly limited as long as they are elastic rubber particles formed with organopolysiloxane. Explanation of specific examples and contents of the silicone rubber particle is omitted here since they are the same as ones in the second resin composition.

The average particle diameter of the silica nanoparticles is 10 to 150 nm, preferably 40 to 100 nm, from the viewpoint of impregnation property. This is because if the average particle diameter is less than 10 nm, the distance between filaments of the base material cannot be increased. If the average particle diameter exceeds 150 nm, the silica nanoparticles may not impregnate into the spaces between filaments.

The silica nanoparticles are not particularly limited, and explanation of specific examples and contents of the silica nanoparticles is omitted here since they are the same as ones in the second resin composition.

In the third resin composition, the weight ratio (weight of silicone rubber particles/weight of silica nanoparticles) of the content of the silicone rubber particles to the content of the silica nanoparticles is not particularly limited, and is preferably 1 to 50, more preferably 2 to 20. If the weight ratio is within the above range, formability can be particularly improved. If the weight ratio is more than or less than the above range, impregnation property decreases, so that solder heat resistance and insulation reliability are likely to decrease due to void occurrence.

The average particle diameter of the silicone rubber particles and silica nanoparticles can be measured by, for example, a laser diffraction and scattering method and the dynamic light scattering method. For example, it can be measured by dispersing particles in water by ultrasonic sound, preparing a particle size distribution of the particles based on volume by means of a laser diffraction particle size analyzer (product name: LA-500; manufactured by: HORIBA) or dynamic light scattering particle size distribution analyzer (product name: LB-550; manufactured by: HORIBA), and defining the thus-obtained median diameter (D50) as the average particle diameter.

The third resin composition can contain inorganic fillers such as boehmite, silica, aluminum hydroxide and talc to the extent that the properties are not deteriorated.

The epoxy resin is not particularly limited, and the specific examples are the same as ones in the first resin composition.

Among the epoxy resins, at least one kind selected from the group consisting of biphenylaralkyl type epoxy resins, naphthalene-skeleton modified epoxy resins and cresol novolac type epoxy resins is particularly preferable. By using these epoxy resins, heat resistance and flame resistance of the prepreg, laminate and printed wiring board can be improved.

Explanation of contents of the epoxy resin is omitted here since they are the same as ones in the second resin composition.

The weight-average molecular weight of the epoxy resin is not particularly limited, and is preferably 400 to 18,000. If the weight-average molecular weight is less than the above lower limit, the glass-transition point decreases. If the weight-average molecular weight exceeds the above upper limit, flowability decreases, so that the base material may not be impregnated with the resin composition. By having the weight-average molecular weight within the above range, the resin composition having excellent impregnation property can be obtained.

The third resin composition is not particularly limited, and preferably contains a cyanate resin. Thereby, flame resistance can be further improved.

The cyanate resin is not particularly limited, and explanation of specific examples and contents of the cyanate resin is omitted here since they are the same as ones in the first resin composition.

The third resin composition is not particularly limited, and preferably contains a maleimide resin. Thereby, heat resistance can be improved.

Specific examples of the maleimide resin are the same as ones in the second resin composition.

The content of the maleimide resin is not particularly limited, and is preferably 1 to 30% by weight, more preferably 5 to 25% by weight, still more preferably 5 to 20% by weight on a solid content basis of the resin composition.

Furthermore, the third resin composition can contain at least one kind selected from the group consisting of polyimide resins, triazine resins, phenol resins and melamine resins.

The third resin composition can use a phenolic curing agent. The phenolic curing agent is not particularly limited, and the specific examples and contents of the phenolic curing agent are the same as ones in the first resin composition.

As with the second resin composition, the third resin composition can contain additives other than the above components as needed, to the extent that the properties are not deteriorated. The additives other than the above components are the same as ones in the second resin composition.

### [Fourth Resin Composition]

Next, the fourth resin composition of the present invention will be described.

The fourth resin composition contains an epoxy resin, barium sulfate particles having an average particle diameter of 10 nm to 150 nm and an inorganic filler.

The epoxy resin composition contains the barium sulfate particles having an average particle diameter of 10 nm to 150 nm; thereby, the resin varnish comprising the resin composition can contain a large amount of the inorganic filler even if the resin varnish is in a high viscosity state. This is estimated because the barium sulfate particles having an average particle diameter of 10 nm to 150 nm impregnate into the spaces between the filaments of the base material, and the spaces between the filaments increases, the resin composition can contain a larger amount of the inorganic filler than that of the conventional art.

The resin varnish can be in a low viscosity state depending on the combination of the inorganic filler, so that the resin composition can contain larger amount of the inorganic filler. This is estimated because the inorganic filler in which the barium sulfate particles are attracted to each other due to the surface zeta potential can decrease the viscosity of the resin varnish; thereby, the resin composition has excellent impregnation property even if a large amount of the inorganic filler is contained.

By using the fourth resin composition having low viscosity despite containing a large amount of the above-mentioned filler particles, it is possible to obtain a prepreg comprising the base material impregnated with a sufficient amount of the resin composition. The obtained prepreg is excellent in flame resistance, low thermal expansion properties, drill processability and desmear resistance.

The metal-clad laminate using the prepreg comprising the above-mentioned fourth resin composition and/or resin composition has large flow, since the varnish of the resin composition is in a low viscosity state. However, the resin composition contains the silicone rubber particles and barium sulfate particles; thereby, the balance of the flowability of the above particles and the resin flowability can be excellent. In addition, if the resin composition containing the silicone rubber particles is used, the pressure by the particles is less varied due to the cushion effect of the silicone rubber particles, so that the metal-clad laminate having very little streaked unevenness can be obtained.

The barium sulfate particles having an average particle diameter of 10 nm to 150 nm are not particularly limited. Preferred shape of the barium sulfate particles is a spherical shape.

Thereby, the resin composition can contain larger amount of the inorganic filler.

The average particle diameter of the barium sulfate particles is 10 to 150 nm, preferably 40 to 100 nm, from the viewpoint of impregnation property. This is because if the average particle diameter is less than 10 nm, the distance between filaments of the base material cannot be increased. If the average particle diameter exceeds 150 nm, the barium sulfate particles may not impregnate into the spaces between filaments.

Examples of the barium sulfate particles include commercial products such as BF-21 and BF-25 (they are manufactured by: Sakai Chemical Industry Co., Ltd.).

The content of the barium sulfate particles is not particularly limited, and is preferably 1 to 10% by weight, more preferably 2 to 5% by weight on a solid content basis of the resin composition. If the content is within the above range, impregnation property can be particularly excellent.

The inorganic filler used for the fourth resin composition is not particularly limited. The examples include boehmite, silica, aluminum hydroxide and talc.

It is preferable that the fourth resin composition further contains silicone rubber particles.

Thereby, drill wearability can be improved and linear thermal expansion coefficient can be decreased.

The silicone rubber particles are not particularly limited as long as they are elastic rubber particles formed with organopolysiloxane. Explanation of specific examples and contents of the silicone rubber particles is omitted here since they are the same as ones in the second resin composition.

The weight ratio (weight of silicone rubber particles/weight of barium sulfate particles) of the content of the silicone rubber particles to the content of the barium sulfate particles is not particularly limited, and is preferably 1 to 50, more preferably 2 to 20. If the weight ratio is within the above range, formability can be particularly improved. If they are less than or exceeds the above range, impregnation property decreases, so that solder heat resistance and insulation reliability are likely to decrease due to void occurrence.

The average particle diameter of the silicone rubber particles and barium sulfate particles can be measured by, for example, the laser diffraction and scattering method and dynamic light scattering method. For example, particles are dispersed in water by ultrasonic sound to measure a particle size distribution of the particles by a laser diffraction particle size analyzer (product name: LA-500; manufactured by: HORIBA) or dynamic light scattering particle size distribution analyzer (product name: LB-550; manufactured by: HORIBA) based on volume, and the thus-obtained median diameter D50 is referred to as an average particle diameter.

The epoxy resin used for the fourth resin composition is not particularly limited, and explanation of specific examples of the epoxy resin is omitted here since they are the same as ones in the first resin composition.

Among the epoxy resins as described above, biphenylaralkyl type epoxy resins, naphthalene-skeleton modified epoxy resins and cresol novolac type epoxy resins are particularly preferable. By using these epoxy resins, heat resistance and flame resistance of the prepreg, laminate and printed wiring board can be improved.

Explanation of contents of the epoxy resin is omitted here since they are the same as ones in the second resin composition.

Also, the weight-average molecular weight of the epoxy resin is not particularly limited, and is the same as that in the third resin composition.

The fourth resin composition is not particularly limited, and preferably contains a cyanate resin. Thereby, flame resistance can be further improved.

The cyanate resin is not particularly limited, and explanation of specific examples and contents is omitted here since they are the same as ones in the first resin composition.

The fourth resin composition is not particularly limited, and preferably contains a maleimide resin. Thereby, heat resistance can be improved. Explanation of specific examples and contents of the maleimide resin is omitted here since the specific examples are the same as ones in the second resin composition and the contents are the same as ones in the third resin composition.

Furthermore, the fourth resin composition can contain at least one kind selected from the group consisting of polyimide resins, triazine resins, phenol resins and melamine resins.

The fourth resin composition can use a phenolic curing agent. The phenolic curing agent is not particularly limited, and the specific examples and contents of the phenolic curing agent are the same as ones in the first resin composition.

As with the second resin composition, the fourth resin composition can contain additives other than the above components as needed, to the extent that the properties are not deteriorated. Explanation of the additives other than the above components is omitted here since they are the same as ones in the second resin composition.

### [Fifth Resin Composition]

Next, the fifth resin composition of the present invention will be described.

The fifth resin composition contains a filler containing (A) a first filler and (B) a second filler, wherein the second filler (B) having a smaller particle diameter than that of the first filler (A) is attached around the first filler (A).

The resin composition contains the filler containing the first filler (A) and the second filler (B), wherein the second filler (B) is attached around the first filler (A); thereby, the filler is uniformly dispersed in the resin composition, so that impregnation property into the base material can be improved. By using such a resin composition, the prepreg having excellent heat resistance, low thermal expansion properties and flame resistance can be obtained.

The average particle diameter of the first filler (A) is not particularly limited, and is preferably 0.2 to 10 μm, more preferably 0.5 to 5 μm.

By using the filler having the above average particle diameter, impregnation property can be further improved.

The first filler (A) is not particularly limited. The examples include oxides such as titanium oxide, alumina, silica and fused silica; carbonates such as calcium carbonate, magnesium carbonate and hydrotalcite; hydroxides such as aluminum hydroxide, magnesium hydroxide and calcium hydroxide; silicate salts such as talc, calcined talc, calcined clay, uncalcined clay, mica and glass; sulfates and sulfites such as barium sulfate, calcium sulfate and calcium sulfite; nitrides such as aluminum nitride, boron nitride, silicon nitride and carbon nitride; borates such as zinc borate, barium metaborate, aluminum borate, calcium borate and sodium borate; titanates such as strontium titanate and barium titanate; silicone such as silicone rubber; and rubber particles such as styrene butadiene rubber particles and acrylic rubber particles.

Among them, they can be used alone or in combination of two or more kinds.

The silicone is not particularly limited as long as it is elastic rubber particles formed with organopolysiloxane. The examples include a particle made of silicone rubber (organopolysiloxane cross-linked elastomer) itself and a core-shell structure particle in which the core portion made of two-dimensional cross-linked silicone is covered with three-dimensional cross-linked silicone. Examples of the silicone rubber particles include commercial products such as KMP-605, KMP-600, KMP-597 and KMP-594 (they are manufactured by: Shin-Etsu Chemical Co., Ltd.), and TREFIL E-500 and TREFIL E-600 (they are manufactured by: Dow Corning Toray Silicone Co., Ltd.).

The rubber particles are not particularly limited, and are preferably core-shell type rubber particles and crosslinked rubber particles.

The core-shell type rubber particles mean rubber particles having a core layer and shell layer. The example includes one having a double-layered structure constituted by a shell layer (outer layer) made of glassy polymer and a core layer (inner layer) made of rubbery polymer, or a three-layered structure constituted by a shell layer (outer layer) made of glassy polymer, a middle layer made of rubbery polymer and a core layer made of glassy polymer. As the rubbery polymer of the core layer in the double-layered structure or the middle layer in the three-layered structure, crosslinked rubber such as ethylene, propylene, styrene, butadiene, isopropylene, methyl acrylate, methyl methacrylate and acrylonitrile can be selected. Also, as the glassy polymer of the shell layer (outer layer) which covers the core layer in the double-layered structure or the core layer in the three-layered structure, methyl methacrylate, styrene, acrylonitrile or a copolymer thereof can be selected. The glassy polymer can contain an epoxy group, carboxyl group or the like as a functional group, and the functional group can be selected depending on use.

Examples of the crosslinked rubber particles include acrylonitrilebutadiene rubber (NBR) particles, styrenebutadiene rubber (SBR) particles and acrylic rubber particles.

The above-mentioned rubber particles can provide an effect of stress relief and low thermal expansion properties of the cured product in the fifth resin composition; thereby, it is possible to increase the mechanical strength of the cured product.

Among the first fillers, one having high heat resistance is particularly preferable. In particular, high heat resistance means that the inorganic filler has a 1% weight-loss thermal decomposition temperature of 260° C. or more, more preferably 300° C. or more. The 1% weight-loss thermal decomposition temperature is defined as a temperature at which a weight of the inorganic filler is reduced by 1% of an initial weight at a heating rate of 10° C./min by means of a differential thermal balance (TG/DTA). Examples of the filler having a 1% weight-loss thermal decomposition temperature of 300° C. or more include boehmite, alumina, talc, calcined talc and silica. Among them, boehmite, talc and calcined talc are particularly preferable. Thereby, heat resistance and drill processability can be further improved.

Organic particles such as the silicone and rubber particles are not dissolved in the organic solvent used for preparing the resin composition, and are incompatible with components such as the resin or the like in the resin composition. Therefore, the organic particles are present in the varnish of the resin composition in a dispersed state.

The content of the first filler is not particularly limited, and is preferably 40 to 75% by weight, more preferably 50 to 70% by weight of the resin composition. If the content is within the above range, the resin composition having particularly excellent heat resistance and flowability can be obtained.

If the silicone is used as the first filler, the content of the silicone is not particularly limited, and is preferably 5 to 50% by weight of the resin composition, more preferably 10 to 40% by weight from the viewpoint of excellent impregnation property. If the content exceeds 50% by weight, rigidity of the prepreg to be obtained decreases and performance such as low warpage of the printed wiring board could be decreased.

Next, the second filler will be described. The second filler (B) is not particularly limited as long as it is attached to the first filler (A).

Examples of the second filler (B) attached to the first filler (A) include one having opposite sign of zeta potential to that of the first filler (A), one which is attracted to the first filler (A) due to van der Waals' force, and one which is chemically bonded to the first filler (A) by a coupling agent treatment cr the like.

The average particle diameter of the second filler (B) is not particularly limited, is preferably 10 to 100 nm.

Thereby, impregnation property improves even if the viscosity of the varnish is high, and the occurrence of the void can be prevented. Furthermore, solder heat resistance can be excellent, and insulation reliability can be improved.

In the case of using the filler having an average particle diameter of 10 to 100 nm, the filler is preferably used as a slurry which is preliminarily dispersed in the organic solvent. This is because the filler having an average particle diameter of 10 to 100 nm easily aggregates and forms secondary aggregates, etc. upon being charged in the resin composition, and thus flowability may decrease.

The average particle diameter of the second filler (B) is preferably 15 to 90 nm, more preferably 25 to 75 nm. If the average particle diameter is within the above range, the resin composition having high filling properties and high flowability can be obtained.

The average particle diameter of the first filler (A) and second filler (B) can be measured by, for example, an ultrasonic vibration method (zeta potential), an ultrasonic attenuation spectroscopy (particle size distribution) and the laser diffraction and scattering method.

The second filler (B) is not particularly limited. The examples include silicate salts such as talc, calcined talc, calcined clay, uncalcined clay, mica and glass; oxides such as titanium oxide, alumina, silica and fused silica; carbonates such as calcium carbonate, magnesium carbonate and hydrotalcite; hydroxides such as aluminum hydroxide, magnesium hydroxide and calcium hydroxide; sulfates and sulfites such as barium sulfate, calcium sulfate and calcium sulfite; borates such as zinc borate, barium metaborate, aluminum borate, calcium borate and sodium borate; nitrides such as aluminum nitride, boron nitride, silicon nitride and carbon nitride; and titanates such as strontium titanate and barium titanate. Among them, they can be used alone or in combination of two or more kinds.

Among the above, silica is preferable from the viewpoint of decreasing linear thermal expansion of the laminate.

The shape of the second filler (B) is not particularly limited, and preferred shape is a spherical shape. Thereby, impregnation property can be improved.

The method for sphereing the second filler (B) is not particularly limited. In the case of silica, for example, silica can be a spherical shape by using the fused silica obtained by the dry methods such as a combustion method and the sol-gel silica obtained by the wet methods such as a precipitation method and a gel method.

The combination of the first filler and second filler is not particularly limited. For example, preferred combination is to use at least one selected from the group consisting of boehmite, talc and silicone particles as the first filler and silica as the second filler. In the case of the above combination, the resin composition exhibits excellent impregnation property into the base material and excellent drill processability, so that the laminate having low thermal expansion can be produced.

The weight ratio of the content of the first filler (A) and the content of the second filler (B) is not particularly limited. The weight ratio (w2/w1) of the content (w2) of the second filler (B) to the content (w1) of the first filler (A) is preferably 0.02 to 0.5, more preferably 0.06 to 0.4. If the weight ratio is within the above range, formability can be particularly improved.

The first filler (A) and/or the second filler (B) can be preliminarily subjected to surface treatment using any of silanes containing functional groups and/or alkyl silazanes including coupling agents such as an epoxy silane coupling agent, a cationic silane coupling agent, an amino silane coupling agent, a titanate coupling agent and a silicone oil coupling agent. By the preliminary surface treatment, adsorption property between the first filler (A) and the second filler (B) can be improved, and also the adhesion between the resin used for the resin composition and the first filler (A) or the second filler (B) can be improved. Therefore, the prepreg or laminate having excellent mechanical strength can be obtained.

As the silanes containing functional groups of the above silanes containing functional groups and/cr alkyl silazanes, known silanes containing functional groups can be used. Preferred are epoxy silane, styrylsilane, methacryloxysilane, acryloxysilane, mercaptosilane, triethoxysilane, N-cyclohexylaminopropyltrimethoxysilane, methyldimethoxysilane, vinylsilane, isocyanate silane, sulfidesilane, chloropropylsilane and ureidosilane compounds. More preferred are epoxy silane and vinylsilane. Particularly, adhesive properties with the irregular-shaped inorganic filler such as hoehmite and the adhesion with the resin can be improved.

The amount of the silanes containing functional groups of the above silanes containing functional groups and/or alkyl silazanes used for preliminarily surface treatment of the first filler (A) and/or the second filler (B) is not particularly limited, and is preferably 0.01 part by weight or more and 5 parts by weight or less, more preferably 0.1 part by weight or more and 3 parts by weight or less, with respect to 100 parts by weight of the filler (the first filler (A) or the second filler (B)). If the content of the silanes containing functional groups of the above silanes containing functional groups and/or alkyl silazanes exceeds the above upper limit, heat resistance and insulation reliability may decrease due to excessive amounts of the coupling agent. If the content is less than the above lower limit, the adhesion between the filler and resin components decreases, so that mechanical strength of the cured product of the resin composition and flowability of the resin composition may decrease.

The method of preliminary surface treatment of the first filler (A) and/or second filler (B) using silanes containing functional groups and/or alkyl silazanes is not particularly limited, and a wet method or a dry method is preferable. The wet method is particularly preferable since uniform surface treatment can be performed when compared with the dry method.

The resin used for the fifth resin composition is not particularly limited. Examples include an epoxy resin, a phenol resin, a cyanate resin and a maleimide resin.

The epoxy resin is not particularly limited, and the specific examples of the epoxy resin are the same as ones in the first resin composition.

Among the above epoxy resins, at least one kind selected from the group consisting of biphenylaralkyl type epoxy resins, naphthalene-skeleton modified epoxy resins and cresol novolac type epoxy resins is preferable. By using these epoxy resins, heat resistance and flame resistance of the prepreg, laminate and printed wiring board can be improved.

In the fifth resin composition, preferred content of the epoxy resin is the same as that in the second resin composition.

The weight-average molecular weight of the epoxy resin is not particularly limited, and is preferably 4.0×10² to 1.8×10³. If the weight-average molecular weight is less than the above lower limit, glass-transition point decreases. If the weight-average molecular weight exceeds the above upper limit, flowability decreases, so that the base material may not be impregnated with the resin composition. By having the weight-average molecular weight within the above range, the resin composition having excellent impregnation property can be obtained.

The cyanate resin is not particularly limited, and the specific examples and contents are the same as ones in the first resin composition.

The maleimide resin is not particularly limited. The specific examples are the same as ones in the second resin composition, and the contents are the same as ones in the third resin composition.

The phenol resin is not particularly limited, and is the same as one exemplified as the phenolic curing agent in first resin composition.

As needed, the fifth resin composition can contain additives other than the above components to the extent that the properties are not deteriorated. Examples of the additives other than the above components include: accelerators such as imidazole, triphenylphosphine and quaternary phosphonium salt; surface conditioners such as acrylic polymer; and colorants such as a dye and a pigment.

### (Resin Sheet)

The resin sheet of the present invention comprises a resin layer and a base material, wherein the resin layer comprises the resin composition of the present invention and is on the base material. The resin layer can be used as the insulating layer of the printed wiring board.

A method for producing the resin sheet is not particularly limited. The examples include: (1) a method comprising the steps of dissolving and dispersing the resin composition in a solvent or the like to prepare a resin varnish, applying the resin varnish on the base material by means of a coater selected from various kinds of coaters, and then drying the varnish; and (2) a method comprising the steps of applying the resin varnish on the base material by means of a spray apparatus, and then drying the varnish.

Among the above, the method comprising the steps of applying the resin varnish on the base material by means of a coater selected from various kinds of coaters such as a comma coater or a die coater, and then drying the varnish is preferable. Thereby, a resin sheet which causes no void and has an insulating layer having a uniform thickness can be efficiently formed.

In the resin sheet of the present invention, the thickness of the insulating layer is not particularly limited, and is preferably 5 to 100 μm. Thereby, when a printed wiring board is produced using the resin sheet, convexoconcaves of an inner layer circuit can be filled upon forming, and suitable thickness of the insulating layer can be ensured.

It is desirable that a solvent used when the resin varnish is prepared exhibits excellent solubility to the resin components in the resin composition. However, a poor solvent can be used to the extent that it exerts no negative effect. Examples of the solvent exhibiting excellent solubility include ketones such as acetone, methyl ethyl ketone, methyl isobutyl ketone, cyclohexanone and tetrahydrofuran; acetic esters such as ethyl acetate, butyl acetate, cellsolve acetate, propylene glycol monomethyl ether acetate and carbitol acetate; cellosolves such as cellosolve and butyl cellosolve; carbitols such as carbitol and butyl carbitol; aromatic hydrocarbons such as toluene and xylene; dimethylformamide; dimethylacetamide; dimethylsulfoxide; and ethylene glycol. The above solvents can be used alone or in combination of two or more kinds.

The base material used in the resin sheet of the present invention is not particularly limited. Examples of the base material include films of heat-resistant thermoplastic resins including polyester resins such as polyethylene terephthalate and polybutylene terephthalate, fluorinated resins and polyimide resins; and metal foils of copper and/or copper alloys, aluminum and/or aluminum alloys, iron and/or iron alloys, silver and/or silver alloys, gold and/or gold alloys, zinc and/or zinc alloys, nickel and/or nickel alloys, and tin and/or tin alloys.

The thickness of the base material is not particularly limited, and is preferably 10 to 70 μm, from the point of view that handling is easy in the production of the resin sheet.

In the production of the resin sheet of the present invention, it is preferable that the surface of the base material being in contact with the insulating layer has convexoconcaves that are as small as possible. Thereby, it is easy to form a fine wiring when the insulating layer is formed on a conducting circuit using the resin sheet.

### (Prepreg)

Next, the prepreg will be described.

The prepreg of the present invention is obtained by impregnating a base material with the resin composition and heat-drying the same, as needed.

Examples of the base material include glass fiber base materials such as a glass woven fabric, a glass nonwoven fabric and a glass paper; woven or nonwoven fabrics comprising synthetic fibers such as paper, aramid, polyester, aromatic polyester and fluorine resins; and woven fabrics, nonwoven fabrics or mats comprising metal fibers, carbon fibers and mineral fibers. These materials can be used alone or in combination of two or more kinds. Among them, glass fiber base materials are preferable. Thereby, there is an improvement in rigidity and dimensional stability of the prepreg.

When the base material is impregnated with the resin composition, as described above, the resin composition is dissolved in the solvent to prepare a resin varnish.

Examples of the method for impregnating the base material with the resin composition include a method for immersing the base material in the resin varnish, a method for applying the resin varnish onto the base material with a coater selected from various kinds of coaters, a method for spraying the resin varnish on the base material, etc. Among them, preferred is a method for immersing the base material in the resin varnish. Thereby, it is possible to increase the impregnation property of the resin composition into the base material. In the case that the base material is immersed in the resin varnish, a general impregnating and coating apparatus can be used.

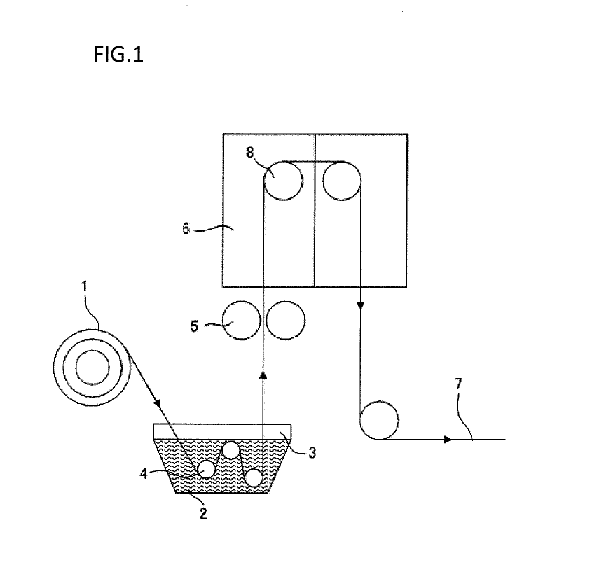

For example, as shown in FIG. 1, base material 1 is immersed in resin varnish 3 of impregnating bath 2 to impregnate base material 1 with resin varnish 3. In this case, base material 1 is immersed in resin varnish 3 by dipping roller 4 (three dipping rollers in FIG. 1) installed in impregnating bath 2. Next, base material 1 impregnated with resin varnish 3 is pulled out in a vertical direction and passed between a pair of squeeze rollers 5 or comma rollers, which are horizontally disposed to be faced each other, to control the coating amount of resin varnish 3 on base material 1. Thereafter, base material 1 coated with resin varnish 3 is heated at a given temperature in drier 6 to volatilize the solvent in the applied varnish and semi-cured the resin composition to produce prepreg 7. Upper rollers 8 in FIG. 1 rotate in the same direction as the travelling direction of prepreg 7 to convey prepreg 7 in the travelling direction. The solvent of the resin varnish impregnated with the base material is dried at a given temperature (e.g. from 90 to 180° C.), thereby, a semi-cured prepreg can be obtained.

### (Metal-Clad Laminate)

Next, the metal-clad laminate will be described.

The metal-clad laminate of the present invention comprises a resin-impregnated base material layer and a metal foil, wherein the metal foil is on at least one surface of the resin-impregnated base material layer, and the resin-impregnated base material layer comprises a base material impregnated with the resin composition.

The metal-clad laminate of the present invention can be produced by, for example, providing a metal foil on at least one surface of the prepreg or on at least one surface of a laminate comprising the stacked prepregs.

The heating temperature is not particularly limited, and is preferably 120 to 250° C., more preferably 120 to 220° C., still more preferably 150 to 220° C., particularly preferably 150 to 200° C. The pressure is not particularly limited, and is preferably 0.5 to 5 MPa. As needed, post-curing can be performed at a temperature of 150 to 300° C. in a basin with high temperature or the like.

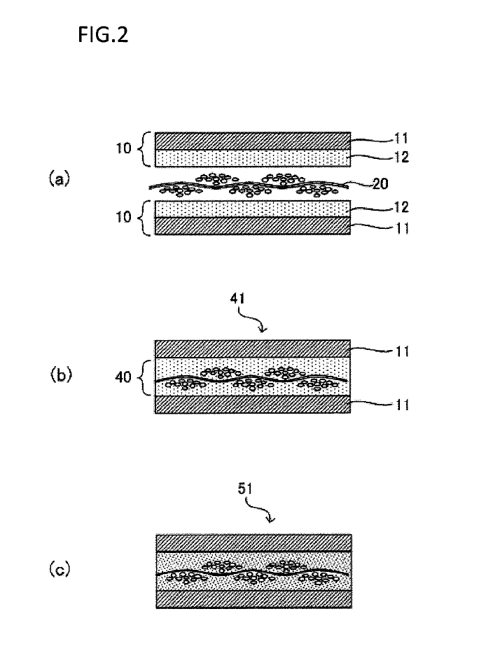

As another method for producing the metal-clad laminate of the present invention, as shown in FIG. 2, a method for producing a metal-clad laminate using a metal foil with an insulating resin layer can be exemplified. First, metal foils 10 with an insulating resin layer, each of which is metal foil 11 having uniform insulating resin layer 12 coated by means of a coater, are prepared. Next, base material 20 such as glass fiber is sandwiched with metal foils 10, 10 with the insulating resin layer by disposing the insulating resin layers facing inward (FIG. 2(a)). The laminate impregnation property is performed thereon under vacuum at a temperature of 60 to 130° C. and a pressure from 0.1 to 5 MPa to obtain prepreg 41 with metal foils (FIG. 2(b)). Then, the obtained prepreg 41 with the metal foils is formed by direct heat-pressing, thereby obtaining metal-clad laminate 51 (FIG. 2(c)).

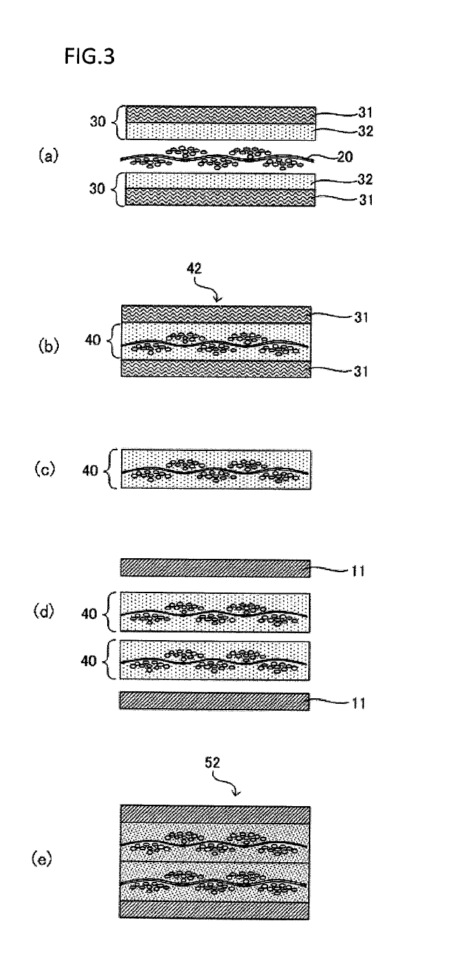

As another different method for producing the metal-clad laminate of the present invention, as shown in FIG. 3, a method for producing a metal-clad laminate using a polymer film sheet with an insulating resin layer can be also exemplified. First, polymer film sheets 30 with an insulating resin layer, each of which is polymer film sheet 31 having uniform insulating resin layer 32 coated by means of a coater, are prepared. Next, base material 20 is sandwiched with polymer film sheets 30, 30 with the insulating resin layer by disposing the insulating resin layers facing inward (FIG. 3(a)). The laminate impregnation property is performed thereon under vacuum at a temperature of 60 to 130° C. and a pressure from 0.1 to 5 MPa to obtain prepreg 42 with a polymer film sheet (FIG. 3(b)). Then, polymer film sheet 31 on at least one surface of prepreg 42 with the polymer film sheet is removed (FIG. 3(c)), and metal foil 11 is provided on the surface from which polymer film sheet 31 is removed (FIG. 3(d)) followed by heat-press forming, thereby obtaining metal-clad laminate 52 (FIG. 3(e)). In the case of removing the polymer film sheets on both surfaces of the prepreg, as with the above-described prepreg, it is possible to stack two or more prepregs. In the case of stacking two or more prepregs, metal foils or polymer film sheets are provided on both the outermost surfaces of the stack, or a metal foil or polymer film sheet is provided on one outermost surface of the stack. Then, the stack is formed by heat-pressing, thereby obtaining a metal-clad laminate. As the condition of heat press forming, the temperature is not particularly limited, and is preferably 120 to 250° C., more preferably 120 to 220° C., still more preferably 150 to 220° C., and the pressure is not particularly limited, and is preferably 0.1 to 5 MPa, more preferably 0.5 to 3 MPa. In the present invention, the prepreg with the base material is produced; therefore, the surface of the prepreg has high smoothness and the metal-clad laminate can be formed at a low pressure. In addition, post-curing can be performed, as needed, at a temperature of 150 to 300° C. in a bath with high temperature or the like.

The metal-clad laminate each in FIGS. 2 to 3 is produced by, for example, a device for producing the metal foil with the insulating resin layer and a device for producing the metal-clad laminate, but not limited thereto.

In the device for producing the metal foil with the insulating resin layer, as the metal foil, for example, a long sheet which is rolled into a roll, etc. is used. Therefore, the metal foil can be continuously unreeled from the roll and provided. A given amount of a liquid insulating resin is continuously provided on the metal foil by means of a device for providing the insulating resin. As the liquid insulating resin, a coating liquid obtained by dissolving the resin composition of the present invention in a solvent and dispersed is used. The coating amount of the insulating resin can be controlled by clearance between a comma roller and a backup roller of the comma roller. The metal foil on which a given amount of the insulating resin is applied is transferred through a horizontal conveyance type hot air drying machine to substantially dry and remove the organic solvent or the like contained in the liquid insulating resin, thereby obtaining a metal foil with an insulating resin layer which is semi-cured, as needed. The metal foil with the insulating resin layer can be rolled without any change. However, a metal foil with an insulating resin layer in the form of a roll can be obtained by providing a protection film on the side on which the insulating resin layer is formed by means of a laminating roller, and rolling the metal foil with the insulating resin layer on which the protection film is laminated.

The device for producing the metal-clad laminate is a device which can perform the steps (a) and (b) in FIG. 2. Examples of the device include devices disclosed in JP-A No. H8-150683, WO2007/040125, etc. In the device for producing the metal-clad laminate, the step (a) is performed by means of a laminating device. Inside the laminating device, the metal foil with the insulating resin layer obtained in the step (a) and the base material are installed so that each of them can be continuously supplied. Since the protection film is laminated on the surface of the insulating resin layer, the metal foil with the insulating resin layer is continuously supplied from the reeling roller while removing the protection film. In addition, the base material is continuously supplied from the base material in the form of a roll. The metal foils with the insulating resin layer are stacked in the form of sandwiching a fiber cloth between the insulating resin layer sides, and bound together by heat-pressing by means of a laminating roller. At this point, the insulating resin layer is an uncured product or semi-cured product containing almost no solvent; however, it is fluidized by thermal fusion and thus the base material is impregnated with the fluidized insulating resin layer. The resultant obtained after bonding is transferred to the subsequent step without any change, or the temperature and pressure are applied thereon by means of the laminating roller to control the bonding temperature of the metal foil with the insulating resin layer and base material. The resultant after bonding is transferred through the horizontal conveyance type hot air drying machine and heated at the temperature higher than the melting temperature of the insulating resin. Thereby, unfilling parts left inside the resultant can be vanished. The metal-clad laminate after heating is continuously rolled up while being interposed by a pinch roller to obtain a metal-clad laminate in the form of a roll. The lamination can be performed under ordinary pressure or vacuum. Preferred is under vacuum.

### (Printed Wiring Board)

Next, the printed wiring board of the present invention will be described.

The printed wiring board of the present invention comprises the metal-clad laminate as an inner layer circuit board.

The printed wiring board of the present invention comprises the prepreg and an inner layer circuit, wherein the prepreg is used as an insulating layer on the inner layer circuit.

The printed wiring board of the present invention comprises the resin composition and an inner layer circuit, wherein the resin composition is used as an insulating layer on the inner layer circuit.

In the present invention, the printed wiring board is a printed wiring board in which circuits are formed on the insulating layer using a conductor such as a metal foil. It can be any of a single-sided printed wiring board (single-layered board), a double-sided printed wiring board (double-layered board), and a multilayer printed wiring board (multilayer board). The multilayer printed wiring board is a printed wiring board in which three or more layers are laminated by a plated-through-hole method, a build-up method, etc., and can be obtained by providing insulating layers on an inner layer circuit board and heat-pressing them.

As the inner layer circuit board, for example, the following inner layer circuit board can be suitably used. The inner layer circuit is obtained by forming predetermined conducting circuits on the metal layer of the metal-clad laminate of the present invention by etching or the like, and performing black oxide treatment on the conducting circuits.

As the insulating layer, the prepreg of the present invention or a resin film comprising the resin composition of the present invention can be used. When the prepreg or the resin film comprising the resin composition is used as the insulating layer, the inner layer circuit board does not have to be an inner layer circuit board comprising the metal-clad laminate of the present invention.

Hereinafter, as a typical example of the printed wiring board of the present invention, a multilayer printed wiring board will be described, which uses the metal-clad laminate of the present invention as the inner layer circuit board, and the prepreg or resin sheet of the present invention as the insulating layer. As the insulating layer, commercially available resin sheets can be used.

The inner layer circuit board is produced by forming circuits on one or both surfaces of the metal-clad laminate. In some cases, both surfaces can be electrically connected by forming through holes by drill processing or laser processing and then plating the same, for example. The prepreg or the resin layer of the resin sheet is provided on the inner layer circuit board and heat-pressed to form an insulating layer. A multilayer printed wiring board can be obtained by alternately and repeatedly forming conducting circuit layers formed by etching or the like and the insulating layers in the same manner as above.

In particular, the prepreg or the resin layer of the resin sheet is provided on the inner layer circuit board. The thus-obtained stack is heat-pressed under vacuum by means of a vacuum press laminator or the like, and then the insulating layers are heat-cured by means of a hot air drying machine or the like. The heat-pressing condition is not particularly limited and can be a temperature of 60 to 160° C. and a pressure of 0.2 to 3 MPa, for example. The heat-curing condition is not particularly limited and can be a temperature of 140 to 240° C. and a time of 30 to 120 minutes, for example.

Alternatively, the prepreg or the resin layer of the resin sheet is provided on the inner layer circuit board. The thus-obtained stack is heat-pressed by means of a plate press machine or the like. The heat-pressing condition is not particularly limited and can be a temperature of 140 to 240° C. and a pressure of 1 to 4 MPa. In the heat-pressing by means of a plate press machine or the like, the heat-curing of the insulating layer is performed at the same time as the heat-pressing.

The curing of the insulating layer formed with the resin sheet or prepreg may be kept in the semi-cured state to make the exposure to laser and removal of resin residue (smear) in the following step easy, and to improve desmearing properties. Also, the adhesion between the insulating layers, and the adhesion between the insulating layer and the circuit can be improved by: heating the first insulating layer at lower temperature than general heating temperature so that the first layer is partly cured (semi-cured); one or more insulating layers are further formed on the semi-cured insulating layer; and the semi-cured insulating layer is subjected to the heat-curing again to the extent that there is practically no problem. The temperature of the semi-curing in this case is preferably 80 to 200° C., more preferably 100 to 180° C.

Next, the insulating layer is exposed to laser to form a hole(s). As the laser, excimer laser, UV laser, CO₂ laser or the like can be used.

Resin residue (smear) or the like left after the exposure to laser is preferably removed with an oxidant such as permanganate or bichromate, that is, it is preferable to perform a desmear treatment. If the desmear treatment is insufficient and thus desmear resistance is not sufficiently ensured, there is a possibility that even if the hole(s) is subjected to a metal plating process, electrical conduction between a upper layer metal wiring and a lower layer metal wiring is not sufficient due to the smear. The smooth surface of the insulating layer can be roughened by the desmear treatment at the same time, so that there is an increase in the adhesion of a conducting wiring circuit which will be formed by metal plating that follows.

In the case of forming the insulating layer using the resin sheet, the base material has to be removed. The timing for removing the base material is not particularly limited. For example, the removal of the base material can be performed before or after the heat-curing of the insulating layer, before or after the forming of the hole(s) by the exposure to laser, or before or after the desmear treatment. In the case that the base material of the resin sheet is a resin film, preferred timing for removing the base material is (1) heat-curing of insulating layer, removal of base material, forming of hole(s) by exposure to laser, desmear treatment, or (2) removal of base material, heat-curing of insulating layer, forming of hole(s) by exposure to laser, desmear treatment. In the case that the base material of the resin sheet is a metal foil, preferred timing for removing the base material is (1) heat-curing of insulating layer, forming of hole(s) by exposure to laser, desmear treatment, removal of base material, or (2) heat-curing of insulating layer, forming of hole(s) by exposure to laser, removal of base material, desmear treatment.

Next, an outer layer circuit is formed. In the forming of the outer layer circuit, the insulating layers are connected by metal plating and an outer layer circuit pattern is formed by etching.

An insulating layer can be further provided thereon and the circuit formation can be performed similarly as the above. In the multilayer printed wiring board, a solder resist layer is formed on the outermost layer after forming the circuit. The method for forming the solder resist layer is not particularly limited. The examples include a method comprising the steps of laminating a dry film solder resist on the circuit, exposing the same to light and developing the same, and a method comprising the steps of printing a liquid resist, exposing the same to light and developing the same. When the thus-obtained multilayer printed wiring board is used for a semiconductor device, an electrode part for connection is provided thereto, to which a semiconductor element is mounted. The electrode part for connection can be appropriately covered with a metal coating such as gold plating, nickel plating or solder plating.

As one of typical methods of the gold plating, a nickel-palladium-gold electroless plating method can be exemplified. This method comprising the steps of: subjecting the electrode part for connection to a pretreatment by appropriate methods such as cleaner, etc.; providing a palladium catalyst; and then successively performing an electroless nickel plating process, an electroless palladium plating process and an electroless gold plating process.

In the ENEPIG method, an immersion gold plating process is performed at the electroless gold plating process of the nickel-palladium-gold electroless plating method. By providing an electroless palladium plating coating between an electroless nickel plating coating being a base plating and an electroless gold plating coating, diffusion preventing property of the conductive material in the electrode part for connection and corrosion resistance can be improved. Since diffusion of the base nickel plating coating can be prevented, the reliability of Au—Au bonding improves. Also, since nickel oxidation by gold can be prevented, the reliability of lead-free solder bonding with high heat load improves. In the ENEPIG method, generally, it is necessary to perform the surface treatment before the electroless palladium plating process to prevent the occurrence of the conduction failure in the plating step. A significant conduction failure may cause a short between adjacent terminals. On the other hand, the printed wiring board of the present invention does not cause such a conduction failure even if the surface treatment is not performed, thus, the plating process can be easily performed.

### (Semiconductor Device)

Next, the semiconductor device of the present invention will be described.

On the above-obtained printed wiring board, a semiconductor element having a solder bump is mounted and connected to the printed wiring board through the solder bump. Then, a liquid encapsulating resin is filled between the printed wiring board and the semiconductor element, thereby forming a semiconductor device. The solder bump is preferably made of alloy comprising tin, lead, silver, copper, bismuth or the like.

A method for connecting the semiconductor element with the printed wiring board is as follows. The position of an electrode part for connection on the board is aligned with that of the solder bump of the semiconductor element by means of a flip chip bonder, etc., and the solder bump is heated to a temperature higher than the melting point by means of an IR reflow apparatus, a hot plate or any other heating apparatus to fusion-bond the printed wiring board and the solder bump together, thereby connecting the semiconductor element with the printed wiring board. For better connection reliability, a layer of relatively-low-melting-point metal, such as a solder paste, can be preliminarily formed on the electrode part for connection on the printed wiring board. Connection reliability can be also increased by applying a flux on the solder bump and/or the surface of the electrode part for connection on the printed wiring board before the above connecting process.

### EXAMPLES

Hereinafter, the present invention will be described in detail with reference to examples and comparative examples. However, the present invention is not limited thereto.

### Example A Series

Examples using the first resin composition will be described below.

### Example A1

### (1) Preparation of Varnish Containing Resin Composition (Resin Varnish)

The following were dissolved in methyl isobutyl ketone and mixed: 17.5% by weight of a novolac type epoxy resin (product name: EOCN-1020-75; manufactured by: Nippon Kayaku Co., Ltd.; epoxy equivalent: 200) as an epoxy resin, 61.4% by weight of boehmite (product number: BMT-3L; manufactured by: Kawai Lime Industry Co., Ltd.; average particle diameter: 2.9 μm; 1% weight-loss thermal decomposition temperature: 420° C.) as a first inorganic filler, 3.5% by weight of a spherical nanosilica (product number: NSS-5N; manufactured by: Tokuyama Corporation; average particle diameter: 70 nm) as a second inorganic filler, 17.5% by weight of a phenol resin (product name: MEH7851-4L; manufactured by: Meiwa Plastic Industries, Ltd; hydroxyl group equivalent: 187) as a curing agent, and 0.1% by weight of imidazole (product number: 2E4MZ; manufactured by: Shikoku Chemicals Corporation) as an accelerator. Then, the thus-obtained mixture was agitated by means of a high speed agitator, thereby obtaining a resin varnish (W2/W1=0.06).

### (2) Production of Prepreg

A glasswoven fabric (product name: F glass woven fabric WEA-2116; manufactured by: Nitto Boseki Co., Ltd.; thickness: 94 μm) was impregnated with the resin varnish and dried with a heating furnace at 150° C. for 2 minutes, thereby obtaining a prepreg having a varnish solid content of about 50% by weight.

### (3) Production of Metal-Clad Laminate

Four prepregs obtained above were stacked. The stack was sandwiched by copper foils having a thickness of 12 μm (product name: 3EC-VLP foil; manufactured by: Mitsui Mining & Smelting Co., Ltd.) and heat-pressed at a temperature of 220° C. and a pressure of 3 MPa for 2 hours, thereby obtaining a copper-clad laminate having a thickness of 0.40 mm with copper foils on both surfaces thereof.

### (4) Production of Printed Wiring Board

After providing an hole(s) by means of a drilling machine on the metal-clad laminate having copper foils on both surfaces thereof, the copper foils were conducted each other by electroless plating and further subjected to etching, thereby inner layer circuits [L (width of conducting circuit)/S (width between conducting circuits)=120/180 μm; clearance holes: 1 mmp and 3 mmφ; slit: 2 mm] were formed on both surfaces of the metal-clad laminate.

Next, a medicinal solution (product name: TEC SO-G; manufactured by: Asahi Denka Co., Ltd.) mainly containing hydrogen peroxide solution and sulfuric acid was sprayed on the inner layer circuits. By this roughening treatment, convexoconcaves were formed.

Commercially available resin films (also called as buildup materials) (product name: ABF GX-13; manufactured by: Ajinomoto Fine-Techno Co., Inc.; thickness: 40 μm) were laminated on the inner layer circuits by means of a vacuum laminating device. Then, the thus-obtained laminate was heat-cured at 170° C. for 60 minutes, thereby obtaining a laminate having insulating layers.

Next, a hole(s) (blind via hole) having a size of φ60 μm was formed on the prepreg of the above obtained laminate by means of a carbon dioxide gas laser device (product name: LG-2G212; manufactured by: Hitachi Via mechanics, Ltd.). Such a laminate was immersed in a swelling agent (product name: Swelling Dip Securiganth P; manufactured by: Atotech Japan K.K.) at 70° C. for 5 minutes, further immersed in a potassium permanganate aqueous solution (product name: Concentrate Compact CP; manufactured by: Atotech Japan K.K.) at 80° C. for 15 minutes, and neutralized to perform roughening treatment.

After degreasing, providing catalyst and activation, an electroless copper plating coating having a thickness of about 0.5 μm was formed as a feeding layer. An ultraviolet photosensitive dry film (product name: AQ-2558; manufactured by: ASAHI KASEI CORPORATION) having a thickness of 25 μm was attached on the surface of the feeding layer by means of a hot roll laminator, and the position of the ultraviolet photosensitive dry film and that of a chrome vapor deposition mask (manufactured by: Towa process Co., Ltd.) in which the pattern of which has a minimum line width/line space of 20/20 μm was drawn were aligned.

Then, the film was exposed to light by an exposure equipment (product name: UX-1100SM-AJN01; manufactured by: USHIO INC.) and developed by an aqueous solution of sodium carbonate, thus plating resist was formed.

Electrolytic copper plating (product name: 81-HL; manufactured by: Okuno Chemical Industries Co., Ltd.) was performed at 3 A/dm² for 30 minutes using the feeding layer as the electrode to form a copper wiring having a thickness of about 25 μm. At this stage, the plating resist was peeled using a two-step peeler. Each medicinal solution used herein includes a mono-ethanolamine solution (product name: R-100; manufactured by: MITSUBISHI GAS CHEMICAL COMPANY, INC.) for a layer of an alkaline aqueous solution in the first step, an aqueous solution mainly containing potassium permanganate and sodium hydroxide (product name: Macudizer 9275 and 9276; manufactured by: Mac Dermid) for an etching agent of oxidizing resin in the second step, and an aqueous solution of acid amine (product name: Macudizer 9279; manufactured by: Mac Dermid) for neutralization.

Next, the feeding layer was removed by etching, in which the feeding layer was dipped in an aqueous solution of ammonium persulfate (product name: AD-485; manufactured by: Meltex Inc.), to ensure insulation between wirings. Then, final curing of the insulating layers was performed at 200° C. for 60 minutes. Finally, a solder resist (product name: PSR4000/AUS308; manufactured by: TAIYO INK MFG. CO., LTD.) was formed on the surface of the circuit. Thus, a multilayer printed wiring board was obtained.

### (5) Production of Semiconductor Device

The printed wiring board, wherein electrode parts for connection subjected to a nickel-gold plating process corresponding to solder bumps alignment of the semiconductor element are mounted, was cut into a size of 50 mm×50 mm and used.

The semiconductor element (TEG chip having a size of 15 mm×15 mm and a thickness of 0.8 mm) which has solder bumps formed of a Sn/Pb eutectic, and the circuit protection film of which is formed of a positive photosensitive resin (product name: CRC-8300; manufactured by: Sumitomo Bakelite Co., Ltd.) were used.

The assembly of the semiconductor device was carried out as follows. At first, a flux material was uniformly applied on the solder bumps by a transfer method. Then, the solder bumps were mounted on the printed wiring board by heat-press bonding with a flip chip bonder. Next, the solder bumps were fusion-bonded with an IR reflow furnace, followed by filling and curing a liquid encapsulating resin (product name: CRP-4152S; manufactured by: Sumitomo Bakelite Co., Ltd.). Thus, a semiconductor device was obtained. The liquid encapsulating resin was cured under the condition of heating at 150° C. for 120 minutes.

### Example A2

Example A2 was performed similarly as in Example A1 except that the resin varnish was compounded as follows:

17.5% by weight of a phenol novolac cyanate resin (product name: Primaset PT-30; manufactured by: Lonza Japan, Ltd.) as a cyanate resin, 9.5% by weight of a biphenyldimethylene type epoxy resin (product name: NC3000; manufactured by: Nippon Kayaku Co., Ltd.; epoxy equivalent: 275) as an epoxy resin, 61.4% by weight of boehmite (product number: BMT-3L; manufactured by: Kawai Lime Industry Co., Ltd.; average particle diameter: 2.9 μm; 1% weight-loss thermal decomposition temperature: 420° C.) as a first inorganic filler, 3.5% by weight of a spherical nanosilica (product number: NSS-5N; manufactured by: Tokuyama Corporation; average particle diameter: 70 nm) as a second inorganic filler, and 8.1% by weight of a phenol resin (product name: MEH7851-4L; manufactured by: Meiwa Plastic Industries, Ltd.; hydroxyl group equivalent: 187) as a curing agent (W2/W1=0.06).

### Example A3

Example A3 was performed similarly as in Example A1 except that that resin varnish was compounded as follows:

17.5% by weight of a phenol novolac cyanate resin (product name: Primaset PT-30; manufactured by: Lonza Japan, Ltd.) as a cyanate resin, 9.5% by weight of a biphenyldimethylene type epoxy resin (product name: NC3000; manufactured by: Nippon Kayaku Co., Ltd.; epoxy equivalent: 275) as an epoxy resin, 31.6% by weight of boehmite (product number: BMT-3L; manufactured by: Kawai Lime Industry Co., Ltd.; average particle diameter: 2.9 μm; 1% weight-loss thermal decomposition temperature: 420° C.) as a first inorganic filler, 3.5% by weight of a spherical nanosilica (product number: NSS-5N; manufactured by: Tokuyama Corporation; average particle diameter: 70 nm) as a second inorganic filler, 29.8% by weight of a spherical silica (product name: SO-31R; manufactured by: Admatechs Company Limited; specific surface area: 4.5 m²/g; average particle diameter: 1.2 μm) as a third inorganic filler, and 8.1% by weight of a phenol resin (product name: MEH7851-4L; manufactured by: Meiwa Plastic Industries, Ltd.; hydroxyl group equivalent: 187) as a curing agent (W2/W1=0.11, W2/W3=0.12).

### Example A4

Example A4 was performed similarly as in Example A3 except that the following was used as the second inorganic filler.

As the second inorganic filler, a spherical nanosilica (product name: Admanano; manufactured by: Admatechs Company Limited; average particle diameter: 50 nm; 40 wt % cyclohexanone slurry) was used (W2/W1=0.11, W2/W3=0.12). The cyclohexanone slurry was compounded in dry weight equivalent of the spherical nanosilica.

### Example A5

Example A5 was performed similarly as in Example A3 except that the following was used as second inorganic filler.

As the second inorganic filler, a spherical nanosilica (product name: Admanano; manufactured by: Admatechs Company Limited; average particle diameter: 25 nm; 30 wt % ANON slurry) was used (W2/W1=0.11,W2/W3=0.12). The cyclohexanone (ANON) slurry was compounded in dry weight equivalent of the spherical nanosilica.

### Example A6

Example A6 was performed similarly as in Example A3 except that the following was used as the second inorganic filler.

As the second inorganic filler, a spherical nanosilica (product number: PL-1; manufactured by: Fuso Chemical Co., Ltd.; average particle diameter: 15 nm; 12 wt % ANON slurry) was used (W2/W1=0.11, W2/W3=0.12). The cyclohexanone (ANON) slurry was compounded in dry weight equivalent of the spherical nanosilica.

### Example A7

Example A7 was performed similarly as in Example A3 except that the following was used as the first inorganic filler.

As the first inorganic filler, aluminum hydroxide (product number: ALH-3L; manufactured by: Kawai Lime Industry Co., Ltd.; average particle diameter: 4.5 μm; 1% weight-loss thermal decomposition temperature: 280° C.) was used (W2/W1=0.11, W2/W3=0.12).

### Example A8

Example A8 was performed similarly as in Example A3 except that the following was used as the first inorganic filler.

As the first inorganic filler, talc (product number: LMS-400; manufactured by: Fuji Talc Industrial Co., Ltd.; average particle diameter: 3.8 μm: 1% weight-loss thermal decomposition temperature: 375° C.) was used (W2/W1=0.11, W2/W3=0.12).

### Example A9

Example A9 was performed similarly as in Example A3 except that the following was used as the epoxy resin.

As the epoxy resin, a naphthalene-modified cresol novolac epoxy resin (product name: HP-5000; manufactured by: DIC CORPORATION; epoxy equivalent: 250) was used (W2/W1=0.11, W2/W3=0.12).

### Example A10

Example A10 was performed similarly as in Example A3 except that the following was used as the epoxy resin.

As the epoxy resin, an anthracene type epoxy resin (product name: YX8800; manufactured by: Japan Epoxy Resins Co., Ltd.; epoxy equivalent: 181) was used (W2/W1=0.11, W2/W3=0.12).

### Example A11

Example A1 was performed similarly as in Example A1 except that resin varnish was compounded as follows:

17.5% by weight of a phenol novolac cyanate resin (product name: Primaset PT-30; manufactured by: Lonza Japan, Ltd.) as a cyanate resin, 9.5% by weight of a biphenyldimethylene type epoxy resin (product name: NC3000; manufactured by: Nippon Kayaku Co., Ltd.; epoxy equivalent: 275) as an epoxy resin, 21.1% by weight of boehmite (product number: BMT-3L; manufactured by: Kawai Lime Industry Co., Ltd.; average particle diameter: 2.9 μm; 1% weight-loss thermal decomposition temperature: 420° C.) as a first inorganic filler, 10.5% by weight of a spherical nanosilica (product number: NSS-5N; manufactured by: Tokuyama Corporation; average particle diameter: 70 nm) as a second inorganic filler, 33.3% by weight of a spherical silica (product name: SO-31R; manufactured by: Admatechs Company Limited; specific surface area: 4.5 m²/g; average particle diameter: 1.2 μm) as a third inorganic filler, and 8.1% by weight of a phenol resin (product name: MEH7851-4L; manufactured by: Meiwa Plastic Industries, Ltd; hydroxyl group equivalent: 187) as a curing agent (W2/W1=0.5, W2/W3=0.32).

### Example A12

Example A12 was performed similarly as in Example A1 except that resin varnish was compounded as follows:

17.5% by weight of a phenol novolac cyanate resin (Product name: Primaset PT-30; manufactured by: Lonza Japan, Ltd.) as a cyanate resin, 9.5% by weight of a biphenyldimethylene type epoxy resin (product name: NC 3000; manufactured by: Nippon Kayaku Co., Ltd.; epoxy equivalent: 275) as an epoxy resin, 45.6% by weight of boehmite (product number: BMT-3L; manufactured by: Kawai Lime Industry Co., Ltd.; average particle diameter: 2.9 μm; 1% weight-loss thermal decomposition temperature: 420° C.) as a first inorganic filler, 10.5% by weight of a spherical nanosilica (product number: NSS-5N; manufactured by: Tokuyama Corporation; average particle diameter: 70 nm) as a second inorganic filler, 8.8% by weight of a spherical silica (product name: SO-31R; manufactured by: Admatechs Company Limited; specific surface area: 4.5 m²/g; average particle diameter; 1.2 μm) as a third inorganic filler, and 8.1% by weight of a phenol resin (product name: MEH7851-4L; manufactured by: Meiwa Plastic Industries, Ltd; hydroxyl group equivalent: 187) as a curing agent (W2/W1=0.23, W2/W3=1.2).

### Comparative Example A1

Comparative example A1 was performed similarly as in Example A1 except that resin varnish was compounded as follows without using the second inorganic filler:

17.5% by weight of a phenol novolac cyanate resin (product name: Primaset PT-30; manufactured by: Lonza Japan, Ltd.) as a cyanate resin, 9.5% by weight of a biphenyldimethylene type epoxy resin (product name: NC3000; manufactured by: Nippon Kayaku Co., Ltd.; epoxy equivalent: 275) as an epoxy resin, 56.1% by weight of boehmite (product number: BMT-3L; manufactured by: Kawai Lime Industry Co., Ltd.; average particle diameter: 2.9 μm; 1% weight-loss thermal decomposition temperature: 420° C.) as a first inorganic filler, 8.8% by weight of a spherical silica (product name: SO-31R; manufactured by: Admatechs Company Limited; specific surface area: 4.5 m²/g; average particle diameter: 1.1 μm) as a third inorganic filler, and 8.1% by weight of a phenol resin (product name: MEH7851-4L; manufactured by: Meiwa Plastic Industries, Ltd; hydroxyl group equivalent: 187) as a curing agent.

### Comparative Example A2

Comparative example A2 was performed similarly as in Example A1 except that the resin varnish was compounded as follows without using the first inorganic filler:

17.5% by weight of a phenol novolac cyanate resin (product name: Primaset PT-30; manufactured by: Lonza Japan, Ltd.) as a cyanate resin, 9.5% by weight of a biphenyldimethylene type epoxy resin (product name: NC3000; manufactured by: Nippon Kayaku Co., Ltd.; epoxy equivalent: 275) as an epoxy resin, 10.5% by weight of a spherical nanosilica (product number: NSS-5N; manufactured by: Tokuyama Corporation; average particle diameter: 70 nm) as a second inorganic filler, 54.4% by weight of a spherical silica (product name: SO-31R; manufactured by: Admatechs Company Limited; specific surface area: 4.5 m²/g; average particle diameter: 1.1 μm) as a third inorganic filler, and 8.1% by weight of a phenol resin (product name: MEH7851-4L; manufactured by: Meiwa Plastic Industries, Ltd; hydroxyl group equivalent: 187) as a curing agent (W2/W3=0.19).

The resin varnish, printed wiring board and semiconductor device obtained in each of Examples and Comparative examples were evaluated for the following items. The items and contents of evaluation are as below. The obtained results are shown in Table A1.

### (1) Thixotropy

The thixotropy of the resin varnish was measured in accordance with JIS K7117-2 by means of an E type viscometer (cone-plate rotational viscometer). In particular, 1 ml of a resin varnish was placed in the middle of a measurement cup to measure the viscosity of the resin varnish. Then, viscosity ratio (5 rpm/20 rpm) was evaluated.

### (2) Sedimentation Property of Filler

After producing the resin varnish, it was poured into a 100 cc measuring cylinder up to a height of 10 cm and left for 24 hours. Then, the length (cm) of the separated transparent part was visually observed. Sedimentation property of filler was evaluated by the calculation of (10-transparent part length)/10×100%.

### (3) Resin Flowability

The resin flowability was evaluated as follows. A test sample was heat-pressed at a temperature of 170° C. and a pressure of 15 kgf/cm² for 5 minutes in accordance with JIS 06521, and the amount of resin flowing was measured. The test sample was obtained by casting the varnish obtained in Example on the roughened surface of the copper foil having a thickness of 12 μm, drying the same at 150° C. for 5 minutes, and laminating the thus-obtained 5 resin films with a copper foil having a thickness of 30 μm.

### (4) Prepreg Impregnation Property

The impregnation property of the resin varnish in the prepreg was evaluated as follows. The prepreg produced the above was cured in a hot-air oven at 180° C. for 1 hour, and then 35 cross-sections obtained at intervals of 15 mm in a width direction of 530 mm were observed. In the cross-sectional observation, the presence of voids which were not impregnated with the resin (unimpregnated void) was observed by means of a scanning electron microscope. Symbols shown in Table A1 refer to the following:

[symbol]

: No unimpregnated void was observed in all the cross sections.
∘: Unimpregnated voids were observed in 1 or more and less than 5 cross sections, but the prepreg was at practicable level.
Δ: Unimpregnated voids were observed in 5 or more and less than 30 cross sections, and the prepreg was not at practicable level.
x: Unimpregnated voids were observed in 30 or more cross sections, and the prepreg was not at practicable level.

### (5) Formability

Four prepregs obtained the above were stacked. The stack was sandwiched by copper foils having a thickness of 12 μm (product name: 3EC-VLP foil; manufactured by: Mitsui Mining & Smelting Co., Ltd.) and heat-pressed at a temperature of 220° C. and a pressure of 3 MPa for 2 hours, thereby obtaining a metal-clad laminate having a thickness of 0.40 mm with copper foils on both surfaces thereof. The pressure was raised up to 3 MPa in 5 minutes at 120° C.

After removing the whole surface of the copper foil of the obtained laminate (510 mm×510 mm) by etching, formability of the laminate was visually evaluated. Symbols shown in Table A1 refer to the following:

[symbol]

: No void was observed.
∘: Void of less than 10 μm was observed only at 10 mm end of the laminate, but the laminate was at practicable level.
Δ: Void of more than 10 μm was observed, and the laminate was not at practicable level.
x: Many voids were observed, and the laminate was not at practicable level.

### (6) Heat Resistance

Heat resistance of the semiconductor device was evaluated with a multiple reflow at 260° C.

In particular, the above-obtained semiconductor device was passed through a reflow furnace at 260° C. in accordance with J-STD-20 of IPC/JEDEC. Peeling of the insulating layer of the semiconductor device, crack, peeling of the back side of the semiconductor element, and defect of the solder bump were evaluated every 10 times of pass by means of an ultrasonic testing equipment. In addition, conduction failure on the hot plate at 125° C. were evaluated every 10 times of pass. Symbols shown in Table A1 refer to the following:

[symbol]

: No peeling of insulating layer, etc. and conduction failure was observed after 40 or more passes.
∘: No peeling of insulating layer, etc. and conduction failure was observed after 20 or more and less than 40 passes.
Δ: Peeling of insulating layer, etc. and conduction failure were observed after 10 or more and less than 20 passes.
x: Peeling of insulating layer, etc. and conduction failure were observed after less than 10 passes.

### (7) Linear Thermal Expansion Coefficient

The copper foil of the obtained metal-clad laminate was removed by etching. Then, a test piece of 4 mm×40 mm (thickness: 100 μm) was taken from the metal-clad laminate and measured for linear thermal expansion coefficient in the range of 25° C. to 150° C. by means of a TMA device (manufactured by: TA Instruments), increasing the temperature at 5° C./minute.

(8) Permeation of Plating after Drill Processing

Permeation of plating after drill processing was evaluated as follows. First, two sheets of the laminate having a thickness of 0.4 mm were stacked, and drill processing was performed three thousand times by means of a drill having a diameter of 0.2 mm. Then, through hole plating having a thickness of 25 μm was performed on the above obtained holes, thereby forming through holes. The permeation depth of a plating solution from an inner wall of each of the through hole into the laminate was measured. Using the drill (product number: KMC L253; manufactured by: Union Tool Co.), drill spindle speed was 250 krpm/min upon forming the holes, and drill chipload was 9.6 μm/rev. Symbols shown in Table A1 refer to the following:

[symbol]

: Permeation depth was less than 20 μm (good).
∘: Permeation depth was 20 μm or more and less than 50 μm (practically no problem).
Δ: Permeation depth was 50 μm or more and less than 100 μm (practically unusable).
x: Permeation depth was 100 μm or more (unusable).

### (9) Through Hole Insulation Reliability

In the condition similarly as the drill processing in (8), through hole insulation reliability of the sample subjected to through hole processing, through hole plating and circuit processing was evaluated as follows. In particular, a voltage of 20 V was applied between through holes, which have a 0.2 mm interval between the inner surfaces thereof, under 130° C. and 85% humidity, and the time until insulation resistance was reduced to Less than 10⁸Ω was continuously measured.

Symbols shown in Table A1 refer to the following:

[symbol]

: 500 hours or more until insulation resistance was less than 10⁸Ω (good).
∘: 200 hours or more and less than 500 hours until insulation resistance was less than 10⁸Ω (practically no problem).
Δ: 100 hours or more and less than 200 hours until insulation resistance was less than 10⁸∘ (practically unusable).
x: Less than 100 hours until insulation resistance was less than 10⁸Ω (unusable).

### (10) Warpage of Printed Wiring Board Section (Package) of Semiconductor Device

Warpage of the printed wiring board section (package) of the semiconductor device produced above was measured as follows.

The semiconductor device was put on a heatable and coolable chamber, with chip side (semiconductor element side) down. The device was exposed in atmospheres of −50° C. and 125° C. Then, the change in warpage of the printed wiring board section in the range of 48 mm×48 mm was measured in the state that the printed wiring board (size: 50 mm×50 mm) on the back side of the semiconductor device was up, that is, BGA side was up. Symbols shown in Table A1 refer to the following:

[symbol]

: Change in warpage was less than 200 μm (good).
∘: Change in warpage was 200 μm or more and less than 300 μm (practically no problem).
Δ: Change in warpage was 300 μm or more and less than 350 μm (practically unusable).
x: Change in warpage was 350 μm or more (unusable).

### (11) Flame Resistance

10 prepregs obtained above were stacked. The stack was sandwiched by copper foils having a thickness of 12 μm and heat-pressed at a temperature of 220° C. and a pressure of 3 MPa for 2 hours, thereby obtaining a double-sided copper-clad laminate having a thickness of 0.12 mm. The copper foils of the above-obtained copper-clad laminate were subjected to etching, and flame resistance of a test piece having a thickness of 1.0 mm was measured by a vertical method in accordance with UL-94 standard. In Table A1, “V-0” means that the requirement of V-0 in UL-94 standard was satisfied.

TABLE A1

| | | | | | | | | | | | | | | Comparative | |
|---|---|---|---|---|---|---|---|---|---|---|---|---|---|---|---|
| | | Examples | | | | | | | | | | | | examples | |
| | | A1 | A2 | A3 | A4 | A5 | A6 | A7 | A8 | A9 | A10 | A11 | A12 | A1 | A2 |
| Cyanate | Phenol novolac | | 17.5 | 17.5 | 17.5 | 17.5 | 17.5 | 17.5 | 17.5 | 17.5 | 17.5 | 17.5 | 17.5 | 17.5 | 17.5 |
| resin | | | | | | | | | | | | | | | |
| Epoxy resin | Novolac type epoxy resin | 17.5 | | | | | | | | | | | | | |
| | Biphenyldimethylene type | | 9.5 | 9.5 | 9.5 | 9.5 | 9.5 | 9.5 | 9.5 | | | 9.5 | 9.5 | 9.5 | 9.5 |
| | epoxy resin | | | | | | | | | | | | | | |
| | Naphthalene-modified cresol | | | | | | | | | 9.5 | | | | | |
| | novolac epoxy resin | | | | | | | | | | | | | | |
| | Glycidylamines | | | | | | | | | | | | | | |
| | Anthracene type epoxy resin | | | | | | | | | | 9.5 | | | | |
| First | Boehmite | 61.4 | 61.4 | 31.6 | 31.6 | 31.6 | 31.6 | | | 31.6 | 31.6 | 21.1 | 45.6 | 56.1 | |
| inorganic | Aluminum hydroxide | | | | | | | 31.6 | | | | | | | |
| filler | (Heat-resistant aluminum | | | | | | | | | | | | | | |
| | hydroxide) | | | | | | | | | | | | | | |
| | Talc | | | | | | | | 31.6 | | | | | | |
| Second | Spherical nanosilica | 3.5 | 3.5 | 3.5 | | | | 3.5 | 3.5 | 3.5 | 3.5 | 10.5 | 10.5 | | 10.5 |
| inorganic | (average particle: 70 nm) | | | | | | | | | | | | | | |
| filler | Spherical nanosilica | | | | 3.5 | | | | | | | | | | |
| | (average particle: 50 nm) | | | | | | | | | | | | | | |
| | Spherical nanosilica | | | | | 3.5 | | | | | | | | | |
| | (average particle: 25 nm) | | | | | | | | | | | | | | |
| | Spherical nanosilica | | | | | | 3.5 | | | | | | | | |
| | (average particle: 15 nm) | | | | | | | | | | | | | | |
| Third | Spherical silica | | | 29.8 | 29.8 | 29.8 | 29.8 | 29.8 | 29.8 | 29.8 | 29.8 | 33.3 | 8.8 | 8.8 | 54.4 |
| inorganic filler | (average particle: 1.2 μm) | | | | | | | | | | | | | | |
| Phenol | Phenol resin | 17.5 | 8.1 | 8.1 | 8.1 | 8.1 | 8.1 | 8.1 | 8.1 | 8.1 | 8.1 | 8.1 | 8.1 | 8.1 | 8.1 |
| curing agent | | | | | | | | | | | | | | | |
| Accelerator | Imidazole | 0.1 | | | | | | | | | | | | | |
| Evaluation | (1) Thixotropic ratio | 1.1 | 1.2 | 1.1 | 0.9 | 1.2 | 1.3 | 1.0 | 1.3 | 1.0 | 1.1 | 0.9 | 1.1 | 2.5 | 1.1 |
| results | (2) Filer sedimentation | 70 | 68 | 60 | 30 | 90 | 100 | 58 | 50 | 62 | 58 | 120 | 58 | 30 | 60 |
| | (3) Resin flowability | 56 | 60 | 65 | 55 | 50 | 45 | 60 | 45 | 65 | 60 | 50 | 45 | 20 | 50 |
| | (4) Prepreg impregnation | [symbol] | [symbol] | [symbol] | [symbol] | ∘ | ∘ | [symbol] | ∘ | [symbol] | [symbol] | [symbol] | [symbol] | x | ∘ |
| | property | | | | | | | | | | | | | | |
| | (5) Formability | [symbol] | [symbol] | [symbol] | [symbol] | ∘ | ∘ | [symbol] | ∘ | [symbol] | [symbol] | [symbol] | [symbol] | x | ∘ |
| | (6) Heat resistance | ∘ | [symbol] | [symbol] | [symbol] | [symbol] | [symbol] | ∘ | [symbol] | [symbol] | ∘ | [symbol] | [symbol] | Δ | [symbol] |
| | (CCL260° C. multi reflow) | | | | | | | | | | | | | | |
| | (7) Linear thermal expansion | 10 | 9 | 9 | 9 | 9 | 9 | 10 | 10 | 9 | 9 | 9 | 9 | 10 | 9 |
| | coefficient | | | | | | | | | | | | | | |
| | (8) Permeation of plating | ∘ | ∘ | ∘ | ∘ | ∘ | ∘ | [symbol] | [symbol] | ∘ | [symbol] | ∘ | [symbol] | Δ | x |
| | after drill processing | | | | | | | | | | | | | | |
| | (9) TH insulation reliability | [symbol] | [symbol] | [symbol] | [symbol] | [symbol] | [symbol] | [symbol] | [symbol] | [symbol] | [symbol] | [symbol] | [symbol] | Δ | x |
| | (10) PKG warpage | ∘ | [symbol] | [symbol] | [symbol] | [symbol] | [symbol] | ∘ | ∘ | [symbol] | [symbol] | [symbol] | [symbol] | x | Δ |
| | (11) Flame resistance | V-0 | V-0 | V-0 | V-0 | V-0 | V-0 | V-0 | V-0 | V-0 | V-0 | V-0 | V-0 | V-0 | V-0 |

As is clear from Table A1, the resin composition obtained in each of Examples A1 to A12 had excellent flowability, and the occurrence of the warpage upon forming the laminate (multilayer printed wiring board) was prevented.

The resin varnish obtained in each of Examples A1 to A12 had excellent thixotropy and filler sedimentation. Therefore, the resin varnishes had excellent mass production stability and impregnation property in the prepreg. Also, the resin varnishes had excellent resin flowability, so that formability was excellent upon producing the laminate even if the resin varnish contains high amount of the inorganic filler. Furthermore, the printed wiring boards produced using the resin varnishes had excellent heat resistance, low linear thermal expansion and drill processability. Therefore, the printed wiring boards had excellent through hole insulation reliability and small amount of PKG warpage since they had low linear thermal expansion.

To the contrary, the resin varnish obtained in Comparative example A1 had high thixotropic ratio, and poor impregnation property and resin flowability in the prepreg. Therefore, the resin varnish had poor formability, heat resistance and through hole insulation reliability. The printed wiring board in Comparative example A2 had poor drill processability; therefore, it had poor through hole insulation reliability.

### Example B Series

Examples using the second resin composition will be described below.

### Example B1

### (1) Preparation of Varnish Containing Resin Composition

First, 26.4% by weight of a silicone rubber particle (product name: KMP-600; manufactured by: Shin-Etsu Chemical Co., Ltd.; average particle diameter: 5 μm), 18.2% by weight of a boehmite particle (product name: AOH-30; manufactured by: TESCO Co., Ltd.; average particle diameter: 1.8 μm), and 2.4% by weight of a silica nanoparticle (product name: NSS-5N; manufactured by: Tokuyama Corporation; average particle diameter: 70 nm) were dispersed in a solvent (ANON: MIBK=1:1 (v/v)) to prepare a slurry having a concentration of 65% by weight.

Next, the following were dissolved in the thus-obtained slurry and mixed: 25.4% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 21.2% by weight of a cyanate resin (product name: PT30; manufactured by: Lonza Japan, Ltd.; novolac type cyanate resin; weight-average molecular weight: 380), and 6.4% by weight of a phenol resin (product name: GPH-103; manufactured by: Nippon Kayaku Co., Ltd.; biphenylaralkyl type phenol resin) as a curing agent. Then, the thus-obtained mixture was agitated by means of a high speed agitator, thereby obtaining a resin varnish having a solid content of 70% by weight.

### (2) Production of Prepreg

A glass woven fabric (product name: E glass woven fabric WEA-2116; manufactured by: Nitto Boseki Co., Ltd.; thickness: 94 μm) was impregnated with the resin varnish and dried with a heating furnace at 180° C. for 2 minutes, thereby obtaining a prepreg having a varnish solid content of about 49% by weight.

### (3) Production of Metal-Clad Laminate

A double-sided metal-clad laminate having a thickness of 0.130 mm was obtained similarly as in Example A1 using the obtained prepreg.

### (4) Production of Printed Wiring Board

After forming inner layer circuits [L (μm) (width of conducting circuit/S (μm) (width between conducting circuits)=50/50] on both surfaces of the obtained double-sided metal-clad laminate similarly as in Example A1, convexoconcaves were formed on the inner layer circuits by roughening treatment.

Next, the prepreg was laminated on the inner layer circuit by means of a vacuum laminating device. Then, the thus-obtained laminate was heat-cured at 170° C. for 60 minutes, thereby obtaining a laminate.

Thereafter, a printed wiring board was produced similarly as in Example A1 using the thus-obtained laminate.

In the thus-obtained printed wiring board, the ENEPIG process is performed on the electrode parts for connection corresponding to solder bumps alignment of the semiconductor element. The ENEPIG process was performed in the following steps [1] to [8].

Metal precipitate between thin lines on the printed wiring board produced by the ENEPIG process was observed by SEM and confirmed.

### [1] Cleaner Process

The test piece was dipped in a cleaner solution (product name: ACL-007; manufactured by: C. Uyemura & Co., Ltd.) at 50° C. for 5 minutes followed by water washing for three times.

### [2] Soft Etching Process

After the cleaner process, the test piece was dipped in a soft etching solution, which is a mixed solution of sodium persulfate and sulfuric acid, at 25° C. for 1 minute followed by water washing for three times.

### [3] Acid Cleaning Process

After the soft etching process, the test piece was dipped in sulfuric acid at 25° C. for 1 minute followed by water washing for three times.

### [4] Pre-Dip Process

After the acid cleaning process, the test piece was dipped in sulfuric acid at 25° C. for 1 minute.

### [5] Providing Palladium Catalyst

After the pre-dip process, KAT-450 (product name: manufactured by: C. Uyemura & Co., Ltd.) was used as a palladium catalyst-imparting liquid to provide a palladium catalyst with a terminal part(s). The test piece was dipped in the palladium catalyst-imparting liquid at 25° C. for 2 minutes followed by water washing for three times.

### [6] Electroless Ni Plating Process

After providing the palladium catalyst, the test piece was dipped in an electroless Ni plating bath (product name: NPR-4; manufactured by: C. Uyemura & Co., Ltd.) at 80° C. for 35 minutes followed by water washing for three times.

### [7] Electroless Pd Plating Process

After the electroless Ni plating process, the test piece was dipped in an electroless Pd plating bath (product name: TPD-30; manufactured by: C. Uyemura & Co., Ltd.) at 50° C. for 5 minutes followed by water washing for three times.

### [8] Electroless Au Plating Process

After the electroless Pd plating process, the test piece was dipped in an electroless Au plating bath (product name: TWX-40; manufactured by: C. Uyemura & Co., Ltd.) at 80° C. for 30 minutes followed by water washing for three times.

### (5) Production of Semiconductor Device

A semiconductor element was produced similarly as in Example A1 by using the obtained printed wiring board subjected to the ENEPIG, which was cut into a size of 50 mm×50 mm.

### Example B2

Example B2 was performed similarly as in Example B1 except that the components of the slurry were as follows: 32.4% by weight of a silicone rubber particle (product name: KMP-600; manufactured by: Shin-Etsu Chemical Co., Ltd.; average particle diameter: 5 μm), 12.2% by weight of a boehmite particle (product name: AOH-30; manufactured by: TESCO Co., Ltd.; average particle diameter: 1.8 μm), and 2.4% by weight of a silica nanoparticle (product name: NSS-5N; manufactured by: Tokuyama Corporation; average particle diameter: 70 nm).

### Example B3

Example B2 was performed similarly as in Example B1 except that a resin varnish having a solid content of 70% by weight was obtained as follows: 18.6% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 34.4% by weight of a cyanate resin (product name: PT30; manufactured by: Lonza Japan, Ltd.; novolac type cyanate resin; weight-average molecular weight: 380), and 0.02% by weight of zinc octoate (manufactured by: Tokyo Chemical Industry Co., Ltd.) as a curing catalyst were dissolved in the slurry prepared similarly as in Example B1 and mixed, and then the mixture was agitated by means of a high speed agitator.

### Example B4

Example B4 was performed similarly as in Example B1 except that a resin varnish having a solid content of 70% by weight was obtained as follows: 19.6% by weight of an epoxy resin (product name: NC3000; manufactured by: Nippon Kayaku Co., Ltd.; biphenylaralky: type epoxy resin; weight-average molecular weight: 1300; softening point: 57° C.; epoxy equivalent: 276 g/eq), 13.3% by weight of a cyanate resin (product name: PT30; manufactured by: Lonza Japan, Ltd.; novolac type cyanate resin; weight-average molecular weight: 380), 20.1% by weight of a maleimide resin (product name: BMI-70,(3-ethyl-5-methyl-4-maleimidephenyl)methane; manufactured by: KI Chemical Industry Co., Ltd.; bismaleimide resin), and 0.02% by weight of zinc octoate (manufactured by: Tokyo Chemical Industry Co., Ltd.) as a curing catalyst were dissolved in the slurry prepared similarly as in Example B1 and mixed, and then the mixture was agitated by means of a high speed agitator.

### Example B5

Example B5 was performed similarly as in Example B1 except that a resin varnish having a solid content of 70% by weight was obtained as follows: 25.4% by weight of an epoxy resin (product name: ESN-375; manufactured by: Tohto Kasei Co., Ltd.; naphthalene type epoxy resin; weight-average molecular weight: 700; softening point: 75° C.; epoxy equivalent: 167 g/eq), 21.2% by weight of a cyanate resin (product name: PT30; manufactured by: Lonza Japan, Ltd.; novolac type cyanate resin; weight-average molecular weight: 380), and 6.4% by weight of a phenol resin (product name: GPH-103; manufactured by: Nippon Kayaku Co., Ltd.; biphenylaralkyl type phenol resin) as a curing agent were dissolved in the slurry prepared similarly as in Example B1 and mixed, and then the mixture was agitated by means of a high speed agitator.

### Example B6

Example B6 was performed similarly as in Example B1 except that a resin varnish having a solid content of 70% by weight was obtained as follows: 25.4% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 21.2% by weight of a cyanate resin (product name: PT30; manufactured by: Lonza Japan, Ltd.; novolac type cyanate resin; weight-average molecular weight: 380), and 6.4% by weight of a phenol resin (product name: MEH-7500; manufactured by: Meiwa Plastic Industries, Ltd; triphenylmethane type phenol resin; hydroxyl group equivalent: 97 g/eq) as a curing agent were dissolved in the slurry prepared similarly as in Example B1 and mixed, and then the mixture was agitated by means of a high speed agitator.

### Comparative Example B1

37.5% by weight of a silicone rubber particle (product name: KMP-600; manufactured by: Shin-Etsu Chemical Co., Ltd.; average particle diameter: 5 μm), and 2.5% by weight of a silica particle (product name: SO-25R; manufactured by: Admatechs Company Limited; average particle diameter: 0.5 μm) were dissolved in a solvent (ANON: MIBK=1:1 (v/v)) to prepare a slurry having a concentration of 65% by weight.

Comparative example B1 was performed similarly as in Example B1 except that a resin varnish having a solid content of 70% by weight was obtained as follows: 38.0% by weight of an epoxy resin (product name: ESN-375; manufactured by: Tohto Kasei Co., Ltd.; naphthalene type epoxy resin; weight-average molecular weight: 700; softening point: 75° C.; epoxy equivalent: 167 g/eq), and 22.0% by weight of a phenol resin (product name: MEH-7500; manufactured by: Meiwa Plastic Industries, Ltd; triphenylmethane type phenol resin; hydroxyl group equivalent: 97 g/eq) as a curing agent were dissolved in the above obtained slurry and mixed, and then the mixture was agitated by means of a high speed agitator.

### Comparative Example B2

Comparative example B2 was performed similarly as in Example B1 except that the components of the slurry were as follows: 18.2% by weight of a boehmite particle (product name: AOH-30; manufactured by: TESCO Co., Ltd.; average particle diameter: 1.8 μm), 2.4% by weight of a silica nanoparticle (product name: NSS-5N; manufactured by: Tokuyama Corporation; average particle diameter: 70 nm), and 26.4% by weight of a silica particle (product name: SO-25R; manufactured by: Admatechs Company Limited; average particle diameter: 0.5 μm).

### Comparative Example B3

Comparative example B3 was performed similarly as in Example B1 except that the components of the slurry were as follows: 18.2% by weight of a silicone rubber particle (product name: KMP-600; manufactured by: Shin-Etsu Chemical Co., Ltd.; average particle diameter: 5 μm), 2.4% by weight of a silica nanoparticle (product name: NSS-5N; manufactured by: Tokuyama Corporation; average particle diameter: 70 nm), and 26.4% by weight of a silica particle (product name: SO-25R; manufactured by: Admatechs Company Limited; average particle diameter: 0.5 μm).

### Comparative Example B4

Comparative example B4 was performed similarly as in Example B1 except that the components of the slurry were as follows: 20.6% by weight of a boehmite particle (product name: AOH-30; manufactured by: TESCO Co., Ltd.; average particle diameter: 1.8 μm), and 26.4% by weight of a silica particle (product name: SO-25R; manufactured by: Admatechs Company Limited; average particle diameter: 0.5 μm).

### Comparative Example B5

Comparative example B5 was performed similarly as in Example B1 except that the components of the slurry were as follows: 44.6% by weight of a boehmite particle (product name: AOH-30; manufactured by: TESCO Co., Ltd.; average particle diameter: 1.8 μm), and 2.4% by weight of a silica nanoparticle (product name: NSS-5N; manufactured by: Tokuyama Corporation; average particle diameter: 70 nm).

The prepreg, metal-clad laminate, printed wiring board and semiconductor device obtained in each of Examples and Comparative examples were evaluated for the following items. The items and contents of evaluation are as below. The obtained results are shown in Table B1.

### (1) Linear Thermal Expansion Coefficient

The copper foil of the obtained metal-clad laminate was removed by etching. Then, a test piece of 2 mm×2 mm was taken from the metal-clad laminate and measured for linear thermal expansion coefficient (CTE) in a thickness direction (Z direction) in the range of 50 to 100° C. by means of a TMA device (manufactured by: TA Instruments), increasing the temperature from 30 to 150° C. in the condition of 10° C./minute.

### (2) Flame Resistance

A double-sided metal-clad laminate having a thickness of 1.02 mm was obtained similarly as in Example A1. The copper foils of the above-obtained metal-clad laminate was subjected to etching, and flame resistance of a test piece having a thickness of 1.0 mm was measured by a vertical method in accordance with UL-94 standard.

V-0: the requirement of V-0 in UL-94 standard was satisfied.

Nonstandard: one or more out of 5 test pieces burned down.

### (3) Drill Wearability

Three sheets of the obtained metal laminate were stacked, and drill processing ((φ150) was performed thereon three thousand times (3000 holes) by means of a drill bit (product name UV L0950; manufactured by: Union Tool Co.) in the condition of drill spindle speed of 160 rpm and feeding speed of 3.2 m/minute. The residual rate of the width of a drill blade after use was measured to evaluate drill wearability, based on the premise that the width of the drill blade before use is 100%.

### (4) Prepreg Impregnation Property

The obtained metal-clad laminate was cross-sectionally observed. A scanning electron microscope was used for the cross-sectional observation.

Impregnation property was evaluated from the area of void which was observed in the cross-sectional observation.

∘: Unimpregnated voids were observed at less than 10% of total area, but the metal-clad laminate was at practicable level.

Δ: Unimpregnated voids were observed at 10 to 30% of total area, and the metal-clad laminate was not at practicable level.

x: Unimpregnated voids were observed at 50% or more of total area, and the metal-clad laminate was not at practicable level.

### (5) Desmear Resistance

By means of a carbon dioxide gas laser device (product name: LG-2G212; manufactured by: Hitachi Via Mechanics, Ltd.), 500 via holes having a size of 960 μm were formed on the structure obtained by removing the copper foil of the metal-clad laminate by etching. The desmear treatment was performed on the resultant by roughening treatment as follows: immersing in a swelling agent (product name: Swelling Dip Securiganth P; manufactured by: Atotech Japan K.K.) at 70° C. for 5 minutes; further immersing in a potassium permanganate aqueous solution (product name: Concentrate Compact CP; manufactured by: Atotech Japan K.K.) at 80° C. for 15 minutes; and neutralizing. The thickness of the structure before and after the desmear treatment was measured to evaluate the amount of reduction in thickness [(thickness before treatment-thickness after treatment)/(thickness before treatment)].

### (6) Occurrence of Streaked Unevenness

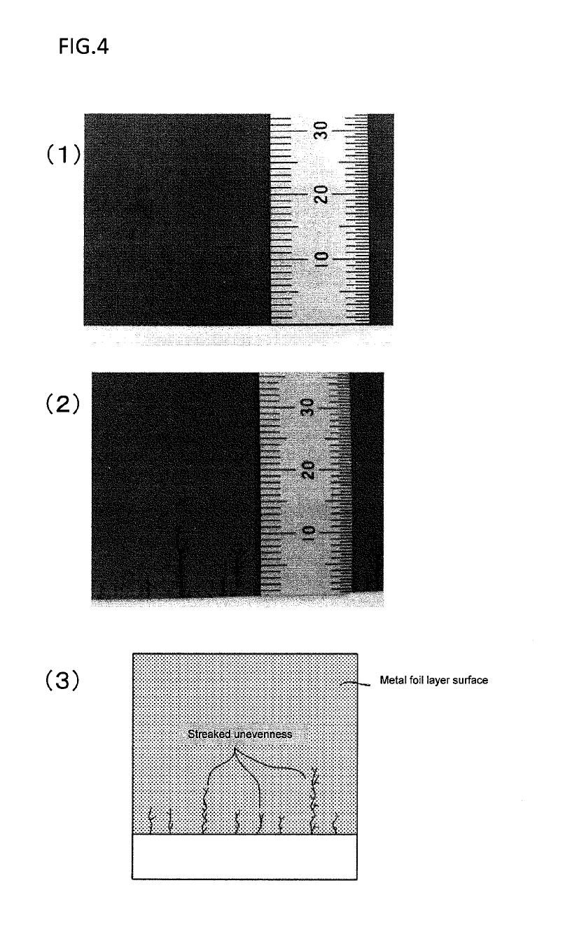

FIG. 4 shows: (1) a photograph of the surface of the metal-clad laminate obtained in Example B1; (2) a photograph of The surface of the metal-clad laminate obtained in Comparative example B1; and (3) a view explaining a photograph of the surface of a metal foil layer of the metal-clad laminate. As shown in the photographs, the surface of the metal foil layer of the metal-clad laminate in Comparative example 31 had streaked unevenness; however, the surface of the metal foil layer of the metal-clad laminate in Example B1 had no streaked unevenness.

### (7) ENEPIG Properties

Metal precipitated on the space between thin lines, which are produced by the ENEPIG process, of the printed wiring board was observed by SEM and confirmed by the same evaluation as in Example A series.

TABLE B1

| | | Examples | | | | | | Comparative examples | |
|---|---|---|---|---|---|---|---|---|---|
| | | B1 | B2 | B3 | B4 | B5 | B6 | B1 | B2 |
| Epoxy resin | NC-3000, Biphenylaralkyl type | 25.4 | 25.4 | 18.6 | 19.6 | | 25.4 | | 25.4 |
| | ESN-375, Naphthalene type | | | | | 25.4 | | 38.0 | |
| Cyanate resin | PT-30, Novolac type | 21.2 | 21.2 | 34.4 | 13.3 | 21.2 | 21.2 | | 21.2 |
| Phenol resin | GPH-103, Biphenylaralkyl type | 6.4 | 6.4 | | | 6.4 | | | 6.4 |
| | MEH-7500, Triphenylmethane type | | | | | | 6.4 | 22.0 | |
| Maleimide resin | BMI-70, Bismaleimide | | | | 20.1 | | | | |
| Curing catalyst | Zinc octoate | | | 0.02 | 0.02 | | | | |
| Silicone rubber particle | KMP-600, 5 μm | 26.4 | 32.4 | 26.4 | 26.4 | 26.4 | 26.4 | 37.5 | |
| Boehmite particle | AOH-30, 1.8 μm | 18.2 | 12.2 | 18.2 | 18.2 | 18.2 | 18.2 | | 20.6 |
| Silica nanoparticle | NSS-5N, 70 nm | 2.4 | 2.4 | 2.4 | 2.4 | 2.4 | 2.4 | | |
| Silica particle | SO-25R, 0.5 μm | | | | | | | 2.5 | 26.4 |

| | | | | | | | | |
|---|---|---|---|---|---|---|---|---|
| CTE (ppm) | 8 | 7 | 9 | 8 | 7 | 8 | 14⁽¹⁾ | 8⁽¹⁾ |
| Flame resistance | V-0 | V-0 | V-0 | V-0 | V-0 | V-0 | Nonstandard | V-0 |
| Drill wearability (residual rate) | 60 | 65 | 60 | 60 | 55 | 55 | 55⁽²⁾ | 65⁽²⁾ |
| Prepreg impregnation property | ∘ | ∘ | ∘ | ∘ | ∘ | ∘ | x | x |
| Desmear resistance (amount of reduction in thickness) | 0.12 | 0.12 | 0.13 | 0.14 | 0.13 | 0.13 | 0.20 | 0.18 |
| ENEPIG properties | ∘ | ∘ | ∘ | ∘ | ∘ | ∘ | x | x |

⁽¹⁾Since the test piece had poor prepreg impregnation property, impregnation property was measured by selecting the part having high filling properties.
⁽²⁾The numerical value of drill wearability was equal to the results of Examples; however, the test piece had many voids, thus, the Comparative example B1 cannot be objectively compared with Examples.

From the evaluation results shown in Table B1, the following are understood.

In Comparative example B1, prepreg impregnation property was inferior since the silica nanoparticles and boehmite particles specified in the present invention were not used. Therefore, linear thermal expansion coefficient, flame resistance, desmear resistance and ENEPIG properties were not developed to a practicable level.

In Comparative example B2, prepreg impregnation property was inferior since the silicone rubber particles and silica nanoparticles specified in the present invention were not used. Therefore, desmear resistance and ENEPIG properties were not developed to a practicable level.

In Comparative example B1, the numerical value of drill wearability was equal to the results of Examples; however, the test piece had many voids, thus, Comparative example B1 cannot be objectively compared with Examples.

In addition, in linear thermal expansion coefficient test in Comparative example B1, since the test piece had poor prepreg impregnation property, impregnation property was measured by selecting the part having high filling properties.

The resin composition, prepreg, metal-clad laminate, printed wiring board and semiconductor device of the present invention obtained in each of Examples B1 to B6 had excellent linear thermal expansion coefficient, flame resistance, drill wearability, prepreg impregnation property, desmear resistance and ENEPIG properties. Therefore, it can be understood that the prepreg, metal-clad laminate, printed wiring board and semiconductor device having excellent performance can be obtained by using the resin composition comprising the epoxy resin, silicone rubber particles, boehmite particles and silica nanoparticles specified in the present invention.

### Reference Example C Series

Reference examples using the third resin composition of the present invention will be described below.

### Reference Example C1

### (1) Preparation of Varnish Containing Resin Composition (Resin Varnish)

First, 37.5% by weight of a silicone rubber particle (product name: KMP-600; manufactured by: Shin-Etsu Chemical Co., Ltd.; average particle diameter: 5 μm), and 2.5% by weight of a silica nanoparticle (product name: NSS-5N; manufactured by: Tokuyama Corporation; average particle diameter: 70 nm) were dispersed in a solvent (cyclohexanone (ANON): methyl isobutyl ketone (MIBK)=1:1 (v/v)) to prepare a slurry having a concentration of 65% by weight.

Next, the following were dissolved in the thus-obtained slurry and mixed: 28.7% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 24.0% by weight of a cyanate resin (product name: PT30; manufactured by: Lonza Japan, Ltd.; novolac type cyanate resin; weight-average molecular weight: 380), and 7.3% by weight of a phenol resin (product name: GPH-103; manufactured by: Nippon Kayaku Co., Ltd.; biphenylaralkyl type phenol resin) as a curing agent. Then, thus-obtained mixture was agitated by means of a high speed agitator, thereby obtaining a resin varnish having a solid content of 70% by weight.

### (2) Production of Prepreg

A prepreg was obtained similarly as in Example B1 using the resin varnish.

### (3) Production of Metal-Clad Laminate

A double-sided metal-clad laminate having a thickness of 0.130 mm was obtained similarly as in Example A1 using the obtained prepreg.

### (4) Production of Printed Wiring Board

A printed wiring board was produced similarly as in Example B1 using the obtained double-sided metal-clad laminate, and an ENEPIG process was performed thereon.

### (5) Production of Semiconductor Device

A semiconductor device was produced similarly as in Example A1 using the obtained printed wiring board subjected to the ENEPIG process, which was cut into a size of 50 mm×50 mm.

### Reference Example C2

Reference example C2 was performed similarly as in Reference example C1 except that the components of the slurry were as follows: 32.5% by weight of a silicone rubber particle (product name: KMP-600; manufactured by: Shin-Etsu Chemical Co., Ltd.; average particle diameter: 5 μm), 2.5% by weight of a silica nanoparticle (product name: NSS-5N; manufactured by: Tokuyama Corporation; average particle diameter: 70 nm), and 5.0% by weight of a silica particle (product name: SO-25R; manufactured by: Admatechs Company Limited; average particle diameter: 0.5 μm).

### Reference Example C3

37.5% by weight of a silicone rubber particle (product name: KMP-600; manufactured by: Shin-Etsu Chemical Co., Ltd.; average particle diameter: 5 μm), and 2.5% by weight of a silica nanoparticle (product name: NSS-5N; manufactured by: Tokuyama Corporation; average particle diameter: 70 nm) were dispersed in a solvent (ANON: MIBK=1:1 (v/v)) to prepare a slurry having a concentration of 65% by weight.

Reference example C3 was performed similarly as in Reference example C1 except that a resin varnish having a solid content of 70% by weight was obtained as follows: 21.0% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 39.0% by weight of a cyanate resin (product name: PT30; manufactured by: Lonza Japan, Ltd.; novolac type cyanate resin; weight-average molecular weight: 380), and 0.02% by weight of zinc octoate (manufactured by: Tokyo Chemical Industry Co., Ltd.) as a curing catalyst were dissolved in the obtained slurry and mixed, and then the mixture was agitated by means of a high speed agitator.

### Reference Example C4

Reference example C4 was performed similarly as in Reference example C1 except that a resin varnish having a solid content of 70% by weight was obtained as follows: 22.2% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 15.0% by weight of a cyanate resin (product name: PT30; manufactured by: Lonza Japan, Ltd.; novolac type cyanate resin; weight-average molecular weight: 380), 22.8% by weight of a maleimide resin (product name: BMI-70; manufactured by: KI Chemical Industry Co., Ltd.; (3-ethyl-5-methyl-4-maleimidephenyl)methane; bismaleimide resin), and 0.02% by weight of zinc octoate (manufactured by: Tokyo Chemical Industry Co., Ltd.) as a curing catalyst were dissolved in the slurry prepared similarly as in Reference example C3 and mixed, and then the mixture was agitated by means of a high speed agitator.

### Reference Example C5

Reference example C5 was performed similarly as in Reference example C1 except that a resin varnish having a solid content of 70% by weight was obtained as follows: 28.7% by weight of an epoxy resin (product name: ESN-375; manufactured by: Tohto Kasei Co., Ltd.; naphthalene type epoxy resin; weight-average molecular weight: 700; softening point: 75° C.; epoxy equivalent: 167 g/eq), 24.0% by weight of a cyanate resin (product name: PT30; manufactured by: Lonza Japan, Ltd.; novolac type cyanate resin; weight-average molecular weight: 380), and 7.3% by weight of a phenol resin (product name: GPH-103; manufactured by: Nippon Kayaku Co., Ltd.; biphenylaralkyl type phenol resin) as a curing agent were dissolved in the slurry prepared similarly as in Reference example C3 and mixed, and then the mixture was agitated by means of a high speed agitator.

### Reference Example C6

Reference example C6 was performed similarly as in Reference example C1 except that a resin varnish having a solid content of 70% by weight was obtained as follows: 28.7% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 24.0% by weight of a cyanate resin (product name: PT30; manufactured by: Lonza Japan, Ltd.; novolac type cyanate resin; weight-average molecular weight: 380), and 7.3% by weight of a phenol resin (product name: MEH-7500; manufactured by: Meiwa Plastic Industries, Ltd.; triphenylmethane type phenol resin; hydroxyl group equivalent: 97 g/eq) were dissolved in the slurry prepared similarly as in Reference example C3 and mixed, and then the mixture was agitated by means of a high speed agitator.

### Reference Example C7

Reference example C7 was performed similarly as in Reference example C1 except that the components of the slurry were as follows: 37.5% by weight of a silicone rubber particle (product name: KMP-605; manufactured by: Shin-Etsu Chemical Co., Ltd.; average particle diameter: 2 μm), and 2.5% by weight of a silica nanoparticle (product name: NSS-5N; manufactured by: Tokuyama Corporation; average particle diameter: 70 nm).

### Reference Example C8

Reference example C8 was performed similarly as in Reference example C1 except that the components of the slurry were as follows: 37.5% by weight of a silicone rubber particle (product name: KMP-597; manufactured by: Shin-Etsu Chemical Co., Ltd.; average particle diameter: 5 μm), and 2.5% by weight of a silica nanoparticle (product name: NSS-5N; manufactured by: Tokuyama Corporation; average particle diameter: 70 nm).

### Reference Comparative Example C1

37.5% by weight of a silicone rubber particle (product name: KMP-600; manufactured by: Shin-Etsu Chemical Co., Ltd.; average particle diameter: 5 μm), and 2.5% by weight of a silica particle (product name: SO-25R; manufactured by: Admatechs Company Limited; average particle diameter: 0.5 μm) were dispersed in a solvent (ANON: MIBK=1:1 (v/v)) to prepare a slurry having a concentration of 65% by weight.

Reference comparative example C1 was performed similarly as in Reference example C1 except that a resin varnish having a solid content of 70% by weight was obtained as follows: 38.0% by weight of an epoxy resin (product name: ESN-375; manufactured by: Tohto Kasei Co., Ltd.; naphthalene type epoxy resin; weight-average molecular weight: 700; softening point: 75° C.; epoxy equivalent: 167 g/eq), and 22.0% by weight of a phenol resin (product name: MEH-7500; manufactured by: Meiwa Plastic Industries, Ltd.; triphenylmethane type phenol resin; hydroxyl group equivalent: 97 g/eq) as a curing agent were dissolved in the obtained slurry and mixed, and then the mixture was agitated by means of a high speed agitator.

### Reference Comparative Example C2

Reference comparative example C2 was performed similarly as in Reference example C1 except that the components of the slurry were as follows: 37.5% by weight of a silicone rubber particle (product name: KMP-600; manufactured by: Shin-Etsu Chemical Co., Ltd.; average particle diameter: 5 μm), and 2.5% by weight of a silica particle (product name: SO-25R; manufactured by: Admatechs Company Limited; average particle diameter: 0.5 μm).

### Reference Comparative Example C3

Reference comparative example C3 was performed similarly as in Reference example C1 except that the components of the slurry were as follows: 37.5% by weight of a silica particle (product name: SO-25R; manufactured by: Admatechs Company Limited; average particle diameter: 0.5 μm), and 2.5% by weight of a silica nanoparticle (product name: NSS-5N; manufactured by: Tokuyama Corporation; average particle diameter: 70 nm).

### Reference Comparative Example C4

Reference comparative example C4 was performed similarly as in Reference example C1 except that the component of the slurry was as follows: 40.0% by weight of a silicone rubber particle (product name: KMP-600; manufactured by: Shin-Etsu Chemical Co., Ltd.; average particle diameter: 5 μm).

(1) linear thermal expansion coefficient, (2) flame resistance, (3) drill wearability, (4) prepreg impregnation property, (5) desmear resistance, (6) occurrence of streaked unevenness, and (7) ENEPIG properties of the prepreg, metal-clad laminate, printed wiring board and semiconductor device obtained in each of Reference examples and Reference comparative examples were evaluated. Evaluation each of the items was performed similarly as in Example B series except the item (5). The obtained results are shown in Table C1.

(5) desmear resistance was evaluated similarly as in Example B series except that the desmear treatment was performed on the stack constituted with four prepregs.

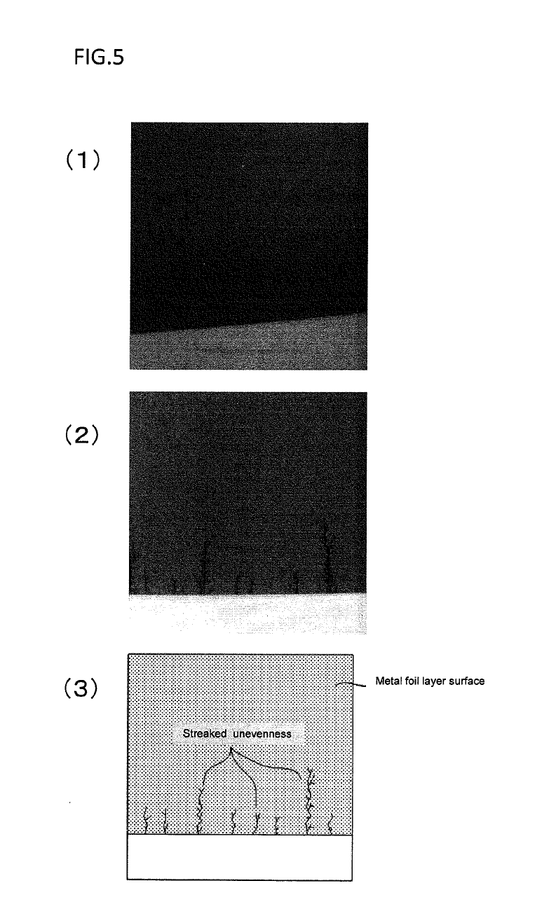

As for (6) occurrence of streaked unevenness, FIG. 5 shows: (1) a photograph of the surface of the metal-clad laminate obtained in Reference example C1; (2) a photograph of the surface of the metal-clad laminate obtained in Reference comparative example C1; and (3) a view explaining a photograph of the surface of a metal foil layer of the metal-clad laminate. As shown in the photographs, the surface of the metal foil layer of the metal-clad laminate in Reference comparative example C1 had streaked unevenness; however, the surface of the metal foil layer of the metal-clad laminate in Reference example C1 had no streaked unevenness.

TABLE C1

| | | Reference examples | | | | | | | | Reference comparative examples | | | |
|---|---|---|---|---|---|---|---|---|---|---|---|---|---|
| | | C1 | C2 | C3 | C4 | C5 | C6 | C7 | C8 | C1 | C2 | C3 | C4 |
| Epoxy resin | NC-3000, Biphenylaralkyl type | 28.7 | 28.7 | 21.0 | 22.2 | | 28.7 | 28.7 | 28.7 | | 28.7 | 28.7 | 28.7 |
| | ESN-375, Naphthalene type | | | | | 28.7 | | | | 38.0 | | | |
| Cyanate resin | PT-30, Novolac type | 24.0 | 24.0 | 39.0 | 15.0 | 24.0 | 24.0 | 24.0 | 24.0 | | 24.0 | 24.0 | 24.0 |
| Phenol resin | GPH-103, Biphenylaralkyl type | 7.3 | 7.3 | | | 7.3 | | 7.3 | 7.3 | | 7.3 | 7.3 | 7.3 |
| | MEH-7500, | | | | | | 7.3 | | | 22.0 | | | |
| | Triphenylmethane type | | | | | | | | | | | | |
| Maleimide resin | BMI-70, Bismaleimide | | | | 22.8 | | | | | | | | |
| Curing catalyst | Zinc octoate | | | 0.02 | 0.02 | | | | | | | | |
| Silicone | KMP-600, 5 μm | 37.5 | 32.5 | 37.5 | 37.5 | 37.5 | 37.5 | | | 37.5 | 37.5 | | 40.0 |
| rubber particle | KMP-605, 2 μm | | | | | | | 37.5 | | | | | |
| | KMP-597, 5 μm | | | | | | | | 37.5 | | | | |
| Silica nanopartide | NSS-5N, 70 nm | 2.5 | 2.5 | 2.5 | 2.5 | 2.5 | 2.5 | 2.5 | 2.5 | | | 2.5 | |
| Silica particle | SO-25R, 0.5 μm | | 5.0 | | | | | | | 2.5 | 2.5 | 37.5 | |

| | | | | | | | | | | | | |
|---|---|---|---|---|---|---|---|---|---|---|---|---|
| CTE (ppm) | 8 | 8 | 9 | 8 | 7 | 8 | 7 | 9 | 13⁽¹⁾ | 11⁽¹⁾ | 8 | 8⁽¹⁾ |
| Flame resistance | V-0 | V-0 | V-0 | V-0 | V-0 | V-0 | V-0 | V-0 | Non- | Non- | V-0 | Non- |
| | | | | | | | | | standand | standard | | standard |
| Drill wearability (residual rate) | 60 | 55 | 60 | 60 | 55 | 55 | 55 | 55 | 50⁽²⁾ | 60⁽²⁾ | 30 | 60⁽²⁾ |
| Prepreg impregnation property | ∘ | ∘ | ∘ | ∘ | ∘ | ∘ | ∘ | ∘ | x | x | ∘ | x |
| Desmear resistance (amount of reduction in thickness) | 0.11 | 0.11 | 0.12 | 0.13 | 0.12 | 0.12 | 0.11 | 0.11 | 0.20 | 0.18 | 0.12 | 0.23 |
| ENEPIG properties | ∘ | ∘ | ∘ | ∘ | ∘ | ∘ | ∘ | ∘ | x | x | ∘ | x |

⁽¹⁾Since the test piece had poor prepreg impregnation property, impregnation property was measured by selecting the part having high filling properties.
⁽²⁾The numerical value of drill wearability was equal to the results of Reference examples; however, the test piece had many voids, thus, the Reference comparative examples cannot be objectively compared with Reference examples.

From the evaluation results shown in Table C1, the following are understood.

In Reference comparative example C1 and Reference comparative example C2, prepreg impregnation property was inferior since the silica nanoparticles specified in the third resin composition of the present invention were not used. Therefore, linear thermal expansion coefficient, flame resistance, desmear resistance and ENEPIG properties were not developed to a practicable level.

In Reference comparative example C3, drill wearability was not developed to a practicable level since the silicone rubber particles specified in the third resin composition of the present invention were not used.

In Reference comparative example C4, linear thermal expansion coefficient was excellent since a large amount of the silicone rubber particles specified in the third resin composition of the present invention was used; however, prepreg impregnation property was inferior since the silica nanoparticles specified in the third resin composition of the present invention were not used. Therefore, flame resistance, desmear resistance, and ENEPIG properties were not developed to a practicable level.

In each of Reference comparative examples C1, C2 and C4, the numerical value of drill wearability was equal to the results of Reference examples; however, the test piece had many voids, thus, Reference comparative examples cannot be objectively compared with Reference examples.

In addition, in linear thermal expansion coefficient test in each of Reference comparative examples C1, C2 and C4, since the test piece had poor prepreg impregnation property, impregnation property was measured by selecting the part having high filling properties.

The resin composition, prepreg, metal-clad laminate, printed wiring board and semiconductor device of the present invention obtained in each of Reference examples C1 to C8 had excellent linear thermal expansion coefficient, flame resistance, drill wearability, prepreg impregnation property, desmear resistance and ENEPIG properties. Therefore, it can be understood that the prepreg, metal-clad laminate, printed wiring board and semiconductor device having excellent performance can be obtained by using the silicone rubber particle-containing resin composition comprising the epoxy resin, silicone rubber particles and silica nanoparticles specified in the present invention.

### Reference Example D Series

Reference examples using the fourth resin composition of the present invention will be described below.

### Reference Example D1

### (1) Preparation of Varnish Containing Resin Composition (Resin Varnish)

21.0% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 39.0% by weight of a cyanate resin (product name: PT30; manufactured by: Lonza Japan, Ltd.; novolac type cyanate resin; weight-average molecular weight: 380), 0.02% by weight of zinc octoate (manufactured by: Tokyo Chemical Industry Co., Ltd.), 37.0% by weight of a silicone rubber particle (product name: KMP-605; manufactured by: Shin-Etsu Chemical Co., Ltd.; average particle diameter: 2 μm), and 3.0% by weight of a barium sulfate particle (product name: BF-21; manufactured by: Sakai Chemical Industry Co., Ltd.; average particle diameter: 50 nm) were dissolved in cyclohexanone and mixed. Then, the thus-obtained mixture was agitated by means of a high speed agitator, thereby obtaining a resin varnish having a solid content of 70% by weight.

### (2) Production of Prepreg

A prepreg was obtained similarly as in Example B1 using the resin varnish.

### (3) Production of Metal-Clad Laminate

A double-sided metal-clad laminate having a thickness of 0.430 mm was obtained similarly as in Example A1 using the obtained prepreg.

### (4) Production of Printed Wiring Board

A printed wiring board was produced similarly as in Example B1 using the obtained double-sided metal-clad laminate, and an ENEPIG process was performed thereon.

### (5) Production of Semiconductor Device

A semiconductor device was produced similarly as in Example A1 using the obtained printed wiring board subjected to the ENEPIG process, which was cut into a size of 50 mm×50 mm.

### Reference Example D2

Reference example D2 was performed similarly as in Reference example D1 except that a resin varnish having a solid content of 70% by weight was obtained as follows: 21.0% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 39.0% by weight of a cyanate resin (product name: PT30; manufactured by: Lonza Japan, Ltd.; novolac type cyanate resin; weight-average molecular weight: 380), 0.02% by weight of zinc octoate (manufactured by: Tokyo Chemical Industry Co., Ltd.), 32.0% by weight of a silicone rubber particle (product name: KMP-605; manufactured by: Shin-Etsu Chemical Co., Ltd.; average particle diameter: 2 μm), 3.0% by weight of a barium sulfate particle (product name: BF-21; manufactured by: Sakai Chemical Industry Co., Ltd.; average particle diameter: 50 nm), and 5.0% by weight of a silica particle (product name: SO-25R; manufactured by: Admatechs Company Limited; average particle diameter: 0.5 μm) were dissolved in cyclohexanone and mixed, and then the mixture was agitated by means of a high speed agitator.

### Reference Example D3

Reference example D3 was performed similarly as in Reference example D1 except that a resin varnish having a solid content of 70% by weight was obtained as follows: 22.2% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 15.0% by weight of a cyanate resin (product name: PT30; manufactured by: Lonza Japan, Ltd.; novolac type cyanate resin; weight-average molecular weight: 380), 22.8% by weight of a maleimide resin (product name: BMI-70; manufactured by: KI Chemical Industry Co., Ltd.; (3-ethyl-5-methyl-4-maleimidephenyl)methane; bismaleimide resin), 0.02% by weight of zinc octoate (manufactured by: Tokyo Chemical Industry Co., Ltd.), 37.0% by weight of a silicone rubber particle (product name: KMP-605; manufactured by: Shin-Etsu Chemical Co., Ltd.; average particle diameter: 2 μm), and 3.0% by weight of a barium sulfate particle (product name: BF-21; manufactured by: Sakai Chemical Industry Co., Ltd.; average particle diameter: 50 nm) were dissolved in cyclohexanone and mixed, and then the mixture was agitated by means of a high speed agitator.

### Reference Example D4

Reference example D4 was performed similarly as in Reference example D1 except that a resin varnish having a solid content of 70% by weight was obtained as follows: 28.7% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 24.0% by weight of a cyanate resin (product name: PT30; manufactured by: Lonza Japan, Ltd.; novolac type cyanate resin; weight-average molecular weight: 380), 7.3% by weight of a phenol resin (product name: MEH-7851-H; manufactured by: Meiwa Plastic Industries, Ltd.; biphenylaralkyl type phenol resin), 37.0% by weight of a silicone rubber particle (product name: KMP-605; manufactured by: Shin-Etsu Chemical Co., Ltd.; average particle diameter: 2 μm), and 3.0% by weight of a barium sulfate particle (product name: BF-21; manufactured by: Sakai Chemical Industry Co., Ltd.; average particle diameter: 50 nm) were dissolved in cyclohexanone and mixed, and then the mixture was agitated by means of a high speed agitator.

### Reference Example D5

Reference example D5 was performed similarly as in Reference example D1 except that a resin varnish having a solid content of 70% by weight was obtained as follows: 28.7% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 24.0% by weight of a cyanate resin (product name: PT30; manufactured by: Lonza Japan, Ltd.; novolac type cyanate resin; weight-average molecular weight: 380), 7.3% by weight of a phenol resin (product name: MEH-7500; manufactured by: Meiwa Plastic Industries, Ltd.; triphenylmethane type phenol resin; hydroxyl group equivalent: 97 g/eq), 37.0% by weight of a silicone rubber particle (product name: KMP-605; manufactured by: Shin-Etsu Chemical Co., Ltd.; average particle diameter: 2 μm), and 3.0% by weight of a barium sulfate particle (product name: BF-21; manufactured by: Sakai Chemical Industry Co., Ltd.; average particle diameter: 50 nm) were dissolved in cyclohexanone and mixed, and then the mixture was agitated by means of a high speed agitator.

### Reference Example D6

Reference example D6 was performed similarly as in Reference example D1 except that a resin varnish having a solid content of 70% by weight was obtained as follows: 21.0% by weight of an epoxy resin (product name: ESN-375; manufactured by: Tohto Kasei Co., Ltd.; naphthalene type epoxy resin; weight-average molecular weight: 700; softening point: 75° C.; epoxy equivalent: 167 g/eq), 39.0% by weight of a cyanate resin (product name: PT30; manufactured by: Lonza Japan, Ltd.; novolac type cyanate resin; weight-average molecular weight: 380), 0.02% by weight of zinc octoate (manufactured by: Tokyo Chemical Industry Co., Ltd.), 37.0% by weight of a silicone rubber particle (product name: KMP-605; manufactured by: Shin-Etsu Chemical Co., Ltd.; average particle diameter: 2 μm), and 3.0% by weight of a barium sulfate particle (product name: BF-21; manufactured by: Sakai Chemical Industry Co., Ltd.; average particle diameter: 50 nm) were dissolved in cyclohexanone and mixed, and then the mixture was agitated by means of a high speed agitator.

### Reference Example D7

Reference example D7 was performed similarly as in Reference example D1 except that a resin varnish having a solid content of 70% by weight was obtained as follows: 21.0% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 39.0% by weight of a cyanate resin (product name: PT30; manufactured by: Lonza Japan, Ltd.; novolac type cyanate resin; weight-average molecular weight: 380), 0.02% by weight of zinc octoate (manufactured by: Tokyo Chemical Industry Co., Ltd.), 37.0% by weight of a silicone rubber particle (product name: KMP-597; manufactured by: Shin-Etsu Chemical Co., Ltd.; average particle diameter: 5 μm), and 3.0% by weight of a barium sulfate particle (product name: BF-21; manufactured by: Sakai Chemical Industry Co., Ltd.; average particle diameter: 50 nm) were dissolved in cyclohexanone and mixed, and then the mixture was agitated by means of a high speed agitator.

### Reference Example D8

Reference example D8 was performed similarly as in Reference example D1 except that a resin varnish having a solid content of 70% by weight was obtained as follows: 21.0% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 39.0% by weight of a cyanate resin (synthesized by the method disclosed in JP-A No. 2009-35728; naphtholaralkyl type cyanate resin), 0.02% by weight of zinc octoate (manufactured by: Tokyo Chemical Industry Co., Ltd.), 37.0% by weight of a silicone rubber particle (product name: KMP-605; manufactured by: Shin-Etsu Chemical Co., Ltd.; average particle diameter: 2 μm), and 3.0% by weight of a barium sulfate particle (product name: BF-21; manufactured by: Sakai Chemical Industry Co., Ltd.; average particle diameter: 50 nm) were dissolved in cyclohexanone and mixed, and then the mixture was agitated by means of a high speed agitator.

### Reference Example D9

Reference example D9 was performed similarly as in Reference example D1 except that a resin varnish having a solid content of 70% by weight was obtained as follows: 21.0% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 39.0% by weight of a cyanate resin (product name: PT30; manufactured by: Lonza Japan, Ltd.; novolac type cyanate resin; weight-average molecular weight: 380), 0.02% by weight of zinc octoate (manufactured by: Tokyo Chemical Industry Co., Ltd.), 3.0% by weight of a barium sulfate particle (product name: BF-21; manufactured by: Sakai Chemical Industry Co., Ltd.; average particle diameter: 50 nm), and 37.0% by weight of a silica particle (product name: SO-25R; manufactured by: Admatechs Company Limited; average particle diameter: 0.5 μm) were dissolved in cyclohexanone and mixed, and then the mixture was agitated by means of a high speed agitator.

### Reference Comparative Example D1

Reference comparative example D1 was performed similarly as in Reference example D1 except that a resin varnish having a solid content of 70% by weight was obtained as follows: 38.0% by weight of an epoxy resin (product name: ESN-375; manufactured by: Tohto Kasei Co., Ltd.; naphthalene type epoxy resin; weight-average molecular weight: 700; softening point: 75° C.; epoxy equivalent: 167 g/eq), 22.0% by weight of a phenol resin (product name: MEH-7500; manufactured by: Meiwa Plastic Industries, Ltd.; triphenylmethane type phenol resin; hydroxyl group equivalent: 97 g/eq), 37.0% by weight of a silicone rubber particle (product name: KMP-605; manufactured by: Shin-Etsu Chemical Co., Ltd.; average particle diameter: 2 μm), and 3.0% by weight of a silica particle (product name: SO-25R; manufactured by: Admatechs Company Limited; average particle diameter: 0.5 μm) were dissolved in cyclohexanone and mixed, and then the mixture was agitated by means of high speed agitator.

### Reference Comparative Example D2

Reference comparative example D2 was performed similarly as in Reference example D1 except that a resin varnish having a solid content of 70% by weight was obtained as follows: 21.0% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 39.0% by weight of a cyanate resin (product name: PT30; manufactured by: Lonza Japan, Ltd.; novolac type cyanate resin; weight-average molecular weight: 380), 0.02% by weight of zinc octoate (manufactured by: Tokyo Chemical Industry Co., Ltd.), 37.0% by weight of a silicone rubber particle (product name: KMP-605; manufactured by: Shin-Etsu Chemical Co., Ltd.; average particle diameter: 2 μm), and 3.0% by weight of a silica particle (product name: SO-25R; manufactured by: Admatechs Company Limited; average particle diameter: 0.5 μm) were dissolved in cyclohexanone and mixed, and then the mixture was agitated by means of a high speed agitator.

### Reference Comparative Example D3

Reference comparative example D3 was performed similarly as in Reference example D1 except that a resin varnish having a solid content of 70% by weight was obtained as follows: 21.0% by weight of an epoxy resin (product name: NC3000; manufactured by: Nippon Kayaku Co., Ltd.; biphenylaralkyl type epoxy resin; weight-average molecular weight: 1300; softening point: 57° C.; epoxy equivalent: 276 g/eq), 39.0% by weight of a cyanate resin (product name: PT30; manufactured by: Lonza Japan, Ltd.; novolac type cyanate resin; weight-average molecular weight: 380), 0.02% by weight of zinc octoate (manufactured by: Tokyo Chemical Industry Co., Ltd.), and 40.0% by weight of a silicone rubber particle (product name: KMP-605; manufactured by: Shin-Etsu Chemical Co., Ltd.; average particle diameter: 2 μm) were dissolved in cyclohexanone and mixed, and then the mixture was agitated by means of a high speed agitator.

(1) linear thermal expansion coefficient, (2) flame resistance, (3) drill wearability, (4) prepreg impregnation property, (5) desmear resistance, (6) occurrence of streaked unevenness, and (7) ENEPIG properties of the prepreg, metal-clad laminate, printed wiring board and semiconductor device obtained in each of Reference examples and Reference comparative examples were evaluated. Each of the items was evaluated similarly as in Example B series.

The obtained results are shown in Tables D1 and D2.

As for (2) flame resistance, “burned down” in Table D2 means that one or more test pieces out of 5 burned down.

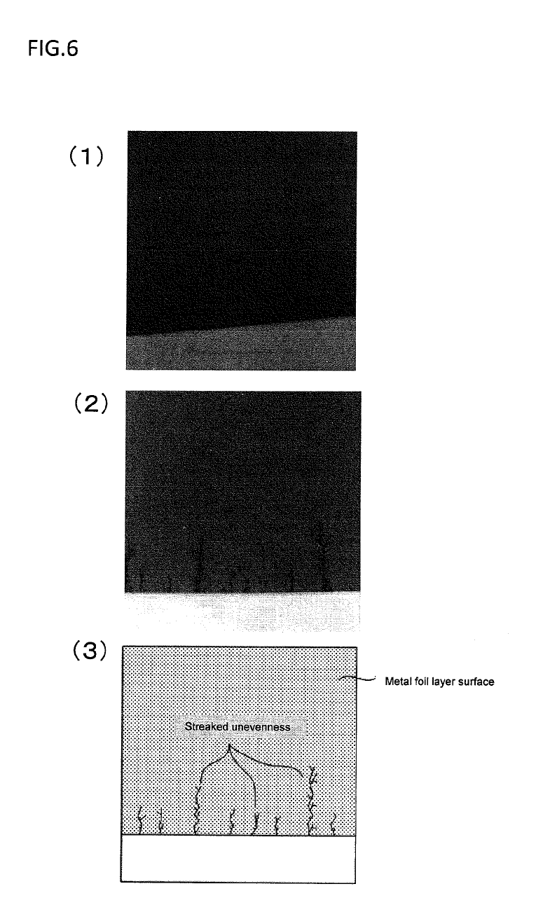

As for (6) occurrence of streaked unevenness, FIG. 6 shows: (1) a photograph of the surface of the metal-clad laminate obtained in Reference example D1; (2) a photograph of the surface of the metal-clad laminate obtained in Reference comparative example D1; and (3) a view explaining a photograph of the surface of a metal foil layer of the metal-clad laminate. As shown in the photographs, the surface of the metal foil layer of the metal-clad laminate in Reference comparative example D1 had streaked unevenness; however, the surface of the metal foil layer of the metal-clad laminate in Reference example D1 had no streaked unevenness.

TABLE D1

| | Reference examples | | | | | |
|---|---|---|---|---|---|---|
| | D1 | D2 | D3 | D4 | D5 | D6 |
| Biphenylaralkyl type epoxy resin ¹⁾ | 21.0 | 21.0 | 22.2 | 28.7 | 28.7 | |
| Naphthalene type epoxy resin ²⁾ | | | | | | 21.0 |
| Novolac type cyanate resin ³⁾ | 39.0 | 39.0 | 15.0 | 24.0 | 24.0 | 39.0 |
| Naphtholaralkyl type cyanate resin | | | | | | |
| Biphenylaralkyl type phenol resin ⁴⁾ | | | | 7.3 | | |
| Triphenylmethane type phenol resin ⁵⁾ | | | | | 7.3 | |
| Maleimide resin ⁶⁾ | | | 22.8 | | | |
| Zinc octoate ⁷⁾ | 0.02 | 0.02 | 0.02 | | | 0.02 |
| Silicone rubber particle ⁸⁾ | 37.0 | 32.0 | 37.0 | 37.0 | 37.0 | 37.0 |
| Silicone rubber particle ⁹⁾ | | | | | | |
| Barium sulfate particle ¹⁰⁾ | 3.0 | 3.0 | 3.0 | 3.0 | 3.0 | 3.0 |
| Silica particle ¹¹⁾ | | 5.0 | | | | |
| (1) Linear thermal expansion coefficient (ppm) | 10 | 9 | 9 | 10 | 9 | 9 |
| (2) Flame resistance | V-0 | V-0 | V-0 | V-0 | V-0 | V-0 |
| (3) Drill wearability (residual rate) | 55 | 50 | 55 | 55 | 50 | 50 |
| (4) Prepreg impregnation property | ∘ | ∘ | ∘ | ∘ | ∘ | ∘ |
| (5) Desmear resistance (amount of reduction | 0.13 | 0.13 | 0.14 | 0.13 | 0.12 | 0.13 |
| in thickness) | | | | | | |
| (7) ENEPIG properties | ∘ | ∘ | ∘ | ∘ | ∘ | ∘ |

TABLE D2

| | Reference examples | | | Reference comparative example | | |
|---|---|---|---|---|---|---|
| | D7 | D8 | D9 | D1 | D2 | D3 |
| Biphenylaralkyl type epoxy resin ¹⁾ | 21.0 | 21.0 | 22.2 | | 21.0 | 21.0 |
| Naphthalene type epoxy resin ²⁾ | | | | 38.0 | | |
| Novolac type cyanate resin ³⁾ | 39.0 | | 39.0 | | 39.0 | 39.0 |
| Naphtholaralkyl type cyanate resin | | 39.0 | | | | |
| Biphenylaralkyl type phenol resin ⁴⁾ | | | | | | |
| Triphenylmethane type phenol resin ⁵⁾ | | | | 22.0 | | |
| Maleimide resin ⁶⁾ | | | | | | |
| Zinc octoate ⁷⁾ | 0.02 | 0.02 | 0.02 | | 0.02 | 0.02 |
| Silicone rubber particle ⁸⁾ | | | | 37.0 | 37.0 | 40.0 |
| Silicone rubber particle ⁹⁾ | 37.0 | 37.0 | | | | |
| Barium sulfate particle ¹⁰⁾ | 3.0 | 3.0 | 3.0 | | | |
| Silica particle ¹¹⁾ | | | 37.0 | 3.0 | 3.0 | |
| (1) Linear thermal expansion coefficient (ppm) | 9 | 9 | 9 | 15 | 11 | 10 |
| (2) Flame resistance | V-0 | V-0 | V-0 | Burned | V-0 | Burned |
| | | | | down | | down |
| (3) Drill wearability (residual rate) | 50 | 55 | 25 | 50 | 55 | 60 |
| (4) Prepreg impregnation property | ∘ | ∘ | ∘ | x | x | x |
| (5) Desmear resistance (amount of reduction | 0.13 | 0.13 | 0.12 | 0.20 | 0.18 | 0.23 |
| in thickness) | | | | | | |
| (7) ENEPIG properties | ∘ | ∘ | ∘ | x | x | x |

In Tables D1 and D2, the following 1) to 11) were used:

1) product name: NC3000; manufactured by: Nippon Kayaku Co., Ltd.
2) product name: ESN-375; manufactured by: Tohto Kasei Co., Ltd.
3) product name: PT30; manufactured by: Lonza Japan, Ltd.
4) product name: MEH-7851-H; manufactured by: Meiwa Plastic Industries, Ltd.
5) product name: MEH-7500; manufactured by: Meiwa Plastic Industries, Ltd.
6) product name: BMI-70; manufactured by: KI Chemical Industry Co., Ltd.
7) manufactured by: Tokyo Chemical Industry Co., Ltd.; reagent
8) product name: KMP-605; manufactured by: Shin-Etsu Chemical Co., Ltd.; average particle diameter: 2 μm
9) product name: KMP-597; manufactured by: Shin-Etsu Chemical Co., Ltd.; average particle diameter: 5 μm
10) product name: BF-21; manufactured by: Sakai Chemical Industry Co., Ltd.; average particle diameter: 50 nm
11) product name: SO-25R; manufactured by: Admatechs Company Limited; average particle diameter: 0.5 μm

From the evaluation results shown in Tables D1 and D2, the following are understood.

In Reference comparative examples D1 and D2, prepreg impregnation property was inferior since the barium sulfate particles specified in the present invention was not used. Therefore, linear thermal expansion coefficient, flame resistance, desmear resistance and ENEPIG properties were not developed to a practicable level.

In Reference comparative example D3, linear thermal expansion coefficient was excellent since a large amount of the silicone rubber particles was used; however, prepreg impregnation property was inferior since the barium sulfate particles specified in the present invention was not used. Therefore, flame resistance, desmear resistance and ENEPIG properties were not developed to a practicable level

The resin composition, prepreg, metal-clad laminate, printed wiring board and semiconductor device of the present invention obtained in each of Reference examples D1 to D9 had excellent linear thermal expansion coefficient, flame resistance, prepreg impregnation property, desmear resistance and ENEPIG properties. Therefore, it can be understood that the prepreg, metal-clad laminate, printed wiring board and semiconductor device having excellent performance can be obtained by using the barium sulfate particle-containing resin composition comprising the epoxy resin and barium sulfate particles specified in the present invention.

### Reference Example E Series

Reference examples using the fifth resin composition of the present invention will be described below.

### Reference Example E1

### (1) Preparation of Varnish Containing Resin Composition (Resin Varnish)

17.5% by weight of a naphthalene type tetrafunctional epoxy resin (product number: HP-4700; manufactured by: DIC CORPORATION; epoxy equivalent: 165) as an epoxy resin, 17.3% by weight of a biphenyl alkylene type novolac resin (product number: MEH-7851-3H; manufactured by: Meiwa Plastic Industries, Ltd.; hydroxyl group equivalent: 230) as a phenol curing agent, 0.1% by weight of imidazole (product number: 2E4MZ; manufactured by: Shikoku Chemicals Corporation) as an accelerator, 61.4% by weight of boehmite (product number: BMT-3L; manufactured by: Kawai Lime Industry Co., Ltd.; average particle diameter: 2.9 μm; 1% weight-loss thermal decomposition temperature: 420° C.) as a first filler, 3.5% by weight of a spherical nanosilica (product number: NSS-5N; manufactured by: Tokuyama Corporation; average particle diameter: 70 nm; product treated with vinylsilane) as a second filler, and 0.2% by weight of epoxy silane (product number: A-187; manufactured by: GE TOSHIBA SILICONES CO., LTD.) as a coupling agent were dissolved in methyl isobutyl ketone and mixed. Then, the thus-obtained mixture was agitated by means of a high speed agitator, thereby obtaining a resin varnish.

### (2) Production of Prepreg

A prepreg was obtained similarly as in Example A1 using the resin varnish.

### (3) Production of Metal-Clad Laminate

A double-sided metal-clad laminate having a thickness of 0.40 mm was obtained similarly as in Example A1 using the obtained prepreg.

### (4) Production of Printed Wiring Board

A printed wiring board was produced similarly as in Example A1 using the obtained metal-clad laminate having copper foils on both surfaces thereof.

### (5) Production of Semiconductor Device

A semiconductor device was produced similarly as in Example A1 using the obtained printed wiring board.

### Reference Examples E2 to E12 and Reference Comparative Example E1

In each of Reference examples E2 to E12 and Reference comparative example E1, a resin varnish, prepreg, metal-clad laminate, printed wiring board and semiconductor device were produced similarly as in Reference example E1 except that the resin varnish was prepared in accordance with the lists of Tables E1 and E2.

The following materials were used:

(1) Cyanate resin/novolac type cyanate resin (product name: Primaset PT-30; manufactured by: Lonza Japan, Ltd.; cyanate equivalent: 124)
(2) Epoxy resin/naphthalene type tetrafunctional epoxy resin (product name: HP-4700; manufactured by: DIC Corporation; epoxy equivalent: 165 g/eq)
(3) Epoxy resin/biphenyldimethylene type epoxy resin (product name: NC-3000H; manufactured by: Nippon Kayaku Co., Ltd.; epoxy equivalent: 275)
(4) Phenol curing agent/biphenyl alkylene type novolac resin (product name: MEH-7851-3H; manufactured by: Meiwa Plastic Industries, Ltd.; hydroxyl group equivalent: 230)
(5) Accelerator/imidazole (product name: 2E4MZ; manufactured by: Shikoku Chemicals Corporation)
(6) First filler/boehmite (product name: BMT-3L; manufactured by: Kawai Lime Industry Co., Ltd.; average particle diameter: 2.9 μm)
(7) First filler/heat-resistant aluminum hydroxide (product name: AHL-F; manufactured by: Kawai Lime Industry Co., Ltd.; average particle diameter: 3 μm)
(8) First filler/talc (product name: LMS-200; manufactured by: Fuji Talc Industrial Co., Ltd.; average particle diameter: 5.0 μm)
(9) First filler/spherical silica (product name: SO-25R; manufactured by: Admatechs Company Limited; average particle diameter: 0.5 μm)
(10) First filler/spherical silica (product name: SO-31R; manufactured by: Admatechs Company Limited; average particle diameter: 1.0 μm)
(11) First filler/silicone powder (product name: KMP-605; manufactured by: Shin-Etsu Chemical Co., Ltd.; average particle diameter: 2 μm)
(12) First filler/silicone powder (product name: KMP-600; manufactured by: Shin-Etsu Chemical Co., Ltd.; average particle diameter: 5 μm)
(13) Second filler/spherical silica (product name: NSS-5N; manufactured by: Tokuyama Corporation; average particle diameter: 70 nm; product treated with vinylsilane)
(14) Second filler/spherical silica (product name: NSS-5N; manufactured by: Tokuyama Corporation; average particle diameter: 70 nm; product treated with epoxy silane)
(15) Second filler/spherical silica (product name: Admanano; manufactured by: Admatechs Company Limited; average particle diameter: 50 nm; product treated with vinylsilane)
(16) Second filler/spherical silica (product name: Admanano; manufactured by: Admatechs Company Limited; average particle diameter: 25 nm; product treated with vinylsilane)
(17) Coupling agent/epoxy silane (product name: A-187; manufactured by: GE Toshiba Silicones Co., Ltd.)

The evaluation results of the resin varnish, and the prepreg, metal-clad laminate, printed wiring board and semiconductor device produced using the resin varnish in each of Reference examples and Reference comparative examples are shown in Tables E1 and E2.

TABLE E1

| | | Reference examples | | | | | | |
|---|---|---|---|---|---|---|---|---|
| | | E1 | E2 | E3 | E4 | E5 | E6 | E7 |
| Cyanate resin | PT-30 | | 17.5 | 17.5 | 17.5 | 17.5 | 17.5 | 17.5 |
| Epoxy resin | HP-4700 | 17.5 | 9.4 | | | | | |
| | NC3000H | | | 9.4 | 9.4 | 9.4 | 9.4 | 9.4 |
| Phenol curing agent | MEH-7851-3H | 17.3 | 8.0 | 8.0 | 8.0 | 8.0 | 8.0 | 8.0 |
| Accelerator | 2E4MZ | 0.1 | | | | | | |
| First filler | BMT-3L | 61.4 | 61.4 | 61.4 | | 46.1 | 31.6 | 31.6 |
| | AHL-F | | | | 61.4 | | | |
| | LMS-200 | | | | | 15.3 | | |
| | 2E4MZ | | | | | | 29.8 | |
| | SO-31R | | | | | | | 29.8 |
| Second filter | NSS-5N | 3.5 | 3.5 | 3.5 | 3.5 | 3.5 | 3.5 | 3.5 |
| | product treated with | | | | | | | |
| | vinylsilane | | | | | | | |
| Coupling agent | A-187 | 0.2 | 0.2 | 0.2 | 0.2 | 0.2 | 0.2 | 0.2 |
| | Compounding amount | 100.0 | 100.0 | 100.0 | 100.0 | 100.0 | 100.0 | 100.0 |
| | (total 100%) | | | | | | | |
| | (1) Thixotropic ratio | 1.1 | 1.1 | 1.1 | 1.1 | 1.2 | 1.1 | 0.9 |
| | (5/20 rmp) | | | | | | | |
| | (2) Dispersibility | ∘ | ∘ | ∘ | ∘ | ∘ | ∘ | ∘ |
| | (grind gauge) | | | | | | | |
| | (3) Dispersability | ∘ | ∘ | ∘ | ∘ | ∘ | ∘ | ∘ |
| | (particle size distribution) | | | | | | | |
| | (4) Impregnation | ∘ | [symbol] | [symbol] | ∘ | ∘ | [symbol] | [symbol] |
| | property | | | | | | | |
| | (5) Formability | ∘ | [symbol] | [symbol] | ∘ | ∘ | [symbol] | [symbol] |
| | (6) Heat resistance | 0 | [symbol] | [symbol] | ∘ | ∘ | [symbol] | [symbol] |
| | (7) Linear thermal | 12 | 12 | 12 | 12 | 11 | 10 | 10 |
| | expansion coefficient | | | | | | | |
| | (8) Permeation of plating | [symbol] | [symbol] | [symbol] | [symbol] | [symbol] | ∘ | ∘ |
| | after drill processing | | | | | | | |
| | (9) TH insulation reliability | [symbol] | [symbol] | [symbol] | [symbol] | [symbol] | [symbol] | [symbol] |
| | (10) Warpage of printed | ∘ | ∘ | ∘ | ∘ | ∘ | [symbol] | [symbol] |
| | wiring board section | | | | | | | |
| | (11) Flame resistance | V-0 | V-0 | V-0 | V-0 | V-0 | V-0 | V-0 |

TABLE E2

| | | | | | | | Reference |
|---|---|---|---|---|---|---|---|
| | | | | | | | comparative |
| | | Reference examples | | | | | example |
| | | E8 | E9 | E10 | E11 | E12 | E1 |
| Cyanate resin | PT-30 | 21.8 | 21.8 | 17.5 | 17.5 | 17.5 | 17.5 |
| Epoxy resin | HP-4700 | | | | | | |
| | NC3000H | 12.4 | 12.4 | 9.4 | 9.4 | 9.4 | 9.4 |
| Phenol curing agent | MEH-7851-3H | 10.5 | 10.5 | 8.0 | 8.0 | 8.0 | 8.0 |
| First filler | BMT-3L | 31.6 | 31.6 | 31.6 | 31.6 | 31.6 | 31.6 |
| | 2E4MZ | | | 29.8 | 29.8 | 29.8 | 33.3 |
| | KMP-605 | 20 | | | | | |
| | KNP-600 | | 20 | | | | |
| Second filler | NSS-5N | 3.5 | 3.5 | | | | |
| | product treated with | | | | | | |
| | vinylsilane | | | | | | |
| | NSS-5N | | | 3.5 | | | |
| | product treated with | | | | | | |
| | epoxysilane | | | | | | |
| | NSS-5N | | | | | | |
| | product treated with | | | | | | |
| | anilide silane | | | | | | |
| | Admanano-50 m | | | | 3.5 | | |
| | product treated with | | | | | | |
| | vinylsilane | | | | | | |
| | Admanoano-25 m | | | | | 3.5 | |
| | product treated with | | | | | | |
| | vinylsilane | | | | | | |
| Coupling agent | A-187 | 0.2 | 0.2 | 0.2 | 0.2 | 0.2 | 0.2 |
| | Compounding amount | 100.0 | 100.0 | 100.0 | 100.0 | 100.0 | 100.0 |
| | (total 100%) | | | | | | |
| | (1)Thixotropic ratio | 1.2 | 1.2 | 1.2 | 1.2 | 1.1 | 2.5 |
| | (5/20 rmp) | | | | | | |
| | (2) Dispersibility | ∘ | ∘ | ∘ | ∘ | ∘ | x |
| | (grind gauge) | | | | | | |
| | (3) Dispersibility | ∘ | ∘ | ∘ | ∘ | ∘ | x |
| | (particle size distribution) | | | | | | |
| | (4) Impregnation | [symbol] | [symbol] | [symbol] | [symbol] | [symbol] | x |
| | property | | | | | | |
| | (5) Formability | [symbol] | [symbol] | [symbol] | [symbol] | [symbol] | x |
| | (6) Heat resistance | [symbol] | [symbol] | [symbol] | [symbol] | [symbol] | Δ |
| | (7) Linear thermal | 9 | 9 | 9 | 9 | 9 | 10 |
| | expansion coefficient | | | | | | |
| | (8) Permeation of plating | [symbol] | [symbol] | ∘ | ∘ | ∘ | Δ |
| | after drill processing | | | | | | |
| | (9) TH insulation | [symbol] | [symbol] | [symbol] | [symbol] | [symbol] | Δ |
| | reliability | | | | | | |
| | (10) Warpage of printed | [symbol] | [symbol] | [symbol] | [symbol] | [symbol] | x |
| | wiring board section | | | | | | |
| | (11) Flame resistance | V-0 | V-0 | V-0 | V-0 | V-0 | V-0 |

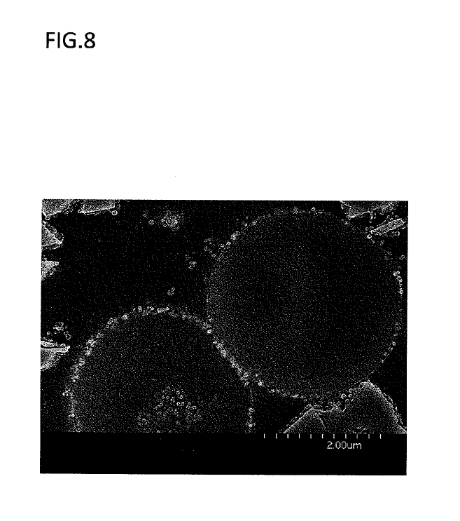

The evaluation items shown in Tables E1 and E2 will be described below. FIG. 8 shows a FE-SEM photograph of the cross-sectional surface of the laminate obtained in Reference example E1. FIG. 9 shows a FE-SEM photograph of the cross-sectional surface of the laminate obtained in Reference example E9.

### (1) Thixotropy

Thixotropy of the resin varnish was evaluated similarly as in Example A series.

### (2) Dispersibility (Grind Gauge)

Dispersibility of the resin varnish was evaluated by means of a grind gauge (product name: Elcometer KP-2020-2; manufactured by: Cotec Corporation). In particular, a grind gauge was horizontally placed, and the resin vanish was charged into a groove which is deeper than the other. Then, a scraper was moved in a direction that is perpendicular to the groove to the depth of 0 at a uniform rate in one or two seconds. The groove was observed at a right angle to the groove direction and at an angle of 20 to 30° within three seconds, and a scale with notable spots, which represents a particle diameter of aggregate, was measured. Symbols shown in Tables E1 and E2 refer to the following:

∘: No aggregate of 20 μm or more was observed.
Δ: Aggregate of 20 μm or more and less than 50 μm was observed.
x: Aggregate of 50 μm or more was observed.

### (3) Dispersibility (Particle Size Distribution)

Dispersibility of the resin varnish was evaluated by means of a laser diffraction particle size analyzer (product name: LA-500; manufactured by: HORIBA). In particular, about 100 μl of the resin varnish was charged into an evaluation cell filled with a ketone organic solvent and stabilized, and then a value was read off. The particle size distribution of the filler was prepared based on volume, and the thus-obtained median diameter was defined as the average particle diameter. Symbols shown in Tables E1 and E2 refer to the following:

∘: No aggregate of 20 μm or more was observed.
Δ: Aggregate of 20 μm or more and less than 50 μm was observed.
x: Aggregate of 50 μm or more was observed.

### (4) Prepreg Impregnation Property

Prepreg impregnation property was evaluated similarly as in Example A series.

### (5) Formability

Formability of the laminate (510 mm×510 mm) obtained in each of Reference examples and Reference comparative examples was evaluated. In particular, the obtained laminate was divided into quarters each having a size of about 250 mm×250 mm by means of a shear followed by removing the copper foil by etching. The surface of the laminate was visually observed and evaluated.

Symbols shown in Tables E1 and E2 refer to the following:

[symbol]

: No void was observed.
∘: Void of less than 10 μm was observed only at 10 mm end of the laminate.
Δ: Void of more than 10 μm was observed.
x: Many voids were observed.

### (6) Heat Resistance

Heat resistance of the semiconductor device was evaluated similarly as in Example A series.

### (7) Linear Thermal Expansion Coefficient

Linear thermal expansion coefficient was measured similarly as in Example A series using the obtained metal-clad laminate.

(8) Permeation of Plating after Drill Processing

Permeation of plating after drill processing was evaluated similarly as in Example A series using the obtained metal-clad laminate.

### (9) Through Hole Insulation Reliability

Through hole insulation reliability was evaluated similarly as in Example A series using the obtained metal-clad laminate.

### (10) Warpage of Printed Wiring Board Section of Semiconductor Device

Warpage of the printed wiring board section of the above-produced semiconductor device was measured similarly as in Example A series.

### (11) Flame Resistance

A double-sided copper-clad laminate having a thickness of 0.4 mm was obtained similarly as in Example A series except that heat-press was performed at a temperature of 200° C. in the production of the laminate. The copper foils of the above-obtained copper-clad laminate was subjected to etching, and flame resistance of a test piece having a thickness of 0.4 mm was measured by a vertical method in accordance with UL-94 standard.

As is clear from Table E1, the resin varnish obtained in each of Reference examples E1 to E12 had excellent flowability, and the occurrence of the warpage upon forming the laminate was prevented. It can be confirmed in FIG. 8 that the spherical filler (silica) being the second filler adsorbed around the first filler (In FIG. 8, boehmite). It can be also confirmed in FIG. 9 that the spherical filler (silica) being the second filler adsorbed around the silicone being the first filler.

The resin varnish obtained in each of Reference examples E1 to E12 had excellent thixotropy and filler sedimentation property. Therefore, the resin varnish had excellent mass production stability and impregnation property in the prepreg. The resin varnish had excellent resin flowability, so that formability was excellent upon producing the laminate even if the resin varnish contains high amount of the inorganic filler. In addition, heat resistance, low linear thermal expansion coefficient and drill processability was excellent upon forming the printed wiring board. Therefore, through hole insulation reliability was excellent, and the printed wiring board section of the semiconductor device had small warpage since it had low linear thermal expansion coefficient.

In contrast, the resin varnish in Reference comparative example E1 had high thixotropy, so that impregnation property in the prepreg and resin flowability were poor. Therefore, it can be estimated that formability, heat resistance, through hole insulation reliability were inferior.

### REFERENCE SIGNS LIST

1: Base material
2: Impregnating bath
3: Resin varnish
4: Dipping roller
5: Squeeze roller
6: Drier
7: Prepreg
8: Upper roller
10: Metal foil with insulating resin layer
11: Metal foil
12: Insulating resin layer
20: Base material
30: Polymer film sheet with insulating resin layer
31: Polymer film sheet
32: Insulating resin layer
40: Prepreg
41: Prepreg with metal foil
42: Prepreg with polymer film sheet
51: Metal-clad laminate
52: Metal-clad laminate

1. A resin composition for forming a laminate, comprising an epoxy resin, a first inorganic filler with an irregular shape and a second inorganic filler having an average particle diameter of 10 to 100 nm which is different from that of the first inorganic filler.

2. The resin composition according to claim 1, wherein a content of the second inorganic filler is 0.5 to 5% by weight of the resin composition.

3. The resin composition according to claim 1, prepared with a slurry produced by preliminarily dispersing the second inorganic filler in an organic solvent.

4. The resin composition according to claim 1, wherein the second inorganic filler is silica.

5. The resin composition according to claim 1, wherein the first inorganic filler is boehmite.

6. The resin composition according to claim 1, wherein the first inorganic filler has an average particle diameter of 0.5 to 5 μm.

7. The resin composition according to claim 1, wherein a content of the first inorganic filler is 20 to 65% by weight of the resin composition.

8. The resin composition according to claim 1, further comprising a third inorganic filler having an average particle diameter of 0.2 to 3 μm.

9. The resin composition according to claim 8, wherein the third inorganic filler has a maximum particle diameter of 10 μm or less.

10. The resin composition according to claim 8, wherein a weight ratio (w2/w3) of the content of the second inorganic filler (w2) and a content of the third inorganic filler (w3) is 0.02 to 1.5.

11. The resin composition according to claim 1, wherein a weight ratio (w2/w1) of the content of the first inorganic filler (w1) and the content of the second inorganic filler (w2) is 0.02 to 0.5.

12. The resin composition according to claim 1, further comprising a cyanate resin.

13. The resin composition according to claim 1, wherein the epoxy resin is at least one kind selected from the group consisting of a biphenyldimethylene type epoxy resin, a novolac type epoxy resin, a naphthalene-modified cresol novolac epoxy resin and an anthracene type epoxy resin.

14. A resin composition comprising an epoxy resin, silicone rubber particles having an average particle diameter of 1 μm to 10 μm, boehmite particles having an average particle diameter of 0.2 μm to 5 μm, and silica nanoparticles having an average particle diameter of 10 nm to 100 nm.

15. The resin composition according to claim 14, wherein each of the silicone rubber particles is a core-shell structure particle in which a core portion consisting of silicone rubber is covered with a silicone resin.

16. The resin composition according to claim 14, wherein the silica nanoparticles have an average particle diameter of 40 nm or more and 100 nm or less.

17. The resin composition according to claim 14, further comprising a cyanate resin.

18. The resin composition according to claim 14, further comprising a maleimide resin.

19. The resin composition according to claim 14, wherein the epoxy resin is at least one kind selected from the group consisting of a biphenylaralkyl type epoxy resin, a naphthalene-skeleton modified epoxy resin and a cresol novolac type epoxy resin.

20. A resin sheet comprising a resin layer and a base material, wherein the resin layer comprises the resin composition defined by claim 1 and is on the base material.

21. A prepreg comprising a base material impregnated with the resin composition defined by claim 1.

22. A metal-clad laminate comprising a resin-impregnated base material layer and a metal foil, wherein the metal foil is on at least one surface of the resin-impregnated base material layer, and the resin-impregnated base material layer comprises a base material impregnated with the resin composition defined by claim 1.

23. A metal-clad laminate, obtained by providing a metal foil on at least one surface of the prepreg defined by claim 21 or on at least one surface of a laminate comprising the stacked prepregs, and applying heat and pressure.

24. A printed wiring board comprising the metal-clad laminate defined by claim 22 as an inner layer circuit board.

25. A printed wiring board comprising the prepreg defined by claim 21 and an inner layer circuit, wherein the prepreg is used as an insulating layer on the inner layer circuit.

26. A printed wiring board comprising the resin composition defined by claim 1 and an inner layer circuit, wherein the resin composition is used as an insulating layer on the inner layer circuit.

27. A semiconductor device comprising the printed wiring board defined by claim 24, and a semiconductor element mounted on the printed wiring board.

28. A printed wiring board comprising the metal-clad laminate defined by claim 23 as an inner layer circuit board.

29. A semiconductor device comprising the printed wiring board defined by claim 25, and a semiconductor element mounted on the printed wiring board.

30. A semiconductor device comprising the printed wiring board defined by claim 26, and a semiconductor element mounted on the printed wiring board.

31. A semiconductor device comprising the printed wiring board defined by claim 28, and a semiconductor element mounted on the printed wiring board.

32. A resin sheet comprising a resin layer and a base material, wherein the resin layer comprises the resin composition defined by claim 14 and is on the base material.

33. A prepreg comprising a base material impregnated with the resin composition defined by claim 14.

34. A metal-clad laminate comprising a resin-impregnated base material layer and a metal foil, wherein the metal foil is on at least one surface of the resin-impregnated base material layer, and the resin-impregnated base material layer comprises a base material impregnated with the resin composition defined by claim 14.

35. A metal-clad laminate, obtained by providing a metal foil on at least one surface of the prepreg defined by claim 33 or on at least one surface of a laminate comprising the stacked prepregs, and applying heat and pressure.

36. A printed wiring board comprising the metal-clad laminate defined by claim 34 as an inner layer circuit board.

37. A printed wiring board comprising the prepreg defined by claim 33 and an inner layer circuit, wherein the prepreg is used as an insulating layer on the inner layer circuit.

38. A printed wiring board comprising the resin composition defined by claim 14 and an inner layer circuit, wherein the resin composition is used as an insulating layer on the inner layer circuit.

39. A semiconductor device comprising the printed wiring board defined by claim 36, and a semiconductor element mounted on the printed wiring board.

40. A printed wiring board comprising the metal-clad laminate defined by claim 35 as an inner layer circuit board.

41. A semiconductor device comprising the printed wiring board defined by claim 37, and a semiconductor element mounted on the printed wiring board.

42. A semiconductor device comprising the printed wiring board defined by claim 38, and a semiconductor element mounted on the printed wiring board.

43. A semiconductor device comprising the printed wiring board defined by claim 40, and a semiconductor element mounted on the printed wiring board.
